(19) United States
(12) Patent Application Publication
(10) Pub. No.: US 2026/0171029 A1
(43) Pub. Date: Jun. 18, 2026

(54) Shift Register and Drive Method Therefor, Gate Drive Circuit, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Xiang LUO, Beijing (CN); Ziyang YU, Beijing (CN)

(21) Appl. No.: 18/851,708

(22) PCT Filed: Jan. 24, 2024
(86) PCT No.: PCT/CN2024/073869

§ 371 Date: Sep. 27, 2024

(30) Foreign Application Priority Data
Oct. 17, 2023 (WO) PCT/CN2023/125026

(51) Int. Cl. G09G 3/3266; G09G 3/32; G11C 19/28

(52) U.S. Cl. CPC G09G 3/3266; G09G 3/32; G09G 2300/0426; G09G 2300/0452; G09G 2310/0267; G09G 2310/0286; G09G 2310/08; G11C 19/287

(57) ABSTRACT

Disclosed are a shift register and a drive method therefor, a gate drive circuit, and a display apparatus, wherein the shift register includes: a shift sub-circuit and an output sub-circuit; the shift sub-circuit is configured to provide a signal to a cascaded signal output terminal (OUTC) under control of signals of a signal input terminal (IN), a first clock signal terminal (CK), a second clock signal terminal (CB), a first power supply terminal (VH1), and a second power supply terminal (VL1); the output sub-circuit is configured to provide a signal to a drive signal output terminal (OUT) under control of signals of the shift sub-circuit, a latch signal terminal (MS), a first control signal terminal (V1), a second control signal terminal (V2), the cascaded signal output terminal (OUTC), a third power supply terminal (VH2), a fourth power supply terminal (VL2), and a fifth power supply terminal (NCX).

### CROSS-REFERENCE TO RELATED APPLICATIONS

The present application is a U.S. National Phase Entry of International Application No. PCT/CN2024/073869 having an international filing date of Jan. 24, 2024, which claims priority to PCT International Application No. PCT/CN2023/125026, filed on Oct. 17, 2023 and entitled “Display Substrate and Display Apparatus”, contents of the above-identified applications should be interpreted as being hereby incorporated by reference.

### TECHNICAL FIELD

The present disclosure relates, but is not limited, to the field of display technologies, and in particular to a shift register and a drive method therefor, a gate drive circuit, and a display apparatus.

### BACKGROUND

An Organic Light Emitting Diode (OLED) and a Quantum dot Light Emitting Diode (QLED) are active light emitting display devices and have advantages of self-illumination, a wide viewing angle, a high contrast ratio, low power consumption, an extremely high reaction speed, lightness and thinness, flexibility, and a low cost, etc. With constant development of display technologies, a flexible display apparatus (Flexible Display) in which an OLED or a QLED is used as a light emitting device and signal control is performed through a Thin Film Transistor (TFT) has become a mainstream product in the field of display at present.

### SUMMARY

The following is a summary of subject matters described in the present disclosure in detail. This summary is not intended to limit the protection scope of claims.

In a first aspect, the present disclosure provides a shift register including: a shift sub-circuit and an output sub-circuit; the shift sub-circuit is electrically connected with a signal input terminal, a first clock signal terminal, a second clock signal terminal, a first power supply terminal, a second power supply terminal, and a cascaded signal output terminal respectively, and is configured to provide a signal to the cascaded signal output terminal under control of signals of the signal input terminal, the first clock signal terminal, the second clock signal terminal, the first power supply terminal, and the second power supply terminal; the output sub-circuit is electrically connected with the shift sub-circuit, a latch signal terminal, a first control signal terminal, a second control signal terminal, a third power supply terminal, a fourth power supply terminal, a fifth power supply terminal, the cascaded signal output terminal, and a drive signal output terminal respectively, and is configured to provide a signal to the drive signal output terminal under control of signals of the shift sub-circuit, the latch signal terminal, the first control signal terminal, the second control signal terminal, the cascaded signal output terminal, the third power supply terminal, the fourth power supply terminal, and the fifth power supply terminal; the shift sub-circuit includes: at least one shift output transistor, the shift output transistor is electrically connected with the cascaded signal output terminal, and the output sub-circuit includes: at least one drive output transistor, and the drive output transistor is electrically connected with the drive signal output terminal; the shift sub-circuit further includes: at least one transistor, and the output sub-circuit further includes: at least one transistor; the shift sub-circuit is provided with a third node, a control electrode of the at least one drive output transistor is electrically connected with the third node through the at least one transistor of the output sub-circuit, and a control electrode of the at least one shift output transistor is electrically connected with the third node through the at least one transistor of the shift sub-circuit.

In an exemplary implementation mode, the shift sub-circuit is further electrically connected with the fifth power supply terminal, and is configured to provide a signal to the cascaded signal output terminal under control of signals of the signal input terminal, the first clock signal terminal, the second clock signal terminal, the first power supply terminal, the second power supply terminal, and the fifth power supply terminal.

In an exemplary implementation mode, the shift sub-circuit includes: a first transistor to a sixteenth transistor and a first capacitor to a third capacitor; a control electrode of the first transistor is electrically connected with the first clock signal terminal, a first electrode of the first transistor is electrically connected with the signal input terminal, and a second electrode of the first transistor is electrically connected with the third node; a control electrode of the second transistor is electrically connected with the third node, a first electrode of the second transistor is electrically connected with the first clock signal terminal, and a second electrode of the second transistor is electrically connected with a tenth node; a control electrode of the third transistor is electrically connected with the first clock signal terminal, a first electrode of the third transistor is electrically connected with the second power supply terminal, and a second electrode of the third transistor is electrically connected with the tenth node; a control electrode of the fourth transistor is electrically connected with a second node, a first electrode of the fourth transistor is electrically connected with the second clock signal terminal, and a second electrode of the fourth transistor is electrically connected with a fifth node; a control electrode of the fifth transistor is electrically connected with the tenth node, a first electrode of the fifth transistor is electrically connected with the first power supply terminal, and a second electrode of the fifth transistor is electrically connected with the fifth node; a control electrode of the sixth transistor is electrically connected with a sixth node, a first electrode of the sixth transistor is electrically connected with the second clock signal terminal, and a second electrode of the sixth transistor is electrically connected with a first node; a control electrode of the seventh transistor is electrically connected with the second clock signal terminal, a first electrode of the seventh transistor is electrically connected with the first node, and a second electrode of the seventh transistor is electrically connected with a fourth node; a control electrode of the eighth transistor is electrically connected with the third node, a first electrode of the eighth transistor is electrically connected with the first power supply terminal, and a second electrode of the eighth transistor is electrically connected with the fourth node; a control electrode of the ninth transistor is electrically connected with the fourth node, a first electrode of the ninth transistor is electrically connected with the first power supply terminal, and a second electrode of the ninth transistor is electrically connected with the cascaded signal output terminal; a gate electrode of the tenth transistor is electrically connected with a ninth node, a first electrode of the tenth transistor is electrically connected with the second power supply terminal, and a second electrode of the tenth transistor is electrically connected with the cascaded signal output terminal; a control electrode of the eleventh transistor is electrically connected with the second power supply terminal, a first electrode of the eleventh transistor is electrically connected with the tenth node, and a second electrode of the eleventh transistor is electrically connected with the sixth node; a control electrode of the twelfth transistor is electrically connected with the second power supply terminal, a first electrode of the twelfth transistor is electrically connected with the third node, and a second electrode of the twelfth transistor is electrically connected with the ninth node; a control electrode of the thirteenth transistor is electrically connected with the fifth power supply terminal, a first electrode of the thirteenth transistor is electrically connected with the first power supply terminal, and a second electrode of the thirteenth transistor is electrically connected with the third node; a control electrode of the fourteenth transistor is electrically connected with the first clock signal terminal, a first electrode of the fourteenth transistor is electrically connected with the signal input terminal, and a second electrode of the fourteenth transistor is electrically connected with a first electrode of the fifteenth transistor; a control electrode of the fifteenth transistor is electrically connected with the second power supply terminal, and a second electrode of the fifteenth transistor is electrically connected with the second node; a control electrode of the sixteenth transistor is electrically connected with the second node, a first electrode of the sixteenth transistor is electrically connected with the ninth node, and a second electrode of the sixteenth transistor is electrically connected with the second node; a first electrode plate of the first capacitor is electrically connected with the sixth node, and a second electrode plate of the first capacitor is electrically connected with the first node; a first electrode plate of the second capacitor is electrically connected with the fourth node, and a second electrode plate of the second capacitor is electrically connected with the first power supply terminal; and a first electrode plate of the third capacitor is electrically connected with the second node, and a second electrode plate of the third capacitor is electrically connected with the fifth node.

In an exemplary implementation mode, the shift sub-circuit includes: a first transistor to a fifteenth transistor and a first capacitor to a third capacitor; a control electrode of the first transistor is electrically connected with the first clock signal terminal, a first electrode of the first transistor is electrically connected with the signal input terminal, and a second electrode of the first transistor is electrically connected with the third node; a control electrode of the second transistor is electrically connected with the third node, a first electrode of the second transistor is electrically connected with the first clock signal terminal, and a second electrode of the second transistor is electrically connected with a tenth node; a control electrode of the third transistor is electrically connected with the first clock signal terminal, a first electrode of the third transistor is electrically connected with the second power supply terminal, and a second electrode of the third transistor is electrically connected with the tenth node; a control electrode of the fourth transistor is electrically connected with a second node, a first electrode of the fourth transistor is electrically connected with the second clock signal terminal, and a second electrode of the fourth transistor is electrically connected with a fifth node; a control electrode of the fifth transistor is electrically connected with the tenth node, a first electrode of the fifth transistor is electrically connected with the first power supply terminal, and a second electrode of the fifth transistor is electrically connected with the fifth node; a control electrode of the sixth transistor is electrically connected with a sixth node, a first electrode of the sixth transistor is electrically connected with the second clock signal terminal, and a second electrode of the sixth transistor is electrically connected with a first node; a control electrode of the seventh transistor is electrically connected with the second clock signal terminal, a first electrode of the seventh transistor is electrically connected with the first node, and a second electrode of the seventh transistor is electrically connected with a fourth node; a control electrode of the eighth transistor is electrically connected with the third node, a first electrode of the eighth transistor is electrically connected with the first power supply terminal, and a second electrode of the eighth transistor is electrically connected with the fourth node; a control electrode of the ninth transistor is electrically connected with the fourth node, a first electrode of the ninth transistor is electrically connected with the first power supply terminal, and a second electrode of the ninth transistor is electrically connected with the cascaded signal output terminal; a control electrode of a tenth transistor is electrically connected with the second node, a first electrode of the tenth transistor is electrically connected with the second power supply terminal, and a second electrode of the tenth transistor is electrically connected with the cascaded signal output terminal; a control electrode of the eleventh transistor is electrically connected with the second power supply terminal, a first electrode of the eleventh transistor is electrically connected with the tenth node, and a second electrode of the eleventh transistor is electrically connected with the sixth node; a control electrode of the twelfth transistor is electrically connected with the second power supply terminal, a first electrode of the twelfth transistor is electrically connected with the third node, and a second electrode of the twelfth transistor is electrically connected with the second node; a control electrode of the thirteenth transistor is electrically connected with the fifth power supply terminal, a first electrode of the thirteenth transistor is electrically connected with the first power supply terminal, and a second electrode of the thirteenth transistor is electrically connected with the third node; a control electrode of the fourteenth transistor is electrically connected with the first clock signal terminal, a first electrode of the fourteenth transistor is electrically connected with the signal input terminal, and a second electrode of the fourteenth transistor is electrically connected with a first electrode of the fifteenth transistor; a control electrode of the fifteenth transistor is electrically connected with the second power supply terminal, and a second electrode of the fifteenth transistor is electrically connected with the second node; a first electrode plate of the first capacitor is electrically connected with the sixth node, and a second electrode plate of the first capacitor is electrically connected with the first node; a first electrode plate of the second capacitor is electrically connected with the fourth node, and a second electrode plate of the second capacitor is electrically connected with the first power supply terminal; and a first electrode plate of the third capacitor is electrically connected with the second node, and a second electrode plate of the third capacitor is electrically connected with the fifth node.

In an exemplary implementation mode, the shift sub-circuit further includes: a fourth capacitor; a first electrode plate of the fourth capacitor is electrically connected with the second power supply terminal, and a second electrode plate of the fourth capacitor is electrically connected with the cascaded signal output terminal.

In an exemplary implementation mode, the first control signal terminal is electrically connected with the fifth node.

In an exemplary implementation mode, the second control signal terminal is electrically connected with a first node in a previous stage shift register of a current stage shift register.

In an exemplary implementation mode, the output sub-circuit is electrically connected with the second node, the third node, and the fourth node in the shift register, respectively.

In an exemplary implementation mode, the output sub-circuit includes: a seventeenth transistor to a twenty-sixth transistor, and a fifth capacitor and a sixth capacitor; a control electrode and a first electrode of the seventeenth transistor are respectively electrically connected with the second node, and a second electrode of the seventeenth transistor is electrically connected with the sixth node; a control electrode of the eighteenth transistor is electrically connected with a seventh node, a first electrode of the eighteenth transistor is electrically connected with the third node, and a second electrode of the eighteenth transistor is electrically connected with the sixth node; a control electrode of the nineteenth transistor is electrically connected with the second control signal terminal, a first electrode of the nineteenth transistor is electrically connected with the latch signal terminal, and a second electrode of the nineteenth transistor is electrically connected with a second electrode of the twentieth transistor; a control electrode of the twentieth transistor is electrically connected with the cascaded signal output terminal, and a first electrode of the twentieth transistor is electrically connected with the seventh node; a control electrode of the twenty-first transistor is electrically connected with the seventh node, a first electrode of the twenty-first transistor is electrically connected with the fourth node, and a second electrode of the twenty-first transistor is electrically connected with an eighth node; a control electrode of the twenty-second transistor is electrically connected with the fifth power supply terminal, a first electrode of the twenty-second transistor is electrically connected with the fourth power supply terminal, and a second electrode of the twenty-second transistor is electrically connected with the seventh node; a control electrode of the twenty-third transistor is electrically connected with the first control signal terminal, a first electrode of the twenty-third transistor is electrically connected with the fourth power supply terminal, and a second electrode of the twenty-third transistor is electrically connected with the seventh node; a control electrode of the twenty-fourth transistor is electrically connected with the sixth node, a first electrode of the twenty-fourth transistor is electrically connected with the third power supply terminal, and a second electrode of the twenty-fourth transistor is electrically connected with the eighth node; a control electrode of the twenty-fifth transistor is electrically connected with the eighth node, a first electrode of the twenty-fifth transistor is electrically connected with the third power supply terminal, and a second electrode of the twenty-fifth transistor is electrically connected with the drive signal output terminal; a control electrode of the twenty-sixth transistor is electrically connected with the sixth node, a first electrode of the twenty-sixth transistor is electrically connected with the fourth power supply terminal, and a second electrode of the twenty-sixth transistor is electrically connected with the drive signal output terminal; a first electrode plate of the fifth capacitor is electrically connected with the seventh node, and a second electrode plate of the fifth capacitor is electrically connected with the eighth node; and a first electrode plate of the sixth capacitor is electrically connected with the eighth node, and a second electrode plate of the sixth capacitor is electrically connected with the third power supply terminal.

In an exemplary implementation mode, the shift sub-circuit includes: a first transistor to an eighth transistor, and a first capacitor and a second capacitor; a control electrode of the first transistor is electrically connected with the first clock signal terminal, a first electrode of the first transistor is electrically connected with the signal input terminal, and a second electrode of the first transistor is electrically connected with the third node; a control electrode of the second transistor is electrically connected with the third node, a first electrode of the second transistor is electrically connected with the first clock signal terminal, and a second electrode of the second transistor is electrically connected with a fourth node; a control electrode of the third transistor is electrically connected with the first clock signal terminal, a first electrode of the third transistor is electrically connected with the second power supply terminal, and a second electrode of the third transistor is electrically connected with the fourth node; a control electrode of the fourth transistor is electrically connected with the fourth node, a first electrode of the fourth transistor is electrically connected with the first power supply terminal, and a second electrode of the fourth transistor is electrically connected with the cascaded signal output terminal; a control electrode of the fifth transistor is electrically connected with a ninth node, a first electrode of the fifth transistor is electrically connected with the second clock signal terminal, and a second electrode of the fifth transistor is electrically connected with the cascaded signal output terminal; a control electrode of the sixth transistor is electrically connected with the fourth node, a first electrode of the sixth transistor is electrically connected with the first power supply terminal, and a second electrode of the sixth transistor is electrically connected with a first electrode of the seventh transistor; a control electrode of the seventh transistor is electrically connected with the second clock signal terminal, and a second electrode of the seventh transistor is electrically connected with the third node; a control electrode of the eighth transistor is electrically connected with the second power supply terminal, a first electrode of the eighth transistor is electrically connected with the third node, and a second electrode of the eighth transistor is electrically connected with the ninth node; a first electrode plate of the first capacitor is electrically connected with the ninth node, and a second electrode plate of the first capacitor is electrically connected with the cascaded signal output terminal; and a first electrode plate of the second capacitor is electrically connected with the fourth node, and a second electrode plate of the second capacitor is electrically connected with the first power supply terminal.

In an exemplary implementation mode, the output sub-circuit is further electrically connected with the third node and the fourth node in the shift sub-circuit, respectively.

In an exemplary implementation mode, the output sub-circuit includes: an eighteenth transistor to a twenty-sixth transistor, and a fifth capacitor and a sixth capacitor; a control electrode of the eighteenth transistor is electrically connected with a seventh node, a first electrode of the eighteenth transistor is electrically connected with the third node, and a second electrode of the eighteenth transistor is electrically connected with a sixth node; a control electrode of the nineteenth transistor is electrically connected with the second control signal terminal, a first electrode of the nineteenth transistor is electrically connected with the latch signal terminal, and a second electrode of the nineteenth transistor is electrically connected with a second electrode of the twentieth transistor; a control electrode of the twentieth transistor is electrically connected with the cascaded signal output terminal, and a first electrode of the twentieth transistor is electrically connected with the seventh node; a control electrode of the twenty-first transistor is electrically connected with the seventh node, a first electrode of the twenty-first transistor is electrically connected with the fourth node, and a second electrode of the twenty-first transistor is electrically connected with an eighth node; a control electrode of the twenty-second transistor is electrically connected with the fifth power supply terminal, a first electrode of the twenty-second transistor is electrically connected with the fourth power supply terminal, and a second electrode of the twenty-second transistor is electrically connected with the seventh node; a control electrode of the twenty-third transistor is electrically connected with the first control signal terminal, a first electrode of the twenty-third transistor is electrically connected with the fourth power supply terminal, and a second electrode of the twenty-third transistor is electrically connected with the seventh node; a control electrode of the twenty-fourth transistor is electrically connected with the sixth node, a first electrode of the twenty-fourth transistor is electrically connected with the third power supply terminal, and a second electrode of the twenty-fourth transistor is electrically connected with the eighth node; a control electrode of the twenty-fifth transistor is electrically connected with the eighth node, a first electrode of the twenty-fifth transistor is electrically connected with the third power supply terminal, and a second electrode of the twenty-fifth transistor is electrically connected with the drive signal output terminal; a control electrode of the twenty-sixth transistor is electrically connected with the sixth node, a first electrode of the twenty-sixth transistor is electrically connected with the fourth power supply terminal, and a second electrode of the twenty-sixth transistor is electrically connected with the drive signal output terminal; a first electrode plate of the fifth capacitor is electrically connected with the seventh node, and a second electrode plate of the fifth capacitor is electrically connected with the eighth node; and a first electrode plate of the sixth capacitor is electrically connected with the eighth node, and a second electrode plate of the sixth capacitor is electrically connected with the third power supply terminal.

In an exemplary implementation mode, the first power supply terminal and the third power supply terminal are a same signal terminal, and the second power supply terminal and the fourth power supply terminal are a same signal terminal.

In a second aspect, the present disclosure also provides a gate drive circuit, including a plurality of shift registers described above; a cascaded signal output terminal of one shift register in at least one stage shift register is electrically connected with a signal input terminal of a previous stage shift register.

In a third aspect, the present disclosure also provides a display apparatus, including the gate drive circuit described above.

In a fourth aspect, the present disclosure also provides a drive method of a shift register, which is configured to drive the shift register described above, the method includes: providing a signal to a cascaded signal output terminal by a shift sub-circuit under control of signals of a signal input terminal, a first clock signal terminal, a second clock signal terminal, a first power supply terminal, and a second power supply terminal; and providing a signal to a drive signal output terminal by an output sub-circuit under control of signals of the shift sub-circuit, a latch signal terminal, a first control signal terminal, a second control signal terminal, the cascaded signal output terminal, a third power supply terminal, a fourth power supply terminal, and a fifth power supply terminal.

Other aspects may be comprehended after drawings and detailed description are read and understood.

### BRIEF DESCRIPTION OF DRAWINGS

Accompany drawings are used to provide understanding of technical solutions of the present disclosure, and form a part of the specification. The accompany drawings and embodiments of the present disclosure are adopted to explain the technical solutions of the present disclosure, and do not form limitations on the technical solutions of the present disclosure.

FIG. 1 is a schematic diagram of a structure of a display apparatus.

FIG. 2A is a first schematic diagram of a planar structure of a display substrate.

FIG. 2B is a second schematic diagram of a planar structure of a display substrate.

FIG. 2C is a third schematic diagram of a planar structure of a display substrate.

FIG. 3 is a schematic diagram of a structure of a shift register according to an embodiment of the present disclosure.

FIG. 4 is a schematic diagram of a structure of another shift register.

FIG. 5A is an equivalent circuit diagram of a shift register.

FIG. 5B is an equivalent circuit diagram of another shift register.

FIG. 6 is a working timing diagram of part of shift registers.

FIG. 7 is a first schematic diagram of a structure of a display substrate.

FIG. 8 is a second schematic diagram of a structure of a display substrate.

FIG. 9 is a third schematic diagram of a structure of a display substrate.

FIG. 10 is a fourth schematic diagram of a structure of a display substrate.

FIG. 11 is a fifth schematic diagram of a structure of a display substrate.

FIG. 12 is a schematic diagram of a partial structure of the display substrate according to FIGS. 7, 9, 10, and 11.

FIG. 13 is a schematic diagram of a partial structure of the display substrate according to FIG. 8.

FIG. 14 is a schematic diagram of the display substrate according to FIGS. 7, 9, and 11 after a pattern of a semiconductor layer is formed.

FIG. 15 is a schematic diagram of the display substrate according to FIG. 8 after a pattern of a semiconductor layer is formed.

FIG. 16 is a schematic diagram of a pattern of a first conductive layer in the display substrate according to FIGS. 7, 9, and 11.

FIG. 17 is a schematic diagram of forming a pattern of a first conductive layer in the display substrate according to FIGS. 7, 9, and 11.

FIG. 18 is a schematic diagram of a pattern of a first conductive layer in the display substrate according to FIG. 8.

FIG. 19 is a schematic diagram of forming a pattern of a first conductive layer in the display substrate according to FIG. 8.

FIG. 20 is a schematic diagram of a pattern of a second conductive layer in the display substrate according to FIGS. 7, 9, and 11.

FIG. 21 is a schematic diagram of forming a pattern of a second conductive layer in the display substrate according to FIGS. 7, 9, and 11.

FIG. 22 is a schematic diagram of a pattern of a second conductive layer in the display substrate according to FIG. 8.

FIG. 23 is a schematic diagram of forming a pattern of a second conductive layer in the display substrate according to FIG. 8.

FIG. 24 is a schematic diagram of forming a pattern of a third insulation layer in the display substrate according to FIGS. 7, 10, and 11.

FIG. 25 is a schematic diagram of forming a pattern of a third insulation layer in the display substrate according to FIG. 8.

FIG. 26 is a schematic diagram of forming a pattern of a third insulation layer in the display substrate according to FIG. 9.

FIG. 27 is a schematic diagram of a pattern of a third conductive layer in the display substrate according to FIG. 7.

FIG. 28 is a schematic diagram of the display substrate according to FIG. 7 after a pattern of a third conductive layer is formed.

FIG. 29 is a schematic diagram of a pattern of a third conductive layer in the display substrate according to FIG. 8.

FIG. 30 is a schematic diagram of the display substrate according to FIG. 8 after a pattern of a third conductive layer is formed.

FIG. 31 is a schematic diagram of a pattern of a third conductive layer in the display substrate according to FIG. 9.

FIG. 32 is a schematic diagram of the display substrate according to FIG. 9 after a pattern of a third conductive layer is formed.

FIG. 33 is a schematic diagram of a pattern of a third conductive layer in the display substrate according to FIGS. 10 and 11.

FIG. 34 is a schematic diagram of the display substrate according to FIGS. 10 and 11 after a pattern of a third conductive layer is formed.

FIG. 35 is a schematic diagram of the display substrate according to FIG. 7 after a pattern of a fourth insulation layer is formed.

FIG. 36 is a schematic diagram of the display substrate according to FIG. 8 after a pattern of a fourth insulation layer is formed.

FIG. 37 is a schematic diagram of the display substrate according to FIG. 9 after a pattern of a fourth insulation layer is formed.

FIG. 38 is a schematic diagram of the display substrate according to FIG. 10 after a pattern of a fourth insulation layer is formed.

FIG. 39 is a schematic diagram of the display substrate according to FIG. 11 after a pattern of a fourth insulation layer is formed.

FIG. 40 is a schematic diagram of a pattern of a fourth conductive layer in the display substrate according to FIGS. 7 and 8.

FIG. 41 is a schematic diagram of the display substrate according to FIG. 7 after a pattern of a fourth conductive layer is formed.

FIG. 42 is a schematic diagram of the display substrate according to FIG. 8 after a pattern of a fourth conductive layer is formed.

FIG. 43 is a schematic diagram of a pattern of a fourth conductive layer in the display substrate according to FIGS. 9 and 10.

FIG. 44 is a schematic diagram of the display substrate according to FIG. 9 after a pattern of a fourth conductive layer is formed.

FIG. 45 is a schematic diagram of the display substrate according to FIG. 10 after a pattern of a fourth conductive layer is formed.

FIG. 46 is a schematic diagram of a pattern of a fourth conductive layer in the display substrate according to FIG. 11.

FIG. 47 is a schematic diagram of the display substrate according to FIG. 11 after a pattern of a fourth conductive layer is formed.

FIG. 48 is a schematic diagram of the display substrate according to FIG. 9 after a pattern of a first planarization layer is formed.

FIG. 49 is a schematic diagram of the display substrate according to FIG. 10 after a first planarization layer is formed.

FIG. 50 is a schematic diagram of the display substrate according to FIG. 11 after a pattern of a first planarization layer is formed.

FIG. 51 is a schematic diagram of a pattern of a fifth conductive layer in the display substrate according to FIG. 9.

FIG. 52 is a schematic diagram of the display substrate according to FIG. 9 after a pattern of a fifth conductive layer is formed.

FIG. 53 is a schematic diagram of a pattern of a fifth conductive layer in the display substrate according to FIG. 10.

FIG. 54 is a schematic diagram of the display substrate according to FIG. 10 after a pattern of a fifth conductive layer is formed.

FIG. 55 is a schematic diagram of a pattern of a fifth conductive layer in the display substrate according to FIG. 11.

FIG. 56 is a schematic diagram of the display substrate according to FIG. 11 after a pattern of a fifth conductive layer is formed.

FIG. 57 is a schematic diagram of a structure of a shift register according to the present disclosure.

FIG. 58 is a first equivalent circuit diagram of a shift sub-circuit.

FIG. 59 is a second equivalent circuit diagram of a shift sub-circuit.

FIG. 60 is a first equivalent circuit diagram of an output sub-circuit.

FIG. 61 is a third equivalent circuit diagram of a shift sub-circuit.

FIG. 62 is a second equivalent circuit diagram of an output sub-circuit.

FIG. 63 is a first equivalent circuit diagram of a shift register.

FIG. 64 is a second equivalent circuit diagram of a shift register.

FIG. 65 is a third equivalent circuit diagram of a shift register.

FIG. 66 is a working timing diagram of the shift sub-circuit according to FIGS. 58 and 59.

FIG. 67 is a working timing diagram of the shift sub-circuit according to FIG. 61.

### DETAILED DESCRIPTION

To make objectives, technical solutions, and advantages of the present disclosure clearer, the embodiments of the present disclosure will be described in detail below with reference to the accompany drawings. It is to be noted that implementation modes may be implemented in multiple different forms. Those of ordinary skills in the art may easily understand such a fact that modes and contents may be transformed into various forms without departing from the purpose and scope of the present disclosure. Therefore, the present disclosure should not be explained as being limited to the contents recorded in the following implementation modes only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements with reference to the accompanying drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, an “electrical connection” includes a case that constituent elements are connected together through an element with a certain electrical action. An “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

In the specification, “arranged in a same layer” described refers to a structure formed by patterning two (or more than two) structures through a same patterning process, and their materials may be the same or different. For example, materials of precursors for forming multiple structures arranged in a same layer are the same, and final materials may be the same or different.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, deformation, etc.

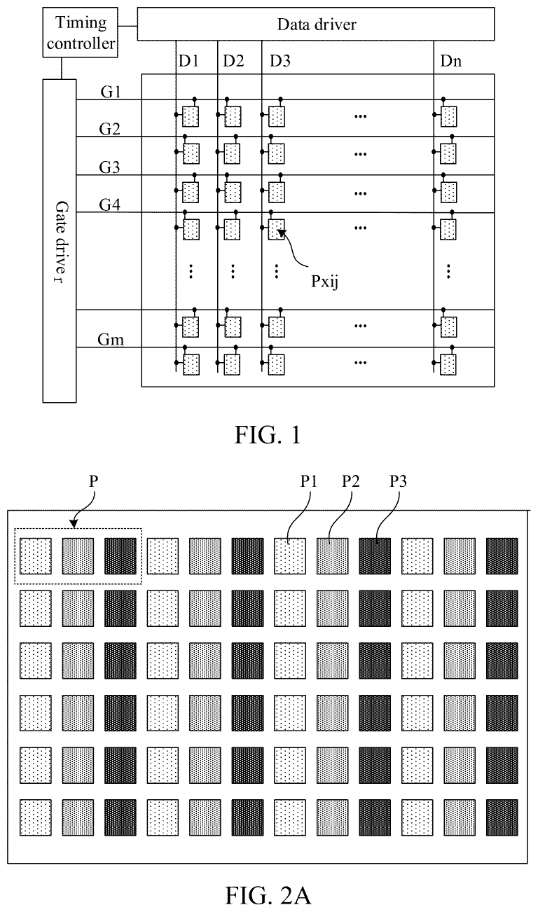

FIG. 1 is a schematic diagram of a structure of a display apparatus. As shown in FIG. 1, the display apparatus may include a timing controller, a data driver, a gate driver, and a pixel array. The timing controller is connected with the data driver and the gate driver respectively, the data driver is connected with a plurality of data signal lines (D1 to Dn) respectively, and the gate driver is connected with a plurality of gate signal lines (G1 to Gm) respectively. The pixel array may include multiple sub-pixels Pxij, wherein i and j may be natural numbers. At least one sub-pixel Pxij may include a circuit unit and a light emitting device connected with the circuit unit. The circuit unit may include a pixel drive circuit, and the pixel drive circuit may be connected with a gate signal line, and a data signal line respectively.

In an exemplary implementation mode, the timing controller may provide the data driver with a grayscale value and a control signal which are suitable for a specification of the data driver, provide the scan driver with a clock signal and a scan start signal and the like which are suitable for a specification of the scan driver, and provide the light emitting driver with a clock signal and an emission stop signal and the like which are suitable for a specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number.

In an exemplary implementation mode, the gate driver may generate a scan signal to be provided to the gate signal lines G1, G2, G3, . . . , to Gm by receiving the clock signal, a gate start signal, and the like from the timing controller. For example, the scan driver may sequentially provide a scan signal with an on-level pulse to the gate signal lines G1 to Gm. For example, the gate driver may be constructed in a form of a shift register and may generate a scan signal in a manner in which a scan start signal provided in a form of an on-level pulse is transmitted to a next-stage circuit sequentially under control of the clock signal, wherein m may be a natural number.

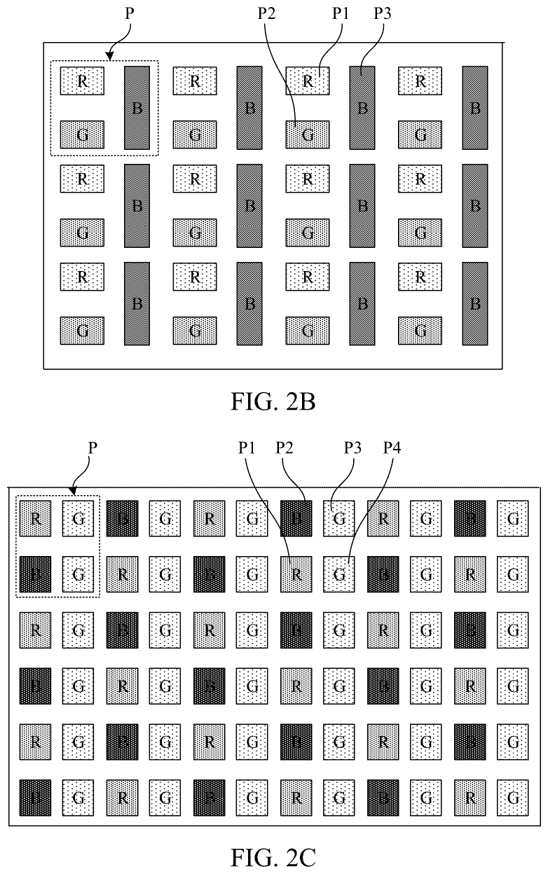

FIG. 2A is a first schematic diagram of a planar structure of a display substrate, FIG. 2B is a second schematic diagram of a planar structure of a display substrate, and FIG. 2C is a third schematic diagram of a planar structure of a display substrate. As shown in FIGS. 2A to 2C, the display substrate may include multiple pixel units P arranged in a matrix, at least one of the multiple pixel units P includes a first sub-pixel P1 emitting light of a first color, a second sub-pixel P2 emitting light of a second color, and a third sub-pixel P3 emitting light of a third color. The first sub-pixel P1, the second sub-pixel P2, and the third sub-pixel P3 each includes a pixel drive circuit and a light emitting device. Pixel drive circuits in the first sub-pixel P1, the second sub-pixel P2, and the third sub-pixel P3 are connected with a gate signal line and a data signal line respectively. The pixel drive circuit is configured to receive a data voltage transmitted by the data signal line and output a corresponding current to the light emitting device under control of the gate signal line. Light emitting devices in the first sub-pixel P1, the second sub-pixel P2, and the third sub-pixel P3 are respectively connected with a pixel drive circuit of a sub-pixel in which a light emitting device is located, and the light emitting device is configured to emit light with corresponding brightness in response to a current outputted by the pixel drive circuit of the sub-pixel in which the light emitting device is located.

In an exemplary implementation mode, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light.

In an exemplary implementation mode, a sub-pixel may be in a shape of a rectangle, a rhombus, a pentagon, or a hexagon. Three sub-pixels may be arranged side by side horizontally, side by side vertically, or in a delta-shaped arrangement, the present disclosure is not limited thereto.

In an exemplary implementation mode, a pixel unit may include three sub-pixels, and the three sub-pixels may be arranged side by side horizontally, side by side vertically, or in a delta-shaped arrangement, and the present disclosure is not limited thereto. FIG. 2A and FIG. 2B are illustrated by taking a pixel unit including three sub-pixels as an example. The three sub-pixels in FIG. 2A are arranged side by side horizontally, and the three sub-pixels in FIG. 2B are arranged in a delta-shaped arrangement.

In an exemplary implementation mode, a pixel unit may include four sub-pixels, and the four sub-pixels may be arranged in a manner to stand side by side horizontally, in a manner to stand side by side vertically, or in a manner of forming a square, which is not limited here in the present disclosure. FIG. 2C is illustrated by taking a case in which a pixel unit includes four sub-pixels and the four sub-pixels are arranged in a manner of forming a square as an example.

In an exemplary implementation mode, the pixel drive circuit may have a structure of 3T1C, 4T1C, 5T1C, 5T2C, 6T1C, 7T1C, or 8T1C, which is not limited in the present disclosure.

In an exemplary implementation mode, the pixel drive circuit may include seven transistors (a first pixel transistor to a seventh pixel transistor) and one storage capacitor C, the pixel drive circuit may include seven pixel transistors (a first pixel transistor to a seventh pixel transistor) and one storage capacitor C, and the pixel drive circuit may be connected with seven signal lines (a data signal line, a first scan signal line, a second scan signal line, a light emitting signal line, an initial signal line, a first power supply line, and a second power supply line).

In an exemplary implementation mode, the pixel drive circuit may include a first node, a second node, and a third node. The first node is connected with a first electrode of the third pixel transistor, a second electrode of the fourth pixel transistor, and a second electrode of the fifth pixel transistor respectively. The second node is connected with a second electrode of a first reset pixel transistor, a first electrode of the second pixel transistor, a control electrode of the third pixel transistor, and a second terminal of the storage capacitor respectively. The third node is connected with a second electrode of the second pixel transistor, a second electrode of the third pixel transistor, and a first electrode of the sixth pixel transistor respectively.

In an exemplary implementation mode, a first terminal of the storage capacitor is connected with the first power supply line, and the second terminal of the storage capacitor is connected with the second node, i.e., the second terminal of the storage capacitor is connected with the control electrode of the third pixel transistor.

The control electrode of the first pixel transistor is connected with the second scan signal line, the first electrode of the first pixel transistor is connected with the initial signal line, and the second electrode of the first pixel transistor is connected with the second node. When a scan signal with an on-level is applied to the second scan signal line, the first pixel transistor transmits an initialization voltage to the control electrode of the third pixel transistor, so as to initialize a charge amount of the control electrode of the third pixel transistor.

A control electrode of the second pixel transistor is connected with the first scan signal line, a first electrode of the second pixel transistor is connected with the second node, and a second electrode of the second pixel transistor is connected with the third node. When a scan signal with an on-level is applied to the first scan signal line, the second pixel transistor enables the control electrode of the third pixel transistor to be connected with the second electrode of the third transistor.

The control electrode of the third pixel transistor is connected with the second node, i.e., the control electrode of the third pixel transistor is connected with the second terminal of the storage capacitor, a first electrode of the third pixel transistor is connected with the first node, and the second electrode of the third pixel transistor is connected with the third node. The third pixel transistor may be referred to as a drive pixel transistor, and the third pixel transistor determines a magnitude of a drive current flowing between the first power supply line and the second power supply line according to a potential difference between the control electrode and the first electrode of the third pixel transistor.

A control electrode of the fourth pixel transistor is connected with the first scan signal line, a first electrode of the fourth pixel transistor is connected with the data signal line, and a second electrode of the fourth pixel transistor is connected with the first node. The fourth pixel transistor may be referred to as a switching pixel transistor, a scan pixel transistor, etc., and the fourth pixel transistor enables a data voltage of the data signal line to be input into the pixel drive circuit when a scan signal with an on-level is applied to the first scan signal line.

A control electrode of the fifth pixel transistor is connected with the light emitting signal line, a first electrode of the fifth pixel transistor is connected with the first power supply line, and a second electrode of the fifth pixel transistor is connected with the first node. A control electrode of the sixth pixel transistor is connected with the light emitting signal line, a first electrode of the sixth pixel transistor is connected with the third node, and a second electrode of the sixth pixel transistor is connected with a first electrode of a light emitting device. The fifth pixel transistor and the sixth pixel transistor may be referred to as light emitting pixel transistors. When a light emitting signal with an on-level is applied to the light emitting signal line, the fifth pixel transistor and the sixth pixel transistor enable the light emitting device to emit light by forming a drive current path between the first power supply line and the second power supply line.

A control electrode of the seventh pixel transistor is connected with the first scan signal line, a first electrode of the seventh pixel transistor is connected with the initial signal line, and a second electrode of the seventh pixel transistor is connected with a first electrode of the light emitting device. When a scan signal with an on-level is applied to the first scan signal line, the seventh pixel transistor transmits an initialization voltage to the first electrode of the light emitting device so as to initialize a charge amount accumulated in the first electrode of the light emitting device or release a charge amount accumulated in the first electrode of the light emitting device.

Pixel transistors may be classified into N-type pixel transistors and P-type pixel transistors according to characteristics of the pixel transistors. When a pixel transistor is a P-type pixel transistor, its turn-on voltage is a low-level voltage (e.g., 0 V, −5 V, −10 V, or another suitable voltage), and its turn-off voltage is a high-level voltage (e.g., 5 V, 10 V, or another suitable voltage). When a pixel transistor is an N-type pixel transistor, its turn-on voltage is a high-level voltage (e.g., 5 V, 10 V, or another suitable voltage), and its turn-off voltage is a low-level voltage (e.g., 0 V, −5 V, −10 V, or another suitable voltage).

In an exemplary implementation mode, the first reset pixel transistor to the seventh pixel transistor may be P-type pixel transistors or may be N-type pixel transistors. Use of a same type of pixel transistors in a pixel drive circuit may simplify a process flow, reduce a process difficulty of a display panel, and improve a product yield. In some possible implementation modes, the first reset pixel transistor to the seventh pixel transistor may include a P-type pixel transistor and an N-type pixel transistor.

In an exemplary implementation mode, for the first rest pixel transistor to the seventh pixel transistor, low temperature poly silicon thin film pixel transistors may be used, or oxide thin film pixel transistors may be used, or both a low temperature poly silicon thin film pixel transistor and an oxide thin film pixel transistor may be used. An active layer of a low temperature poly silicon thin film pixel transistor is made of Low Temperature Poly Silicon (LTPS for short), and an active layer of an oxide thin film pixel transistor is made of an oxide semiconductor (Oxide). A Low temperature poly silicon thin film pixel transistor has advantages such as a high migration rate and fast charging, and an oxide thin film pixel transistor has advantages such as a low leakage current. The low temperature poly silicon thin film pixel transistor and the oxide thin film pixel transistor are integrated on one display substrate to form a Low Temperature Polycrystalline Oxide (LTPO for short) display substrate, so that advantages of both the low temperature poly silicon thin film pixel transistor and the oxide thin film pixel transistor may be utilized, low-frequency drive may be achieved, power consumption may be decreased, and display quality may be improved.

In an exemplary implementation mode, the first scan signal line, the second scan signal line, the light emitting signal line, and the initial signal line may extend along a horizontal direction, and the second power supply line, the first power supply line, and the data signal line may extend along a vertical direction.

In an exemplary implementation mode, the light emitting device may be an Organic Light Emitting Diode (OLED) including a first electrode (anode), an organic emitting layer, and a second electrode (cathode) that are stacked.

In an exemplary implementation mode, a working process of the pixel drive circuit may include following stages.

In a first stage, referred to as a reset stage, a signal of the second scan signal line is a low-level signal, and signals of the first scan signal line and the light emitting signal line are high-level signals. The signal of the second scan signal line is the low-level signal so that a first transistor is turned on, and a signal of the initial signal line is provided to the second node to initialize (reset) the storage capacitor to clear original charges in the storage capacitor. The signals of the first scan signal line and the light emitting signal line are the high-level signals, so that a second transistor, a fourth transistor, a fifth transistor, a sixth transistor, and a seventh transistor are turned off, and no light is emitted in this stage.

In a second stage, referred to as a data writing stage or a threshold compensation stage, a signal of the first scan signal line is a low-level signal, signals of the second scan signal line and the light emitting signal line are high-level signals, and the data signal line outputs a data voltage. In this stage, the second terminal of the storage capacitor is at a low level, so a third transistor is turned on. The signal of the first scan signal line is the low-level signal, so that the second transistor, the fourth transistor, and the seventh transistor are turned on. The second transistor and the fourth transistor are turned on so that the data voltage output by the data signal line is provided to the second node through the first node, the turned-on third transistor, the third node, and the turned-on second transistor, and a difference between the data voltage output by the data signal line and a threshold voltage of the third transistor is charged into the storage capacitor, wherein a voltage at the second terminal (the second node) of the storage capacitor is Vdata−|Vth|, Vdata is the data voltage output by the data signal line, and Vth is the threshold voltage of the third transistor. The seventh transistor is turned on, so that an initialization voltage of the initial signal line is provided to a first electrode to initialize (reset) the first electrode and clear a pre-stored voltage therein, thereby completing initialization and ensuring that no light is emitted. A signal of the second scan signal line is a high-level signal, so that the first transistor is turned off. A signal of the light emitting signal line is a high-level signal, so that the fifth transistor and the sixth transistor are turned off.

In a third stage, referred to as a light emitting stage, a signal of the light emitting signal line is a low-level signal, and signals of the first scan signal line and the second scan signal line are high-level signals. The signal of the light emitting signal line is the low-level signal so that the fifth transistor and the sixth transistor are turned on, and a power supply voltage output by the first power supply line provides a drive voltage to the first electrode through the turned-on fifth transistor, the third transistor, and the sixth transistor to drive light emitting.

In a drive process of the pixel drive circuit, a drive current flowing through the third transistor (drive transistor) is determined by a voltage difference between a gate electrode and the first electrode of the third transistor. The voltage of the second node is Vdata−|Vth|, so the drive current of the third transistor is as follows.

$$I = K * {( Vgs - V t h )}^{2} == K * {[ ( V d a t a - V d d ]}^{2}$$

Herein, I is the drive current flowing through the third transistor, i.e., a drive current for driving, K is a constant, Vgs is the voltage difference between the gate electrode and the first electrode of the third transistor, Vth is the threshold voltage of the third transistor, Vdata is the data voltage output by the data signal line, and Vdd is the power voltage output by the first power supply line.

It may be seen from a derivation result of the above current formula that in the light emitting stage, the drive current of the third transistor is not affected by the threshold voltage of the third transistor. Therefore, an influence of the threshold voltage of the third transistor on the drive current is eliminated, which may ensure uniformity of display brightness of a display product, and improve an overall display effect of the display product.

In an exemplary implementation mode, the light emitting device may include any one of an Organic Light Emitting Diode (OLED), a quantum dot light emitting diode, and an inorganic light emitting diode. For example, the light emitting device may be a micron-scale light emitting device, such as a Micro Light emitting Diode (Micro LED), a Mini Light emitting Diode (Mini LED), and a Micro Organic Light Emitting Diode (Micro OLED), which are not limited in the embodiments of the present disclosure. For example, taking a case in which the light emitting device is an organic electroluminescent diode (OLED) as an example, the light emitting device may include a first electrode (for example, as an anode), an organic emitting layer, and a second electrode (for example, as a cathode) which are stacked.

In an exemplary implementation mode, the organic emitting layer may include an Emitting Layer (EML), and any one or more of following: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation mode, one or more of hole injection layers, hole transport layers, electron block layers, hole block layers, electron transport layers, and electron injection layers of all sub-pixels may be connected together to form a common layer. Emitting layers of adjacent sub-pixels may be overlapped slightly, or may be isolated.

In the display market, a Low Temperature Poly Silicon (LTPS) technology is used in most display substrates. The LTPS technology has advantages of a high resolution, a high response speed, high brightness, and a high aperture ratio. Although it is welcomed by the market, the LTPS technology also has some defects, such as a relatively high production cost and relatively large power consumption. At this time, a technical solution of Low Temperature Polycrystalline Oxide (LTPO for short) came into being. Compared with the LTPS technology, in an LTPO technology, a leakage current is smaller, pixel point response is faster, and an additional layer of an oxide is added to a display substrate, which reduces energy consumption required for exciting pixel points, thus reducing power consumption during screen display.

A display product includes a gate drive circuit and a plurality of sub-pixels. A sub-pixel includes a pixel drive circuit. When displaying a picture by the display product, the gate drive circuit generates a drive signal, and the pixel drive circuit is initialized and performs data writing under control of the drive signal, thus achieving display. When displaying by the display product, in every frame of refresh, that is, the pixel drive circuit needs to be initialized and data written in every display frame. However, for some special pictures (such as off-screen displayed picture, static picture, or infrequently updated picture, etc.), it is not necessary to initialize and write data to the pixel drive circuit in at least some display frames, and original brightness may be maintained through the pixel drive circuit with a low leakage current. A gate drive circuit of the display product generates a drive signal in every frame regardless of which picture is displayed, and repeatedly initializes and writes data to the pixel drive circuit, so that power consumption of the display product is relatively high. A shift register includes a plurality of output transistors, and gate electrodes of some of the output transistors are connected with a same node, so that the shift register cannot output sufficiently, or even if the shift register can output sufficiently, power consumption of the shift register is relatively large, thus reducing reliability of the shift register.

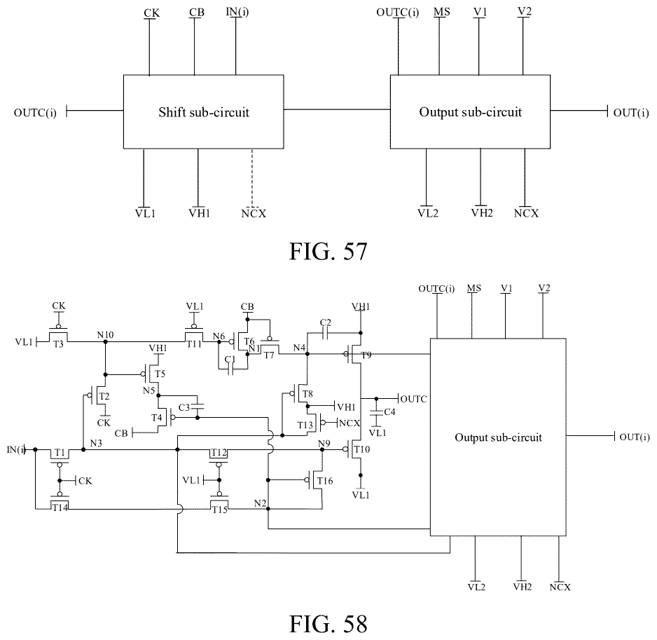

FIG. 57 is a schematic diagram of a structure of a shift register according to the present disclosure. As shown in FIG. 57, an embodiment of the present disclosure provides a shift register including a shift sub-circuit and an output sub-circuit. FIG. 57 is illustrated by taking an i-th stage shift register as an example.

As shown in FIG. 57, the shift sub-circuit may be electrically connected with a signal input terminal IN(i), a first clock signal terminal CK, a second clock signal terminal CB, a first power supply terminal VH1, a second power supply terminal VL1, and a cascaded signal output terminal OUTC(i), respectively, is configured to provide a signal to the cascaded signal output terminal OUTC(i) under control of signals of the signal input terminal IN(i), the first clock signal terminal CK, the second clock signal terminal CB, the first power supply terminal VH1, and the second power supply terminal VL1; the output sub-circuit is electrically connected with the shift sub-circuit, a latch signal terminal MS, a first control signal terminal V1, a second control signal terminal V2, a third power supply terminal VH2, a fourth power supply terminal VL2, a fifth power supply terminal NCX, the cascaded signal output terminal OUTC(i), and a drive signal output terminal OUT(i), respectively, and is configured to provide a signal to the drive signal output terminal OUT(i) under control of signals of the shift sub-circuit, the latch signal terminal MS, the first control signal terminal V1, the second control signal terminal V2, the cascaded signal output terminal OUTC(i), the third power supply terminal VH2, the fourth power supply terminal VL2, and the fifth power supply terminal NCX.

In the present disclosure, the shift sub-circuit includes: at least one shift output transistor electrically connected with the cascaded signal output terminal OUTC(i), and the output sub-circuit includes: at least one drive output transistor electrically connected with the drive signal output terminal OUT(i); the shift sub-circuit further includes at least one transistor, and the output sub-circuit further includes at least one transistor. The shift sub-circuit is provided with a third node, and a control electrode of the at least one drive output transistor is electrically connected with the third node through the at least one transistor of the output sub-circuit, and a control electrode of the at least one shift output transistor is electrically connected with the third node through the at least one transistor of the shift sub-circuit.

In the present disclosure, the control electrode of the at least one drive output transistor is electrically connected with the third node through the at least one transistor of the output sub-circuit, and the control electrode of the at least one shift output transistor is electrically connected with the third node through the at least one transistor of the shift sub-circuit, so that the control electrode of the at least one drive output transistor and the control electrode of the at least one shift output transistor are not directly connected with a same node, but are electrically connected through another transistor, so that the cascaded signal output terminal and the drive signal output terminal are driven through different nodes, which not only ensures sufficient output of the shift register, but also reduces power consumption of the shift register and improves reliability of the shift register.

In an exemplary implementation mode, as shown in FIG. 57, the shift sub-circuit is further electrically connected with the fifth power supply terminal NCX, is configured to provide a signal to the cascaded signal output terminal OUTC(i) under control of signals of the signal input terminal IN(i), the first clock signal terminal CK, the second clock signal terminal CB, the first power supply terminal VH1, and the second power supply terminal VL1, and the fifth power supply terminal NCX.

In an exemplary implementation mode, FIG. 58 is a first equivalent circuit diagram of a shift sub-circuit. As shown in FIG. 58, the shift sub-circuit may include a first transistor T1 to a sixteenth transistor T16 and a first capacitor C1 to a third capacitor C3.

As shown in FIG. 58, a control electrode of the first transistor T1 is electrically connected with the first clock signal terminal CK, a first electrode of the first transistor T1 is electrically connected with the signal input terminal IN(i), and a second electrode of the first transistor T1 is electrically connected with a third node N3. A control electrode of the second transistor T2 is electrically connected with the third node N3, a first electrode of the second transistor T2 is electrically connected with the first clock signal terminal CK, and a second electrode of the second transistor T2 is electrically connected with a tenth node N10; a control electrode of the third transistor T3 is electrically connected with the first clock signal terminal CK, a first electrode of the third transistor T3 is electrically connected with the second power supply terminal VL1, and a second electrode of the third transistor T3 is electrically connected with the tenth node N10; a control electrode of the fourth transistor T4 is electrically connected with a second node N2, a first electrode of the fourth transistor T4 is electrically connected with the second clock signal terminal CB, and a second electrode of the fourth transistor T4 is electrically connected with a fifth node N5; a control electrode of the fifth transistor T5 is electrically connected with the tenth node N10, a first electrode of the fifth transistor T5 is electrically connected with the first power supply terminal VH1, and a second electrode of the fifth transistor T5 is electrically connected with the fifth node N5; a control electrode of the sixth transistor T6 is electrically connected with a sixth node N6, a first electrode of the sixth transistor T6 is electrically connected with the second clock signal terminal CB, and a second electrode of the sixth transistor T6 is electrically connected with a first node N1; a control electrode of the seventh transistor T7 is electrically connected with the second clock signal terminal CB, a first electrode of the seventh transistor T7 is electrically connected with the first node N1, and a second electrode of the seventh transistor T7 is electrically connected with a fourth node N4; a control electrode of the eighth transistor T8 is electrically connected with the third node N3, a first electrode of the eighth transistor T8 is electrically connected with the first power supply terminal VH1, and a second electrode of the eighth transistor T8 is electrically connected with the fourth node N4; a control electrode of the ninth transistor T9 is electrically connected with the fourth node N4, a first electrode of the ninth transistor T9 is electrically connected with the first power supply terminal VH1, and a second electrode of the ninth transistor T9 is electrically connected with the cascaded signal output terminal OUTC(i); a gate electrode of the tenth transistor T10 is electrically connected with a ninth node N9, a first electrode of the tenth transistor T10 is electrically connected with the second power supply terminal VL1, and a second electrode of the tenth transistor T10 is electrically connected with the cascaded signal output terminal OUTC(i); a control electrode of the eleventh transistor T11 is electrically connected with the second power supply terminal VL1, a first electrode of the eleventh transistor T11 is electrically connected with the tenth node N10, and a second electrode of the eleventh transistor T11 is electrically connected with the sixth node N6; a control electrode of the twelfth transistor T12 is electrically connected with the second power supply terminal VL1, a first electrode of the twelfth transistor T12 is electrically connected with the third node N3, and a second electrode of the twelfth transistor T12 is electrically connected with the ninth node N9; a control electrode of the thirteenth transistor T13 is electrically connected with the fifth power supply terminal NCX, a first electrode of the thirteenth transistor T13 is electrically connected with the first power supply terminal VH1, and a second electrode of the thirteenth transistor T13 is electrically connected with the third node N3; a control electrode of the fourteenth transistor T14 is electrically connected with the first clock signal terminal CK, a first electrode of the fourteenth transistor T14 is electrically connected with the signal input terminal IN(i), and a second electrode of the fourteenth transistor T14 is electrically connected with a first electrode of the fifteenth transistor T15; a control electrode of the fifteenth transistor T15 is electrically connected with the second power supply terminal VL1, and a second electrode of the fifteenth transistor T15 is electrically connected with the second node N2; a control electrode of the sixteenth transistor T16 is electrically connected with the second node N2, a first electrode of the sixteenth transistor T16 is electrically connected with the ninth node N9, and a second electrode of the sixteenth transistor T16 is electrically connected with the second node N2; a first electrode plate of the first capacitor C1 is electrically connected with the sixth node N6, and a second electrode plate of the first capacitor C1 is electrically connected with the first node N1; a first electrode plate of the second capacitor C2 is electrically connected with the fourth node N4, and a second electrode plate of the second capacitor C2 is electrically connected with the first power supply terminal VH1; a first electrode plate of the third capacitor C3 is electrically connected with the second node N2, and a second electrode plate of the third capacitor C3 is electrically connected with the fifth node N5.

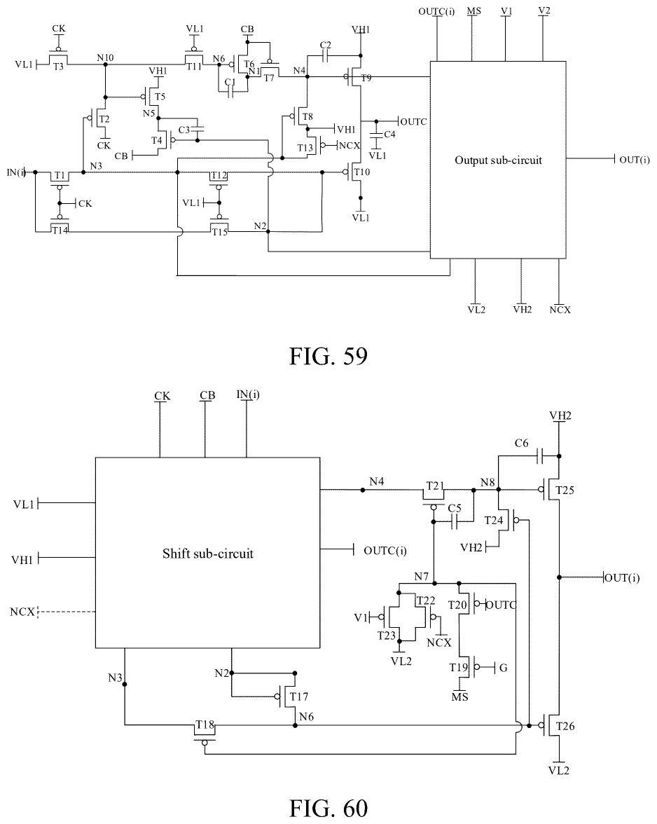

In an exemplary implementation mode, FIG. 59 is a second equivalent circuit diagram of a shift sub-circuit. As illustrated in FIG. 59, the shift sub-circuit may include a first transistor T1 to a fifteenth transistor T15 and a first capacitor C1 to a third capacitor C3.

As shown in FIG. 59, a control electrode of the first transistor T1 is electrically connected with the first clock signal terminal CK, a first electrode of the first transistor T1 is electrically connected with the signal input terminal IN(i), and a second electrode of the first transistor T1 is electrically connected with a third node N3; a control electrode of the second transistor T2 is electrically connected with the third node N3, a first electrode of the second transistor T2 is electrically connected with the first clock signal terminal CK, and a second electrode of the second transistor T2 is electrically connected with a tenth node N10; a control electrode of the third transistor T3 is electrically connected with the first clock signal terminal CK, a first electrode of the third transistor T3 is electrically connected with the second power supply terminal VL1, and a second electrode of the third transistor T3 is electrically connected with the tenth node N10; a control electrode of the fourth transistor T4 is electrically connected with a second node N2, a first electrode of the fourth transistor T4 is electrically connected with the second clock signal terminal CB, and a second electrode of the fourth transistor T4 is electrically connected with a fifth node N5; a control electrode of the fifth transistor T5 is electrically connected with the tenth node N10, a first electrode of the fifth transistor T5 is electrically connected with the first power supply terminal VH1, and a second electrode of the fifth transistor T5 is electrically connected with the fifth node N5; a control electrode of the sixth transistor T6 is electrically connected with a sixth node N6, a first electrode of the sixth transistor T6 is electrically connected with the second clock signal terminal CB, and a second electrode of the sixth transistor T6 is electrically connected with a first node N1; a control electrode of the seventh transistor T7 is electrically connected with the second clock signal terminal CB, a first electrode of the seventh transistor T7 is electrically connected with the first node N1, and a second electrode of the seventh transistor T7 is electrically connected with a fourth node N4; a control electrode of the eighth transistor T8 is electrically connected with the third node N3, a first electrode of the eighth transistor T8 is electrically connected with the first power supply terminal VH1, and a second electrode of the eighth transistor T8 is electrically connected with the fourth node N4; a control electrode of the ninth transistor T9 is electrically connected with the fourth node N4, a first electrode of the ninth transistor T9 is electrically connected with the first power supply terminal VH1, and a second electrode of the ninth transistor T9 is electrically connected with the cascaded signal output terminal OUTC(i); a control electrode of the tenth transistor T10 is electrically connected with the second node N2, a first electrode of the tenth transistor T10 is electrically connected with the second power supply terminal VL1, and a second electrode of the tenth transistor T10 is electrically connected with the cascaded signal output terminal OUTC(i); a control electrode of the eleventh transistor T11 is electrically connected with the second power supply terminal VL1, a first electrode of the eleventh transistor T11 is electrically connected with the tenth node N10, and a second electrode of the eleventh transistor T11 is electrically connected with the sixth node N6; a control electrode of the twelfth transistor T12 is electrically connected with the second power supply terminal VL1, a first electrode of the twelfth transistor T12 is electrically connected with the third node N3, and a second electrode of the twelfth transistor T12 is electrically connected with the second node N2; a control electrode of the thirteenth transistor T13 is electrically connected with the fifth power supply terminal NCX, a first electrode of the thirteenth transistor T13 is electrically connected with the first power supply terminal VH1, and a second electrode of the thirteenth transistor T13 is electrically connected with the third node N3; a control electrode of the fourteenth transistor T14 is electrically connected with the first clock signal terminal CK, a first electrode of the fourteenth transistor T14 is electrically connected with the signal input terminal IN(i), and a second electrode of the fourteenth transistor T14 is electrically connected with a first electrode of the fifteenth transistor T15; a control electrode of the fifteenth transistor T15 is electrically connected with the second power supply terminal VL1, and a second electrode of the fifteenth transistor T15 is electrically connected with the second node N2; a first electrode plate of the first capacitor C1 is electrically connected with the sixth node N6, and a second electrode plate of the first capacitor C1 is electrically connected with the first node N1; a first electrode plate of the second capacitor C2 is electrically connected with the fourth node N4, and a second electrode plate of the second capacitor C2 is electrically connected with the first power supply terminal VH1; a first electrode plate of the third capacitor C3 is electrically connected with the second node N2, and a second electrode plate of the third capacitor C3 is electrically connected with the fifth node N5.

In an exemplary implementation mode, the sixteenth transistor T16 and a seventeenth transistor T17 may transmit a signal of the signal input terminal IN to a control electrode of a twenty-sixth transistor T26, which may further ensure stability of the signal of the control electrode of the twenty-sixth transistor T26, and ensure stability of a signal output by the drive signal output terminal of the shift register.

In an exemplary implementation mode, as shown in FIGS. 58 and 59, the shift sub-circuit may further include a fourth capacitor C4.

As shown in FIGS. 58 and 59, a first electrode plate of the fourth capacitor C4 is electrically connected with the second power supply terminal VL1, and a second electrode plate of the fourth capacitor C4 is electrically connected with the cascaded signal output terminal OUTC(i).

In an exemplary implementation mode, the first control signal terminal V1 may be electrically connected with the fifth node N5.

In an exemplary implementation mode, the second control signal terminal V2 may be electrically connected with a first node N1 in a previous stage shift register of a current stage shift register.

In an exemplary implementation mode, as shown in FIGS. 58 and 59, the output sub-circuit is electrically connected with the second node N2, the third node N3, and the fourth node N4 in the shift register, respectively.

In an exemplary implementation mode, FIG. 60 is a first equivalent circuit diagram of an output sub-circuit. As shown in FIG. 60, when the shift sub-circuit is the shift sub-circuit provided in FIGS. 58 and 59, the output sub-circuit may include a seventeenth transistor T17 to a twenty-sixth transistor T26, and a fifth capacitor C5 and a sixth capacitor C6.

As shown in FIG. 60, a control electrode and a first electrode of the seventeenth transistor T17 are electrically connected with the second node N2, respectively, and a second electrode of the seventeenth transistor T17 is electrically connected with the sixth node N6; a control electrode of the eighteenth transistor T18 is electrically connected with a seventh node N7, a first electrode of the eighteenth transistor T18 is electrically connected with the third node N3, and a second electrode of the eighteenth transistor T18 is electrically connected with the sixth node N6; a control electrode of the nineteenth transistor T19 is electrically connected with the second control signal terminal V2, a first electrode of the nineteenth transistor T19 is electrically connected with the latch signal terminal MS, and a second electrode of the nineteenth transistor T19 is electrically connected with a second electrode of the twentieth transistor T20; a control electrode of the twentieth transistor T20 is electrically connected with the cascaded signal output terminal OUTC(i), and a first electrode of the twentieth transistor T20 is electrically connected with the seventh node N7; a control electrode of the twenty-first transistor T21 is electrically connected with the seventh node N7, a first electrode of the twenty-first transistor T21 is electrically connected with the fourth node N4, and a second electrode of the twenty-first transistor T21 is electrically connected with an eighth node N8; a control electrode of the twenty-second transistor T22 is electrically connected with the fifth power supply terminal NCX, a first electrode of the twenty-second transistor T22 is electrically connected with the fourth power supply terminal VL2, and a second electrode of the twenty-second transistor T22 is electrically connected with the seventh node N7; a control electrode of the twenty-third transistor T23 is electrically connected with the first control signal terminal V1, a first electrode of the twenty-third transistor T23 is electrically connected with the fourth power supply terminal VL2, and a second electrode of the twenty-third transistor T23 is electrically connected with the seventh node N7; a control electrode of the twenty-fourth transistor T24 is electrically connected with the sixth node N6, a first electrode of the twenty-fourth transistor T24 is electrically connected with the third power supply terminal VH2, and a second electrode of the twenty-fourth transistor T24 is electrically connected with the eighth node N8; a control electrode of the twenty-fifth transistor T25 is electrically connected with the eighth node N8, a first electrode of the twenty-fifth transistor T25 is electrically connected with the third power supply terminal VH2, and a second electrode of the twenty-fifth transistor T25 is electrically connected with the drive signal output terminal OUT(i); a control electrode of the twenty-sixth transistor T26 is electrically connected with the sixth node N6, a first electrode of the twenty-sixth transistor T26 is electrically connected with the fourth power supply terminal VL2, and a second electrode of the twenty-sixth transistor T26 is electrically connected with the drive signal output terminal OUT(i); a first electrode plate of the fifth capacitor C5 is electrically connected with the seventh node N7, and a second electrode plate of the fifth capacitor C5 is electrically connected with the eighth node N8; a first electrode plate of the sixth capacitor C6 is electrically connected with the eighth node N8, and a second electrode plate of the sixth capacitor C6 is electrically connected with the third power supply terminal VH2.

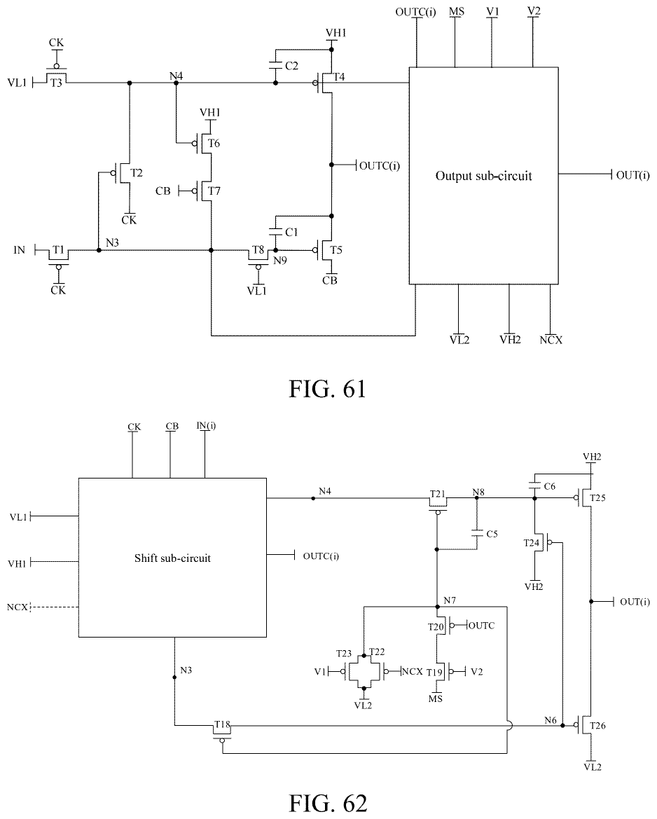

In an exemplary implementation mode, FIG. 61 is a third equivalent circuit diagram of a shift sub-circuit. As illustrated in FIG. 61, the shift sub-circuit may include a first transistor T1 to an eighth transistor T8, and a first capacitor C1 and a second capacitor C2.

As shown in FIG. 61, a control electrode of the first transistor T1 is electrically connected with the first clock signal terminal CK, a first electrode of the first transistor T1 is electrically connected with the signal input terminal IN(i), and a second electrode of the first transistor T1 is electrically connected with a third node N3; a control electrode of the second transistor T2 is electrically connected with the third node N3, a first electrode of the second transistor T2 is electrically connected with the first clock signal terminal CK, and a second electrode of the second transistor T2 is electrically connected with a fourth node N4; a control electrode of the third transistor T3 is electrically connected with the first clock signal terminal CK, a first electrode of the third transistor T3 is electrically connected with the second power supply terminal VL1, and a second electrode of the third transistor T3 is electrically connected with the fourth node N4; a control electrode of the fourth transistor T4 is electrically connected with the fourth node N4, a first electrode of the fourth transistor T4 is electrically connected with the first power supply terminal VH1, and a second electrode of the fourth transistor T4 is electrically connected with the cascaded signal output terminal OUTC(i); a control electrode of the fifth transistor T5 is electrically connected with a ninth node N9, a first electrode of the fifth transistor T5 is electrically connected with the second clock signal terminal CB, and a second electrode of the fifth transistor T5 is electrically connected with the cascaded signal output terminal OUTC(i); a control electrode of the sixth transistor T6 is electrically connected with the fourth node N4, a first electrode of the sixth transistor T6 is electrically connected with the first power supply terminal VH1, and a second electrode of the sixth transistor T6 is electrically connected with a first electrode of the seventh transistor T7; a control electrode of the seventh transistor T7 is electrically connected with the second clock signal terminal CB, and a second electrode of the seventh transistor T7 is electrically connected with the third node N3; a control electrode of the eighth transistor T8 is electrically connected with the second power supply terminal VL1, a first electrode of the eighth transistor T8 is electrically connected with the third node N3, and a second electrode of the eighth transistor T8 is electrically connected with the ninth node N9; a first electrode plate of the first capacitor C1 is electrically connected with the ninth node N9, and a second electrode plate of the first capacitor C1 is electrically connected with the cascaded signal output terminal OUTC(i); a first electrode plate of the second capacitor C2 is electrically connected with the fourth node N4, and a second electrode plate of the second capacitor C2 is electrically connected with the first power supply terminal VH1.

In an exemplary implementation mode, when the shift sub-circuit is the shift sub-circuit provided in FIG. 61, the output sub-circuit is also electrically connected with the third node N3 and the fourth node N4 in the shift sub-circuit, respectively.

In an exemplary implementation mode, FIG. 62 is a second equivalent circuit diagram of an output sub-circuit. As shown in FIG. 62, when the shift sub-circuit is the shift sub-circuit provided in FIG. 61, the output sub-circuit includes an eighteenth transistor T18 to a twenty-sixth transistor T26, and a fifth capacitor C5 and a sixth capacitor C6.

As shown in FIG. 62, a control electrode of the eighteenth transistor T18 is electrically connected with a seventh node N7, a first electrode of the eighteenth transistor T18 is electrically connected with the third node N3, and a second electrode of the eighteenth transistor T18 is electrically connected with a sixth node N6; a control electrode of the nineteenth transistor T19 is electrically connected with the second control signal terminal V2, a first electrode of the nineteenth transistor T19 is electrically connected with the latch signal terminal MS, and a second electrode of the nineteenth transistor T19 is electrically connected with a second electrode of the twentieth transistor T20; a control electrode of the twentieth transistor T20 is electrically connected with the cascaded signal output terminal OUTC(i), and a first electrode of the twentieth transistor T20 is electrically connected with the seventh node N7; a control electrode of the twenty-first transistor T21 is electrically connected with the seventh node N7, a first electrode of the twenty-first transistor T21 is electrically connected with the fourth node N4, and a second electrode of the twenty-first transistor T21 is electrically connected with an eighth node N8; a control electrode of the twenty-second transistor T22 is electrically connected with the fifth power supply terminal NCX, a first electrode of the twenty-second transistor T22 is electrically connected with the fourth power supply terminal VL2, and a second electrode of the twenty-second transistor T22 is electrically connected with the seventh node N7; a control electrode of the twenty-third transistor T23 is electrically connected with the first control signal terminal V1, a first electrode of the twenty-third transistor T23 is electrically connected with the fourth power supply terminal VL2, and a second electrode of the twenty-third transistor T23 is electrically connected with the seventh node N7; a control electrode of the twenty-fourth transistor T24 is electrically connected with the sixth node N6, a first electrode of the twenty-fourth transistor T24 is electrically connected with the third power supply terminal VH2, and a second electrode of the twenty-fourth transistor T24 is electrically connected with the eighth node N8; a control electrode of the twenty-fifth transistor T25 is electrically connected with the eighth node N8, a first electrode of the twenty-fifth transistor T25 is electrically connected with the third power supply terminal VH2, and a second electrode of the twenty-fifth transistor T25 is electrically connected with the drive signal output terminal OUT(i); a control electrode of the twenty-sixth transistor T26 is electrically connected with the sixth node N6, a first electrode of the twenty-sixth transistor T26 is electrically connected with the fourth power supply terminal VL2, and a second electrode of the twenty-sixth transistor T26 is electrically connected with the drive signal output terminal OUT(i); a first electrode plate of the fifth capacitor C5 is electrically connected with the seventh node N7, and a second electrode plate of the fifth capacitor C5 is electrically connected with the eighth node N8; a first electrode plate of the sixth capacitor C6 is electrically connected with the eighth node N8, and a second electrode plate of the sixth capacitor C6 is electrically connected with the third power supply terminal VH2.

In an exemplary implementation mode, the first power supply terminal VH1 and the third power supply terminal VH2 are high-level power supply terminals and are configured to provide high-level power supply signals.

In an exemplary implementation mode, the first power supply terminal VH1 and the third power supply terminal VH2 may be a same signal terminal.

In an exemplary implementation mode, the second power supply terminal VL1 and the fourth power supply terminal VL2 are low-level power supply terminals and are configured to provide low-level power supply signals.

In an exemplary implementation mode, the second power supply terminal VL1 and the fourth power supply terminal VL2 may be a same signal terminal.

In an exemplary implementation mode, the twenty-fourth transistor T24 and the twenty-sixth transistor T26 are turned on at the same time, or are turned off at the same time. When the twenty-sixth transistor T26 is turned on and a low-level signal of the fourth power supply terminal VL2 is written to the drive signal output terminal OUT, the twenty-fourth transistor T24 is turned on, so that a high-level signal of the third power supply terminal VH2 is written to the eighth node N8, so that the twenty-fifth transistor T25 is turned off, and the high-level signal of the third power supply terminal VH2 cannot be written to the drive signal output terminal, which ensures output stability of the drive signal output terminal and may improve reliability of the shift register.

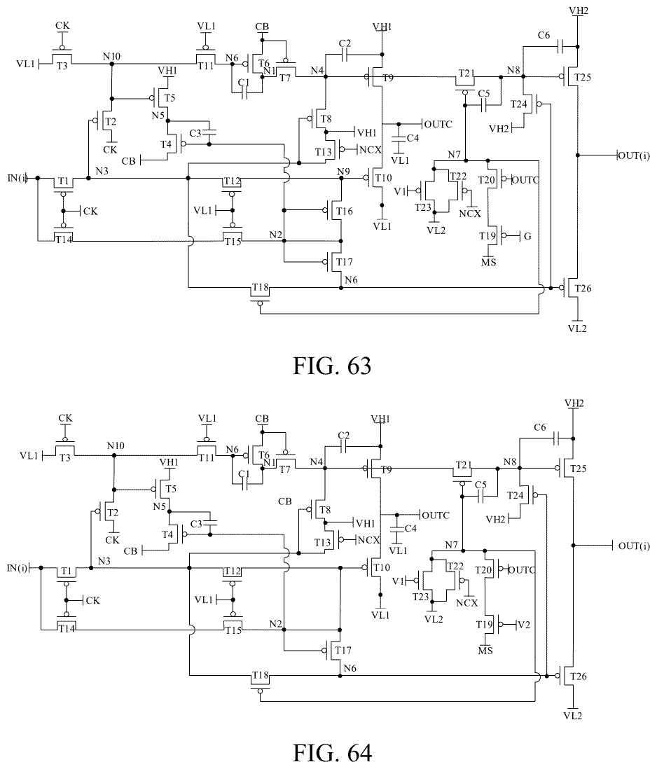

FIG. 63 is a first equivalent circuit diagram of a shift register. As shown in FIG. 63, the shift sub-circuit in the shift register includes a first transistor T1 to a sixteenth transistor T16 and a first capacitor C1 to a fourth capacitor C4, and the output sub-circuit includes a seventeenth transistor T17 to a twenty-sixth transistor T26, and a fifth capacitor C5 and a sixth capacitor C6. Herein, a control electrode of the first transistor T1 is electrically connected with the first clock signal terminal CK, a first electrode of the first transistor T1 is electrically connected with the signal input terminal IN(i), and a second electrode of the first transistor T1 is electrically connected with a third node N3; a control electrode of the second transistor T2 is electrically connected with the third node N3, a first electrode of the second transistor T2 is electrically connected with the first clock signal terminal CK, and a second electrode of the second transistor T2 is electrically connected with a tenth node N10; a control electrode of the third transistor T3 is electrically connected with the first clock signal terminal CK, a first electrode of the third transistor T3 is electrically connected with the second power supply terminal VL1, and a second electrode of the third transistor T3 is electrically connected with the tenth node N10; a control electrode of the fourth transistor T4 is electrically connected with a second node N2, a first electrode of the fourth transistor T4 is electrically connected with the second clock signal terminal CB, and a second electrode of the fourth transistor T4 is electrically connected with a fifth node N5; a control electrode of the fifth transistor T5 is electrically connected with the tenth node N10, a first electrode of the fifth transistor T5 is electrically connected with the first power supply terminal VH1, and a second electrode of the fifth transistor T5 is electrically connected with the fifth node N5; a control electrode of the sixth transistor T6 is electrically connected with a sixth node N6, a first electrode of the sixth transistor T6 is electrically connected with the second clock signal terminal CB, and a second electrode of the sixth transistor T6 is electrically connected with a first node N1; a control electrode of the seventh transistor T7 is electrically connected with the second clock signal terminal CB, a first electrode of the seventh transistor T7 is electrically connected with the first node N1, and a second electrode of the seventh transistor T7 is electrically connected with a fourth node N4; a control electrode of the eighth transistor T8 is electrically connected with the third node N3, a first electrode of the eighth transistor T8 is electrically connected with the first power supply terminal VH1, and a second electrode of the eighth transistor T8 is electrically connected with the fourth node N4; a control electrode of the ninth transistor T9 is electrically connected with the fourth node N4, a first electrode of the ninth transistor T9 is electrically connected with the first power supply terminal VH1, and a second electrode of the ninth transistor T9 is electrically connected with the cascaded signal output terminal OUTC(i); a gate electrode of the tenth transistor T10 is electrically connected with a ninth node N9, a first electrode of the tenth transistor T10 is electrically connected with the second power supply terminal VL1, and a second electrode of the tenth transistor T10 is electrically connected with the cascaded signal output terminal OUTC(i); a control electrode of the eleventh transistor T11 is electrically connected with the second power supply terminal VL1, a first electrode of the eleventh transistor T11 is electrically connected with the tenth node N10, and a second electrode of the eleventh transistor T11 is electrically connected with the sixth node N6; a control electrode of the twelfth transistor T12 is electrically connected with the second power supply terminal VL1, a first electrode of the twelfth transistor T12 is electrically connected with the third node N3, and a second electrode of the twelfth transistor T12 is electrically connected with the ninth node N9; a control electrode of the thirteenth transistor T13 is electrically connected with the fifth power supply terminal NCX, a first electrode of the thirteenth transistor T13 is electrically connected with the first power supply terminal VH1, and a second electrode of the thirteenth transistor T13 is electrically connected with the third node N3; a control electrode of the fourteenth transistor T14 is electrically connected with the first clock signal terminal CK, a first electrode of the fourteenth transistor T14 is electrically connected with the signal input terminal IN(i), and a second electrode of the fourteenth transistor T14 is electrically connected with a first electrode of the fifteenth transistor T15; a control electrode of the fifteenth transistor T15 is electrically connected with the second power supply terminal VL1, and a second electrode of the fifteenth transistor T15 is electrically connected with the second node N2; a control electrode of the sixteenth transistor T16 is electrically connected with the second node N2, a first electrode of the sixteenth transistor T16 is electrically connected with the ninth node N9, and a second electrode of the sixteenth transistor T16 is electrically connected with the second node N2; a control electrode and a first electrode of the seventeenth transistor T17 are electrically connected with the second node N2, respectively, and a second electrode of the seventeenth transistor T17 is electrically connected with the sixth node N6; a control electrode of the eighteenth transistor T18 is electrically connected with a seventh node N7, a first electrode of the eighteenth transistor T18 is electrically connected with the third node N3, and a second electrode of the eighteenth transistor T18 is electrically connected with the sixth node N6; a control electrode of the nineteenth transistor T19 is electrically connected with the second control signal terminal V2, a first electrode of the nineteenth transistor T19 is electrically connected with the latch signal terminal MS, and a second electrode of the nineteenth transistor T19 is electrically connected with a second electrode of the twentieth transistor T20; a control electrode of the twentieth transistor T20 is electrically connected with the cascaded signal output terminal OUTC(i), and a first electrode of the twentieth transistor T20 is electrically connected with the seventh node N7; a control electrode of the twenty-first transistor T21 is electrically connected with the seventh node N7, a first electrode of the twenty-first transistor T21 is electrically connected with the fourth node N4, and a second electrode of the twenty-first transistor T21 is electrically connected with an eighth node N8; a control electrode of the twenty-second transistor T22 is electrically connected with the fifth power supply terminal NCX, a first electrode of the twenty-second transistor T22 is electrically connected with the fourth power supply terminal VL2, and a second electrode of the twenty-second transistor T22 is electrically connected with the seventh node N7; a control electrode of the twenty-third transistor T23 is electrically connected with the first control signal terminal V1, a first electrode of the twenty-third transistor T23 is electrically connected with the fourth power supply terminal VL2, and a second electrode of the twenty-third transistor T23 is electrically connected with the seventh node N7; a control electrode of the twenty-fourth transistor T24 is electrically connected with the sixth node N6, a first electrode of the twenty-fourth transistor T24 is electrically connected with the third power supply terminal VH2, and a second electrode of the twenty-fourth transistor T24 is electrically connected with the eighth node N8; a control electrode of the twenty-fifth transistor T25 is electrically connected with the eighth node N8, a first electrode of the twenty-fifth transistor T25 is electrically connected with the third power supply terminal VH2, and a second electrode of the twenty-fifth transistor T25 is electrically connected with the drive signal output terminal OUT(i); a control electrode of the twenty-sixth transistor T26 is electrically connected with the sixth node N6, a first electrode of the twenty-sixth transistor T26 is electrically connected with the fourth power supply terminal VL2, and a second electrode of the twenty-sixth transistor T26 is electrically connected with the drive signal output terminal OUT(i); a first electrode plate of the first capacitor C1 is electrically connected with the sixth node N6, and a second electrode plate of the first capacitor C1 is electrically connected with the first node N1; a first electrode plate of the second capacitor C2 is electrically connected with the fourth node N4, and a second electrode plate of the second capacitor C2 is electrically connected with the first power supply terminal VH1; a first electrode plate of the third capacitor C3 is electrically connected with the second node N2, and a second electrode plate of the third capacitor C3 is electrically connected with the fifth node N5; a first electrode plate of the fourth capacitor C4 is electrically connected with the second power supply terminal VL1, and a second electrode plate of the fourth capacitor C4 is electrically connected with the cascaded signal output terminal OUTC(i); a first electrode plate of the fifth capacitor C5 is electrically connected with the seventh node N7, and a second electrode plate of the fifth capacitor C5 is electrically connected with the eighth node N8; a first electrode plate of the sixth capacitor C6 is electrically connected with the eighth node N8, and a second electrode plate of the sixth capacitor C6 is electrically connected with the third power supply terminal VH2.

FIG. 64 is a second equivalent circuit diagram of a shift register. As shown in FIG. 64, the shift sub-circuit in the shift register includes a first transistor T1 to a fifteenth transistor T15 and a first capacitor C1 to a fourth capacitor C4, and the output sub-circuit may include a seventeenth transistor T17 to a twenty-sixth transistor T26, and a fifth capacitor C5 and a sixth capacitor C6. Herein, a control electrode of the first transistor T1 is electrically connected with the first clock signal terminal CK, a first electrode of the first transistor T1 is electrically connected with the signal input terminal IN(i), and a second electrode of the first transistor T1 is electrically connected with a third node N3; a control electrode of the second transistor T2 is electrically connected with the third node N3, a first electrode of the second transistor T2 is electrically connected with the first clock signal terminal CK, and a second electrode of the second transistor T2 is electrically connected with a tenth node N10; a control electrode of the third transistor T3 is electrically connected with the first clock signal terminal CK, a first electrode of the third transistor T3 is electrically connected with the second power supply terminal VL1, and a second electrode of the third transistor T3 is electrically connected with the tenth node N10; a control electrode of the fourth transistor T4 is electrically connected with a second node N2, a first electrode of the fourth transistor T4 is electrically connected with the second clock signal terminal CB, and a second electrode of the fourth transistor T4 is electrically connected with a fifth node N5; a control electrode of the fifth transistor T5 is electrically connected with the tenth node N10, a first electrode of the fifth transistor T5 is electrically connected with the first power supply terminal VH1, and a second electrode of the fifth transistor T5 is electrically connected with the fifth node N5; a control electrode of the sixth transistor T6 is electrically connected with a sixth node N6, a first electrode of the sixth transistor T6 is electrically connected with the second clock signal terminal CB, and a second electrode of the sixth transistor T6 is electrically connected with a first node N1; a control electrode of the seventh transistor T7 is electrically connected with the second clock signal terminal CB, a first electrode of the seventh transistor T7 is electrically connected with the first node N1, and a second electrode of the seventh transistor T7 is electrically connected with a fourth node N4; a control electrode of the eighth transistor T8 is electrically connected with the third node N3, a first electrode of the eighth transistor T8 is electrically connected with the first power supply terminal VH1, and a second electrode of the eighth transistor T8 is electrically connected with the fourth node N4; a control electrode of the ninth transistor T9 is electrically connected with the fourth node N4, a first electrode of the ninth transistor T9 is electrically connected with the first power supply terminal VH1, and a second electrode of the ninth transistor T9 is electrically connected with the cascaded signal output terminal OUTC(i); a control electrode of the tenth transistor T10 is electrically connected with the second node N2, a first electrode of the tenth transistor T10 is electrically connected with the second power supply terminal VL1, and a second electrode of the tenth transistor T10 is electrically connected with the cascaded signal output terminal OUTC(i); a control electrode of the eleventh transistor T11 is electrically connected with the second power supply terminal VL1, a first electrode of the eleventh transistor T11 is electrically connected with the tenth node N10, and a second electrode of the eleventh transistor T11 is electrically connected with the sixth node N6; a control electrode of the twelfth transistor T12 is electrically connected with the second power supply terminal VL1, a first electrode of the twelfth transistor T12 is electrically connected with the third node N3, and a second electrode of the twelfth transistor T12 is electrically connected with the second node N2; a control electrode of the thirteenth transistor T13 is electrically connected with the fifth power supply terminal NCX, a first electrode of the thirteenth transistor T13 is electrically connected with the first power supply terminal VH1, and a second electrode of the thirteenth transistor T13 is electrically connected with the third node N3; a control electrode of the fourteenth transistor T14 is electrically connected with the first clock signal terminal CK, a first electrode of the fourteenth transistor T14 is electrically connected with the signal input terminal IN(i), and a second electrode of the fourteenth transistor T14 is electrically connected with a first electrode of the fifteenth transistor T15; a control electrode of the fifteenth transistor T15 is electrically connected with the second power supply terminal VL1, and a second electrode of the fifteenth transistor T15 is electrically connected with the second node N2; a control electrode and a first electrode of the seventeenth transistor T17 are electrically connected with the second node N2, respectively, and a second electrode of the seventeenth transistor T17 is electrically connected with the sixth node N6; a control electrode of the eighteenth transistor T18 is electrically connected with a seventh node N7, a first electrode of the eighteenth transistor T18 is electrically connected with the third node N3, and a second electrode of the eighteenth transistor T18 is electrically connected with the sixth node N6; a control electrode of the nineteenth transistor T19 is electrically connected with the second control signal terminal V2, a first electrode of the nineteenth transistor T19 is electrically connected with the latch signal terminal MS, and a second electrode of the nineteenth transistor T19 is electrically connected with a second electrode of the twentieth transistor T20; a control electrode of the twentieth transistor T20 is electrically connected with the cascaded signal output terminal OUTC(i), and a first electrode of the twentieth transistor T20 is electrically connected with the seventh node N7; a control electrode of the twenty-first transistor T21 is electrically connected with the seventh node N7, a first electrode of the twenty-first transistor T21 is electrically connected with the fourth node N4, and a second electrode of the twenty-first transistor T21 is electrically connected with an eighth node N8; a control electrode of the twenty-second transistor T22 is electrically connected with the fifth power supply terminal NCX, a first electrode of the twenty-second transistor T22 is electrically connected with the fourth power supply terminal VL2, and a second electrode of the twenty-second transistor T22 is electrically connected with the seventh node N7; a control electrode of the twenty-third transistor T23 is electrically connected with the first control signal terminal V1, a first electrode of the twenty-third transistor T23 is electrically connected with the fourth power supply terminal VL2, and a second electrode of the twenty-third transistor T23 is electrically connected with the seventh node N7; a control electrode of the twenty-fourth transistor T24 is electrically connected with the sixth node N6, a first electrode of the twenty-fourth transistor T24 is electrically connected with the third power supply terminal VH2, and a second electrode of the twenty-fourth transistor T24 is electrically connected with the eighth node N8; a control electrode of the twenty-fifth transistor T25 is electrically connected with the eighth node N8, a first electrode of the twenty-fifth transistor T25 is electrically connected with the third power supply terminal VH2, and a second electrode of the twenty-fifth transistor T25 is electrically connected with the drive signal output terminal OUT(i); a control electrode of the twenty-sixth transistor T26 is electrically connected with the sixth node N6, a first electrode of the twenty-sixth transistor T26 is electrically connected with the fourth power supply terminal VL2, and a second electrode of the twenty-sixth transistor T26 is electrically connected with the drive signal output terminal OUT(i); a first electrode plate of the first capacitor C1 is electrically connected with the sixth node N6, and a second electrode plate of the first capacitor C1 is electrically connected with the first node N1; a first electrode plate of the second capacitor C2 is electrically connected with the fourth node N4, and a second electrode plate of the second capacitor C2 is electrically connected with the first power supply terminal VH1; a first electrode plate of the third capacitor C3 is electrically connected with the second node N2, and a second electrode plate of the third capacitor C3 is electrically connected with the fifth node N5; a first electrode plate of the fourth capacitor C4 is electrically connected with the second power supply terminal VL1, and a second electrode plate of the fourth capacitor C4 is electrically connected with the cascaded signal output terminal OUTC(i); a first electrode plate of the fifth capacitor C5 is electrically connected with the seventh node N7, and a second electrode plate of the fifth capacitor C5 is electrically connected with the eighth node N8; a first electrode plate of the sixth capacitor C6 is electrically connected with the eighth node N8, and a second electrode plate of the sixth capacitor C6 is electrically connected with the third power supply terminal VH2.

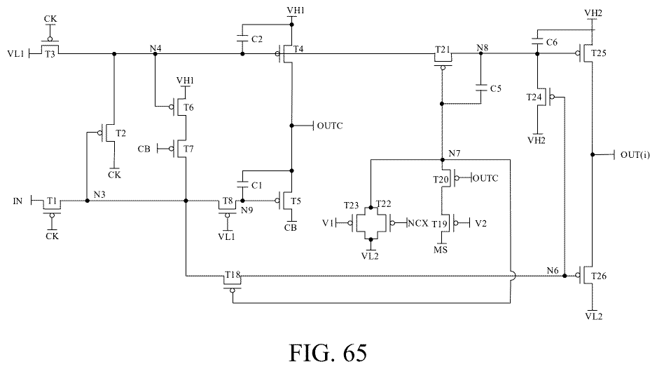

FIG. 65 is a third equivalent circuit diagram of a shift register. As shown in FIG. 65, the shift sub-circuit in the shift register includes a first transistor T1 to an eighth transistor T8, and a first capacitor C1 and a second capacitor C2, and the output sub-circuit includes an eighteenth transistor T18 to a twenty-sixth transistor T26, and a fifth capacitor C5 and a sixth capacitor C6. Herein, a control electrode of the first transistor T1 is electrically connected with the first clock signal terminal CK, a first electrode of the first transistor T1 is electrically connected with the signal input terminal IN(i), and a second electrode of the first transistor T1 is electrically connected with a third node N3; a control electrode of the second transistor T2 is electrically connected with the third node N3, a first electrode of the second transistor T2 is electrically connected with the first clock signal terminal CK, and a second electrode of the second transistor T2 is electrically connected with a fourth node N4; a control electrode of the third transistor T3 is electrically connected with the first clock signal terminal CK, a first electrode of the third transistor T3 is electrically connected with the second power supply terminal VL1, and a second electrode of the third transistor T3 is electrically connected with the fourth node N4; a control electrode of the fourth transistor T4 is electrically connected with the fourth node N4, a first electrode of the fourth transistor T4 is electrically connected with the first power supply terminal VH1, and a second electrode of the fourth transistor T4 is electrically connected with the cascaded signal output terminal OUTC(i); a control electrode of the fifth transistor T5 is electrically connected with a ninth node N9, a first electrode of the fifth transistor T5 is electrically connected with the second clock signal terminal CB, and a second electrode of the fifth transistor T5 is electrically connected with the cascaded signal output terminal OUTC(i); a control electrode of the sixth transistor T6 is electrically connected with the fourth node N4, a first electrode of the sixth transistor T6 is electrically connected with the first power supply terminal VH1, and a second electrode of the sixth transistor T6 is electrically connected with a first electrode of the seventh transistor T7; a control electrode of the seventh transistor T7 is electrically connected with the second clock signal terminal CB, and a second electrode of the seventh transistor T7 is electrically connected with the third node N3; a control electrode of the eighth transistor T8 is electrically connected with the second power supply terminal VL1, a first electrode of the eighth transistor T8 is electrically connected with the third node N3, and a second electrode of the eighth transistor T8 is electrically connected with the ninth node N9; a control electrode of the eighteenth transistor T18 is electrically connected with a seventh node N7, a first electrode of the eighteenth transistor T18 is electrically connected with the third node N3, and a second electrode of the eighteenth transistor T18 is electrically connected with a sixth node N6; a control electrode of the nineteenth transistor T19 is electrically connected with the second control signal terminal V2, a first electrode of the nineteenth transistor T19 is electrically connected with the latch signal terminal MS, and a second electrode of the nineteenth transistor T19 is electrically connected with a second electrode of the twentieth transistor T20; a control electrode of the twentieth transistor T20 is electrically connected with the cascaded signal output terminal OUTC(i), and a first electrode of the twentieth transistor T20 is electrically connected with the seventh node N7; a control electrode of the twenty-first transistor T21 is electrically connected with the seventh node N7, a first electrode of the twenty-first transistor T21 is electrically connected with the fourth node N4, and a second electrode of the twenty-first transistor T21 is electrically connected with an eighth node N8; a control electrode of the twenty-second transistor T22 is electrically connected with the fifth power supply terminal NCX, a first electrode of the twenty-second transistor T22 is electrically connected with the fourth power supply terminal VL2, and a second electrode of the twenty-second transistor T22 is electrically connected with the seventh node N7; a control electrode of the twenty-third transistor T23 is electrically connected with the first control signal terminal V1, a first electrode of the twenty-third transistor T23 is electrically connected with the fourth power supply terminal VL2, and a second electrode of the twenty-third transistor T23 is electrically connected with the seventh node N7; a control electrode of the twenty-fourth transistor T24 is electrically connected with the sixth node N6, a first electrode of the twenty-fourth transistor T24 is electrically connected with the third power supply terminal VH2, and a second electrode of the twenty-fourth transistor T24 is electrically connected with the eighth node N8; a control electrode of the twenty-fifth transistor T25 is electrically connected with the eighth node N8, a first electrode of the twenty-fifth transistor T25 is electrically connected with the third power supply terminal VH2, and a second electrode of the twenty-fifth transistor T25 is electrically connected with the drive signal output terminal OUT(i); a control electrode of the twenty-sixth transistor T26 is electrically connected with the sixth node N6, a first electrode of the twenty-sixth transistor T26 is electrically connected with the fourth power supply terminal VL2, and a second electrode of the twenty-sixth transistor T26 is electrically connected with the drive signal output terminal OUT(i); a first electrode plate of the first capacitor C1 is electrically connected with the ninth node N9, and a second electrode plate of the first capacitor C1 is electrically connected with the cascaded signal output terminal OUTC(i); a first electrode plate of the second capacitor C2 is electrically connected with the fourth node N4, and a second electrode plate of the second capacitor C2 is electrically connected with the first power supply terminal VH1; a first electrode plate of the fifth capacitor C5 is electrically connected with the seventh node N7, and a second electrode plate of the fifth capacitor C5 is electrically connected with the eighth node N8; a first electrode plate of the sixth capacitor C6 is electrically connected with the eighth node N8, and a second electrode plate of the sixth capacitor C6 is electrically connected with the third power supply terminal VH2.

In an exemplary implementation mode, as shown in FIGS. 63 and 65, in the shift register according to the present disclosure, the twenty-sixth transistor T26 (also a drive output transistor of the output sub-circuit) is electrically connected with the third node N3 through the first and second electrodes of the eighteenth transistor, the tenth transistor T10 (also a shift output sub-circuit of the shift sub-circuit) is electrically connected with the third node N3 through the first and second electrodes of the twelfth transistor, and the twelfth transistor T12 and the eighteenth transistor T18 are provided so that gate electrodes of the tenth transistor T10 and the twenty-sixth transistor T26 are not directly connected with a same node, and whether a signal of the third node N3 is written to the control electrode of the twenty-sixth transistor T26 is controlled by a signal of the seventh node of the output sub-circuit, ensuring that the drive output transistor of the output sub-circuit may be controlled individually, which may not only ensure that the shift register outputs sufficiently, but also reduce power consumption of the shift register and improve reliability of the shift register.

An embodiment of the present disclosure provides a display substrate, which has a display region and a non-display region. The display region is provided with a pixel drive circuit, and the non-display region is provided with a gate drive circuit. The gate drive circuit includes a plurality of cascaded shift registers.

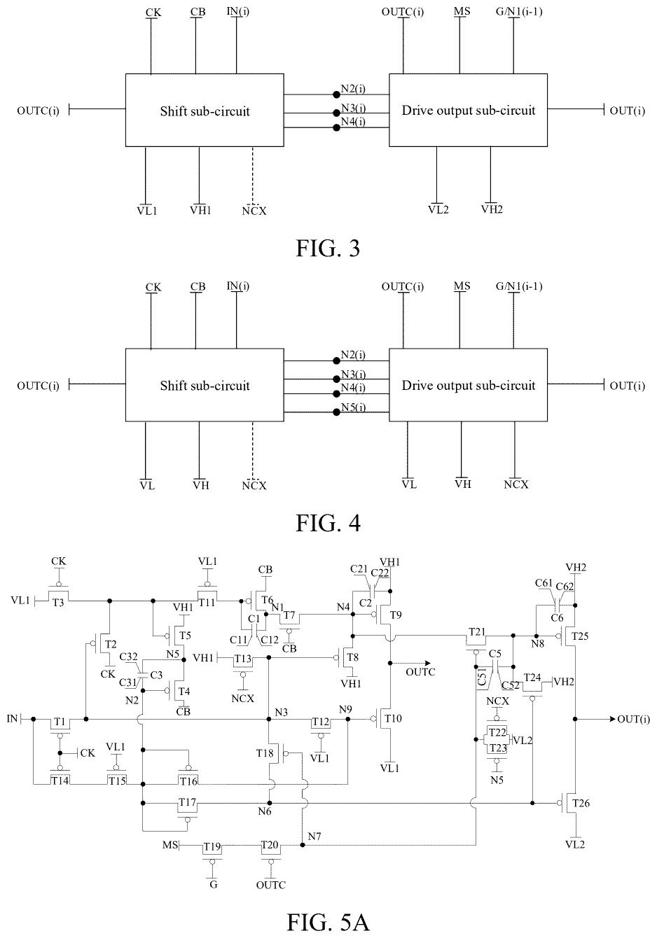

FIG. 3 is a schematic diagram of a structure of a shift register according to an embodiment of the present disclosure. As shown in FIG. 3, at least one stage shift register includes a shift sub-circuit and an output sub-circuit. The shift sub-circuit is provided with a first node N1. Herein, for an i-th stage shift register, the shift sub-circuit is connected with a signal input terminal IN(i), a first clock signal terminal CK, a second clock signal terminal CB, a first power supply terminal VH1, a second power supply terminal VL1, and a cascaded signal output terminal OUTC(i), respectively, and is configured to provide a signal of the first power supply terminal VH1 or the second power supply terminal VL1 to the cascaded signal output terminal OUTC(i) under control of signals of the signal input terminal IN(i), the first clock signal terminal CK, and the second clock signal terminal CB; the output sub-circuit is connected with a latch signal terminal MS, a control signal terminal G, a third power supply terminal VH2, a fourth power supply terminal VL2, the cascaded signal output terminal OUTC(i), and a drive signal output terminal OUT(i), respectively, and is configured to provide signals of the third power supply terminal VH2 and the fourth power supply terminal VL2 to the drive signal output terminal OUT(i) under control of signals of the latch signal terminal MS, the control signal terminal G, and the cascaded signal output terminal OUTC(i). FIG. 3 is illustrated by taking the i-th stage shift register as an example, wherein IN(i) represents a signal input terminal of the i-th stage shift register, OUTC(i) is a cascaded signal output terminal of the i-th stage shift register, OUT(i) is a drive signal output terminal of the i-th stage shift register, a second node N2 (i) is a second node of the i-th stage shift register, a third node N3 (i) is a third node of the i-th stage shift register, and a fourth node N4 (i) is a fourth node of the i-th stage shift register. FIG. 3 is illustrated by taking a case that the shift sub-circuit is the shift sub-circuit according to FIG. 58 as an example. The control signal terminal G in FIG. 3 is the first control signal terminal V1 in FIG. 58.

As shown in FIG. 3, for the i-th stage shift register, the control signal terminal G is connected with a first node N1(i−1) of a previous stage shift register of a current stage shift register, the drive signal output terminal OUT is connected with a pixel drive circuit, and the cascaded signal output terminal OUTC is connected with a signal input terminal IN of at least one stage shift register other than the current stage shift register.

In an exemplary implementation mode, since the control signal terminal G is connected with the first node of the previous stage shift register of the current stage shift register, a control signal terminal of a first-stage shift register in the shift register provides a signal through a signal line, and control signal terminals of other shift registers except the first-stage shift register are all connected with the first node of the previous stage shift register.

By configuring a shift sub-circuit to output a cascaded signal provided for other shift registers to a cascaded signal output terminal, and configuring an output sub-circuit to output a drive signal provided for a pixel drive circuit to a drive signal output terminal, the present disclosure achieves that the cascaded signal and the drive signal are output by different sub-circuits, and may control whether to output a drive signal to the pixel drive circuit while ensuring normal output of the cascaded signal.

In the above shift register according to the present disclosure, through cooperation of the shift sub-circuit and the output sub-circuit, a signal of a corresponding latch signal terminal may be latched in the output sub-circuit according to a requirement of a refresh rate of a display region, which may achieve control of a signal output by the drive signal output terminal, and achieve different refresh rates in different regions of a display panel, i.e., achieve coexistence of high and low refresh rates in a same frame picture; and the embodiment of the present disclosure is not limited to achieving different refresh rates in a fixed region of the display panel, dynamic refresh in any region may be achieved, thereby reducing power consumption of the display panel; at the same time, the output sub-circuit may make use of a phase difference of cascaded signals output by previous and next stages of the shift sub-circuit to store a control signal of the latch signal terminal in each stage shift register, so as to achieve continuous and correct output of a current stage shift register.

In an exemplary implementation mode, the shift sub-circuit is further provided with a second node N2, a third node N3, a fourth node N4, and a fifth node N5. The output sub-circuit is further connected with the second node N2, the third node N3, and the fourth node N4.

FIG. 4 is a schematic diagram of a structure of another shift register. In an exemplary implementation mode, a capacitor group further includes a fourth capacitor C4. A first electrode plate of the fourth capacitor C4 is connected with the second power supply terminal VL1, and a second electrode plate of the fourth capacitor C4 is connected with the cascaded signal output terminal OUTC(i). An arrangement of the fourth capacitor C4 may ensure stability of a signal of the cascaded signal output terminal OUTC(i), and is configured to stabilize an input of a next-stage shift register, and prevent an input signal of the next-stage shift register from being unstable due to jitter during transmission of the cascaded signal output from the cascaded signal output terminal, which may improve stability of the shift register. FIG. 4 is illustrated by taking a case that the shift sub-circuit is the shift sub-circuit according to FIG. 58 as an example. A control signal terminal G in FIG. 4 is the first control signal terminal V1 in FIG. 58, and the fifth node N5 is the second control signal terminal V2 in FIG. 58.

In an exemplary implementation mode, a range of a capacitance value of the fourth capacitor C4 is from 10 farads to 80 farads.

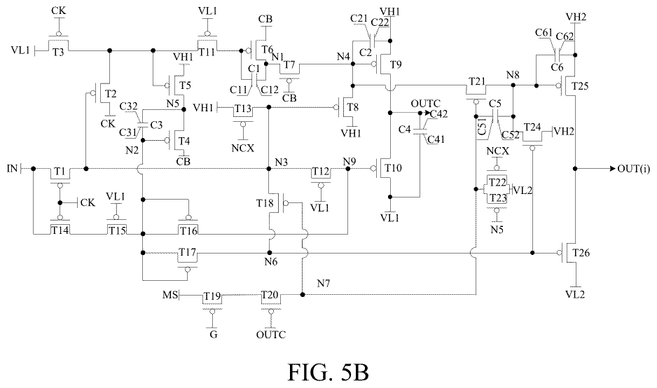

FIG. 5A is an equivalent circuit diagram of a shift register, and FIG. 5B is an equivalent circuit diagram of another shift register. As shown in FIGS. 5A and 5B, in an exemplary implementation mode, the shift sub-circuit includes a first transistor group and a capacitor group, or includes a first transistor group, a second transistor group, and a capacitor group, the first transistor group includes at least a first transistor T1 to a tenth transistor T10, the second transistor group includes at least an eleventh transistor T11 to a twelfth transistor T12, or an eleventh transistor T11 to a thirteenth transistor T13, or an eleventh transistor T11 to a sixteenth transistor T16, the capacitor group includes a first capacitor C1 to a third capacitor C3, and any one of the first capacitor C1 to a third capacitor C3 includes a first electrode plate and a second electrode plate. When the shift sub-circuit includes the thirteenth transistor T13, the shift sub-circuit is further connected with the fifth power supply terminal NCX. FIGS. 5A and 5B are illustrated by taking a case in which the shift sub-circuit includes the first transistor group, the second transistor group, and the capacitor group, and the second transistor group includes the eleventh transistor T11 to the sixteenth transistors T16 as an example. The shift sub-circuit in the shift register provided in FIG. 5A is illustrated by taking the shift sub-circuit provided in FIG. 58 but excluding the fourth capacitor C4 as an example, and the output sub-circuit is illustrated by taking the output sub-circuit provided in FIG. 60 as an example. Description is given by taking a case in which the shift sub-circuit in the shift register provided in FIG. 5B is the shift sub-circuit provided in FIG. 58, and the output sub-circuit is the output sub-circuit provided in FIG. 60 as an example. The fifth node N5 in FIGS. 5A and 5B is the first control signal terminal V1 in FIG. 58, and the control signal terminal G in FIGS. 5A and 5B is the second control signal terminal V2.

In an exemplary implementation mode, a gate electrode of the first transistor T1 is electrically connected with the first clock signal terminal CK, a first electrode of the first transistor T1 is electrically connected with the signal input terminal IN, and a second electrode of the first transistor T1 is electrically connected with the third node N3; a gate electrode of the second transistor T2 is electrically connected with the third node N3, a first electrode of the second transistor T2 is electrically connected with the first clock signal terminal CK, a second electrode of the second transistor T2 is electrically connected with a second electrode of the third transistor T3, a gate electrode of the fifth transistor T5, and a first electrode of the eleventh transistor T11; a gate electrode of the third transistor T3 is electrically connected with the first clock signal terminal CK, and a first electrode of the third transistor T3 is electrically connected with the second power supply terminal VL1; a gate electrode of the fourth transistor T4 is electrically connected with the second node N2, a first electrode of the fourth transistor T4 is electrically connected with the second clock signal terminal CB, and a second electrode of the fourth transistor T4 is electrically connected with the fifth node N5; a first electrode of the fifth transistor T5 is electrically connected with the first power supply terminal VH1, and a second electrode of the fifth transistor T5 is electrically connected with the fifth node N5; a gate electrode of the sixth transistor T6 is electrically connected with a second electrode of the eleventh transistor T11 and a first electrode plate C11 of the first capacitor, a first electrode of the sixth transistor T6 is electrically connected with the second clock signal terminal CB, and a second electrode of the sixth transistor T6 is electrically connected with the first node N1; a gate electrode of the seventh transistor T7 is electrically connected with the second clock signal terminal CB, a first electrode of the seventh transistor T7 is electrically connected with the first node N1, and a second electrode of the seventh transistor T7 is electrically connected with the fourth node N4; a gate electrode of the eighth transistor T8 is electrically connected with the third node N3, a first electrode of the eighth transistor T8 is electrically connected with the first power supply terminal VH1, and a second electrode of the eighth transistor T8 is electrically connected with the fourth node N4; a gate electrode of the ninth transistor T9 is electrically connected with the fourth node N4, a first electrode of the ninth transistor T9 is electrically connected with the first power supply terminal VH1, and a second electrode of the ninth transistor T9 is electrically connected with the cascaded signal output terminal OUTC(i); a gate electrode of the tenth transistor T10 is electrically connected with the ninth node N9, a first electrode of the tenth transistor T10 is electrically connected with the second power supply terminal VL1, and a second electrode of the tenth transistor T10 is electrically connected with the cascaded signal output terminal OUTC(i); a gate electrode of the eleventh transistor T11 is electrically connected with the second power supply terminal VL1; a gate electrode of the twelfth transistor T12 is electrically connected with the second power supply terminal VL1, a first electrode of the twelfth transistor T12 is electrically connected with the third node N3, and a second electrode of the twelfth transistor T12 is electrically connected with the ninth node N9; a gate electrode of the thirteenth transistor T13 is electrically connected with the fifth power supply terminal NCX, a first electrode of the thirteenth transistor T13 is electrically connected with the first power supply terminal VH1, and a second electrode of the thirteenth transistor T13 is electrically connected with the third node N3; a gate electrode of the fourteenth transistor T14 is electrically connected with the first clock signal terminal CK, a first electrode of the fourteenth transistor T14 is electrically connected with the signal input terminal IN, and a second electrode of the fourteenth transistor T14 is electrically connected with a first electrode of the fifteenth transistor T15; a gate electrode of the fifteenth transistor T15 is electrically connected with the second power supply terminal VL1, and a second electrode of the fifteenth transistor T15 is electrically connected with the second node N2; a gate electrode of the sixteenth transistor T16 is electrically connected with the second node N2, and a first electrode of the sixteenth transistor T16 is electrically connected with the ninth node N9; a second electrode plate of the first capacitor C1 is electrically connected with the first power supply terminal VH1, a first electrode plate C21 of the second capacitor C2 is electrically connected with the fourth node N4, a second electrode plate C22 of the second capacitor C2 is electrically connected with the first power supply terminal VH1, a first electrode plate C31 of the third capacitor C3 is electrically connected with the second node N2, and a second electrode plate C32 of the third capacitor C3 is electrically connected with the fifth node N5.

In an exemplary implementation mode, the shift sub-circuit may have a circuit structure of 10T3C, 10T4C, 12T3C, 12T4C, 13T3C, 13T4C, 16T3C, or 16T4C, which is not limited in the present disclosure.

In an exemplary implementation mode, when the shift sub-circuit has the circuit structure of 10T3C, the shift sub-circuit includes the first transistor T1 to the tenth transistor T10 and the first capacitor C1 to the third capacitor C3.

In an exemplary implementation mode, when the shift sub-circuit has the circuit structure of 10T4C, the shift sub-circuit includes the first transistor T1 to the tenth transistor T10 and the first capacitor C1 to a fourth capacitor C4.

In an exemplary implementation mode, when the shift sub-circuit has the circuit structure of 12T3C, the shift sub-circuit includes the first transistor T1 to the twelfth transistor T12 and the first capacitor C1 to the third capacitor C3.

In an exemplary implementation mode, when the shift sub-circuit has the circuit structure of 12T4C, the shift sub-circuit includes the first transistor T1 to the twelfth transistor T12, the first capacitor C1 to the third capacitor C3, and the fourth capacitor C4.

In an exemplary implementation mode, when the shift sub-circuit has the circuit structure of 13T3C, the shift sub-circuit includes the first transistor T1 to the thirteenth transistor T13 and the first capacitor C1 to the third capacitor C3.

In an exemplary implementation mode, when the shift sub-circuit has the circuit structure of 13T4C, the shift sub-circuit includes the first transistor T1 to the thirteenth transistor T13 and the first capacitor C1 to the fourth capacitor C4.

In an exemplary implementation mode, when the shift sub-circuit has the circuit structure of 16T3C, the shift sub-circuit includes the first transistor T1 to the sixteenth transistor T16 and the first capacitor C1 to the third capacitor C3.

In an exemplary implementation mode, as shown in FIG. 5A, the output sub-circuit includes a seventeenth transistor T17 to a twenty-first transistor T21, a twenty-fourth transistor T24, a twenty-fifth transistor T25, a twenty-sixth transistor T26, a fifth capacitor C5, and a sixth capacitor C6, and any one of the fifth capacitor C5 and the sixth capacitor C6 includes a first electrode plate and a second electrode plate. A gate electrode and a first electrode of the seventeenth transistor T17 are connected with the second node N2, a second electrode of the seventeenth transistor T17 is connected with the sixth node N6, a gate electrode of the eighteenth transistor T18 is connected with the seventh node N7, a first electrode of the eighteenth transistor T18 is connected with the third node N3, a second electrode of the eighteenth transistor T18 is connected with the sixth node N6, a gate electrode of the nineteenth transistor is connected with the control signal terminal G, a first electrode of the nineteenth transistor T19 is connected with the latch signal terminal MS, a second electrode of the nineteenth transistor T19 is connected with a first electrode of the twentieth transistor T20, a gate electrode of the twentieth transistor T20 is connected with the cascaded signal output terminal OUTC, a second electrode of the twentieth transistor T20 is connected with the seventh node N7, a gate electrode of the twenty-first transistor T21 is connected with the seventh node N7, a first electrode of the twenty-first transistor T21 is connected with the fourth node N4, a second electrode of the twenty-first transistor T21 is connected with the eighth node N8, a gate electrode of the twenty-fourth transistor T24 is connected with the sixth node N6, a gate electrode of the twenty-fourth transistor T24 is connected with the sixth node N6, a first electrode of the twenty-fourth transistor T24 is connected with the third power supply terminal VH3, a second electrode of the twenty-fourth transistor T24 is connected with the eighth node N8, a gate electrode of the twenty-fifth transistor T25 is connected with the eighth node N8, a first electrode of the twenty-fifth transistor T25 is connected with the third power supply terminal VH2, a second electrode of the twenty-fifth transistor T25 is connected with the drive signal output terminal OUT, a gate electrode of the twenty-sixth transistor T26 is connected with the sixth node N6, a first electrode of the twenty-sixth transistor T26 is connected with the fourth power supply terminal VL2, a second electrode of the twenty-sixth transistor T26 is connected with the drive signal output terminal OUT, a first electrode plate C51 of the fifth capacitor C5 is connected with the seventh node N7, a second electrode plate C52 of the fifth capacitor C5 is connected with the eighth node N8, a first electrode plate C61 of the sixth capacitor C6 is connected with the eighth node N8, and a second electrode plate C62 of the sixth capacitor C6 is connected with the third power supply terminal VH3.

In an exemplary implementation mode, as shown in FIG. 5B, the output sub-circuit includes a seventeenth transistor T17 to a twenty-sixth transistor T26, a fifth capacitor C5, and a sixth capacitor C6, and any one of the fifth capacitor C5 and the sixth capacitor C6 includes a first electrode plate and a second electrode plate. Herein, a gate electrode and a first electrode of the seventeenth transistor T17 are connected with the second node N2, a second electrode of the seventeenth transistor T17 is connected with the sixth node N6, a gate electrode of the eighteenth transistor T18 is connected with the seventh node N7, a first electrode of the eighteenth transistor T18 is connected with the third node N3, a second electrode of the eighteenth transistor T18 is connected with the sixth node N6, a gate electrode of the nineteenth transistor is connected with the control signal terminal G, a first electrode of the nineteenth transistor T19 is connected with the latch signal terminal MS, a second electrode of the nineteenth transistor T19 is connected with a first electrode of the twentieth transistor T20, a gate electrode of the twentieth transistor T20 is connected with the cascaded signal output terminal OUTC, a second electrode of the twentieth transistor T20 is connected with the seventh node N7, a gate electrode of the twenty-first transistor T21 is connected with the seventh node N7, a first electrode of the twenty-first transistor T21 is connected with the fourth node N4, a second electrode of the twenty-first transistor T21 is connected with the eighth node N8, a gate electrode of the twenty-second transistor T22 is connected with the fifth power supply terminal NCX, a first electrode of the twenty-second transistor T22 is connected with the fourth power supply terminal VL2, a second electrode of the twenty-second transistor T22 is connected with the seventh node N7, a gate electrode of the twenty-third transistor T23 is connected with the fifth node N5, a first electrode of the twenty-third transistor T23 is connected with the fourth power supply terminal VL2, a second electrode of the twenty-third transistor T23 is connected with the seventh node N7, a gate electrode of the twenty-fourth transistor T24 is connected with the sixth node N6, a gate electrode of the twenty-fourth transistor T24 is connected with the sixth node N6, a first electrode of the twenty-fourth transistor T24 is connected with the third power supply terminal VH2, a second electrode of the twenty-fourth transistor T24 is connected with the eighth node N8, a gate electrode of the twenty-fifth transistor T25 is connected with the eighth node N8, a first electrode of the twenty-fifth transistor T25 is connected with the third power supply terminal VH2, a second electrode of the twenty-fifth transistor T25 is connected with the drive signal output terminal OUT, a gate electrode of the twenty-sixth transistor T26 is connected with the sixth node N6, a first electrode of the twenty-sixth transistor T26 is connected with the second power supply terminal VL1, a second electrode of the twenty-sixth transistor T26 is connected with the drive signal output terminal OUT, a first electrode plate C51 of the fifth capacitor C5 is connected with the seventh node N7, a second electrode plate C52 of the fifth capacitor C5 is connected with the eighth node N8, a first electrode plate C61 of the sixth capacitor C6 is connected with the eighth node N8, and a second electrode plate C62 of the sixth capacitor C6 is connected with the third power supply terminal VH3.

In an exemplary implementation mode, any of the first capacitor C1 to the sixth capacitor C6 may be a capacitor device made through a process, for example, the capacitor device may be achieved by making a special-purpose capacitor electrode, and a plurality of capacitor electrodes of a capacitor may be achieved through metal layers, semiconductor layers (e.g., doped polysilicon), or the like. Or, any of the first capacitor C1 to the sixth capacitor C6 may be a parasitic capacitor between a plurality of devices, and may be achieved through a transistor itself and other devices or lines. A connection mode of any of the first capacitor C1 to the sixth capacitor C6 includes but is not limited to the mode described above, and may be another suitable connection mode, as long as a level of a corresponding node may be stored. Herein, the exemplary implementation modes of the present disclosure are not limited thereto.

In an exemplary implementation mode, transistors may be divided into N type transistors and P type transistors according to characteristics of the transistors. When a transistor is a P-type transistor, its turn-on voltage is a low-level voltage (e.g., 0 V, −5 V, −10 V, or another suitable voltage), and its turn-off voltage is a high-level voltage (e.g., 5 V, 10 V, or another suitable voltage). When a transistor is an N-type transistor, its turn-on voltage is a high-level voltage (e.g., 5 V, 10 V, or another suitable voltage), and its turn-off voltage is a low-level voltage (e.g., 0 V, −5 V, −10 V, or another suitable voltage).

In an exemplary implementation mode, the first transistor T1 to the twenty-sixth transistor T6 are all P-type transistors.

In an exemplary implementation mode, a signal of the latch signal terminal MS may be a low-level signal or may be a high-level signal. When the signal of the latch signal terminal MS is a low-level signal, its level may be −20 V to −5 V, and when the signal of the latch signal terminal MS is a high-level signal, its level may be 5 V to 20 V.

In an exemplary implementation mode, signals of the first power supply terminal VH1 and the third power supply terminal VH2 may be high-level signals, whose levels may range from 5 V to 10 V for example. Signals of the second power supply terminal VL1 and the fourth power supply terminal VL2 may be low-level signals, whose levels may range from −10 V to −5 V.

In an exemplary implementation mode, a signal of any of the first clock signal terminal CK and the second clock signal terminal CB may be a square wave signal with repeated high and low voltages. Exemplarily, signals of the first clock signal terminal CK and the second clock signal terminal CB may have a same period and may be configured as phase-shifted signals. Here, compared with a signal of the first clock signal terminal CK, a signal of the second clock signal terminal CB may be phase shifted by half a cycle. A high voltage period of a signal of any of the first clock signal terminal CK and the second clock signal terminal CB in each cycle may be set to be longer than a low voltage period.

In an exemplary implementation mode, the fifth power supply terminal NCX is a low-level signal during a startup initialization stage, which prevents the ninth transistor T9 and the tenth transistor T10 of a last-stage control shift register from simultaneously being turned on due to delay of an output signal, or is a low-level signal during an abnormal shutdown stage, which prevents the ninth transistor T9 and the tenth transistor T10 from simultaneously being turned on. The fifth power supply terminal NCX continuously provides a high-level signal during a normal display stage, i.e., the thirteenth transistor T13 is turned off during the normal display stage.

In an exemplary implementation mode, due to existence of the latch signal terminal MS, outputs of the shift sub-circuit and the output sub-circuit are independent. Working processes of the shift sub-circuit and the output sub-circuit will now be described separately.

In an exemplary implementation mode, the first power supply terminal VH1 continuously provides a high-level signal, and the second power supply terminal VL1 continuously provides a low-level signal. Since the second power supply terminal VL1 continuously provides the low-level signal, the eleventh transistor T11, the twelfth transistor T12, and the fifteenth transistor T15 in FIGS. 58 and 59 are continuously turned on, and the eighth transistor T8 in FIG. 61 is continuously turned on.

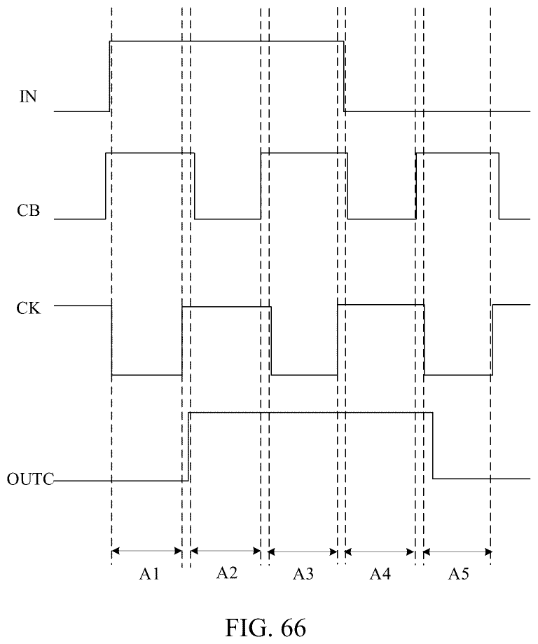

FIG. 66 is a working timing diagram of the shift sub-circuit provided in FIGS. 58 and 59. FIG. 66 is illustrated by taking a case in which the first transistor T1 to the sixteenth transistor T16 are P-type transistors as an example. As shown in FIG. 66, a working process of the shift sub-circuit provided in FIG. 58 may include following stages.

In a first stage A1, signals of the signal input terminal IN and the second clock signal terminal CB are high-level signals, and a signal of the first clock signal terminal CK is a low-level signal. The first transistor T1, the third transistor T3, and the fourteenth transistor T14 are turned on, and the seventh transistor T7 is turned off.

The turned-on first transistor T1 transmits a high-level signal of the signal input terminal IN to the third node N3, the turned-on twelfth transistor T12 transmits a high-level signal of the third node N3 to the ninth node N9, the fourteenth transistor T14 and the fifteenth transistor T15 that are turned on transmits the high-level signal of the signal input terminal IN to the second node N2, and the fourth transistor T4 and the sixteenth transistor T16 are turned off. The third transistor T3 and the eleventh transistor T11 that are turned on transmit a low-level signal of the second power supply terminal VL2 to the sixth node N6 and the tenth node N10, the fifth transistor T5 and the sixth transistor T6 are turned on, a high-level signal of the first power supply terminal VH1 is written to the fifth node N5, a high-level signal of the second clock signal terminal CB is written to the first node N1, since the seventh transistor T7 is turned off, a signal of the first node N1 is not written to the fourth node N4 a low-level signal is maintained, the ninth transistor T9 is turned off, and a signal of the cascaded signal output terminal OUTC maintains a previous low level. In this stage, signals of the first node N1, the second node N2, the third node N3, the fourth node N4, the fifth node N5, and the ninth node N9 are high-level signals, and the signal of the cascaded signal output terminal OUTC is a low-level signal.

In a second stage A2, a signal of the second clock signal terminal CB is a low-level signal, and signals of the signal input terminal IN and the first clock signal terminal CK are high-level signals. The first transistor T1, the third transistor T3, and the fourteenth transistor T14 are turned off, and the seventh transistor T7 is turned on.

Under an action of the first capacitor C1, signals of the sixth node N6 and the tenth node N10 maintain low-level signals, the fifth transistor T5 and the sixth transistor T6 are turned on, a high-level signal of the first power supply terminal VH1 is written to the fifth node N5, the low-level signal of the second clock signal terminal CB is written to the first node N1, a signal of the first node N1 is written to the fourth node N4 through the turned-on seventh transistor T7, the ninth transistor T9 is turned on, and a high-level signal of the first power supply terminal VH1 is transmitted to the cascaded signal output terminal OUTC through the turned-on ninth transistor T9. Under an action of the third capacitor C3, the second node N2 may continue to maintain a high-level signal of a previous stage, the third node N3 and the ninth node N9 maintain high-level signals of the previous stage, and the second transistor T2, the fourth transistor T4, the eighth transistor T8, the tenth transistor T10, and the sixteenth transistor T16 are turned off. In this stage, signals of the second node N2, the third node N3, the fifth node N5, and the ninth node N9 are high-level signals, signals of the first node N1 and the fourth node N4 are low-level signals, and a signal of the cascaded signal output terminal OUTC is a high-level signal.

In a third stage A3, a signal of the first clock signal terminal CK is a low-level signal, and signals of the signal input terminal IN and the second clock signal terminal CB are high-level signals. The first transistor T1, the third transistor T3, and the fourteenth transistor T14 are turned on, and the seventh transistor T7 is turned off.

The turned-on first transistor T1 transmits a high-level signal of the signal input terminal IN to the third node N3, the turned-on twelfth transistor T12 transmits a high-level signal of the third node N3 to the ninth node N9, the fourteenth transistor T14 and the fifteenth transistor T15 that are turned on transmits the high-level signal of the signal input terminal IN to the second node N2, and the fourth transistor T4 and the sixteenth transistor T16 are turned off. The third transistor T3 and the eleventh transistor T11 that are turned on transmit a low-level signal of the second power supply terminal VL2 to the sixth node N6 and the tenth node N10, the fifth transistor T5 and the sixth transistor T6 are turned on, the high-level signal of the first power supply terminal VH1 is written to the fifth node N5, the high-level signal of the second clock signal terminal CB is written to the first node N1, and since the seventh transistor T7 is turned off, the fourth node N4 maintains a low-level signal of a previous stage under an action of the second capacitor C2, the ninth transistor T9 is turned on, and the signal of the cascaded signal output terminal OUTC is a high-level signal. In this stage, signals of the first node N1, the second node N2, the third node N3, the fifth node N5, and the ninth node N9 are high-level signals, a signal of the fourth node N4 is a low-level signal, and a signal of the cascaded signal output terminal OUTC is a low-level signal.

In a fourth stage A4, signals of the signal input terminal IN and the second clock signal terminal CB are low-level signals, and a signal of the first clock signal terminal CK is a high-level signal. The first transistor T1, the third transistor T3, and the fourteenth transistor T14 are turned off, and the seventh transistor T7 is turned on.

Under an action of the third capacitor C3, signals of the second node N2, the third node N3, and the ninth node N9 maintain high-level signals of a previous stage, and the second transistor T2, the fourth transistor T4, the eighth transistor T8, the tenth transistor T10, and the sixteenth transistor T16 are turned off. Under an action of the first capacitor C1, the sixth node N6 and the tenth node N10 maintain low-level signals of the previous stage, the fifth transistor T5 and the sixth transistor T6 are turned on, the high-level signal of the first power supply terminal VH1 is written to the fifth node N5, a low-level signal of the second clock signal terminal CB is written to the first node N1, a signal of the first node N1 is written to the fourth node N4 through the turned-on seventh transistor T7, the ninth transistor T9 is turned on, and a high-level signal of the first power supply terminal VH1 is transmitted to the cascaded signal output terminal OUTC through the turned-on ninth transistor T9. In this stage, signals of the second node N2, the third node N3, the fifth node N5, and the ninth node N9 are high-level signals, signals of the first node N1 and the fourth node N4 are low-level signals, and a signal of the cascaded signal output terminal OUTC is a high-level signal.

In a fifth stage A5, a signal of the second clock signal terminal CB is a high-level signal, and signals of the signal input terminal IN and the first clock signal terminal CK are low-level signals. The first transistor T1, the third transistor T3, and the fourteenth transistor T14 are turned on, and the seventh transistor T7 is turned off.

The turned-on first transistor T1 transmits a low-level signal of the signal input terminal IN to the third node N3, the turned-on twelfth transistor T12 transmits a low-level signal of the third node N3 to the ninth node N9, a signal of the ninth node N9 becomes a low-level signal, the fourteenth transistor T14 and the fifteenth transistor T15 that are turned on transmit the low-level signal of the signal input terminal IN to the second node N2, a signal of the second node N2 is a low-level signal, and the second transistor T2, the fourth transistor T4, the eighth transistor T8, the tenth transistor T10, and the sixteenth transistor T16 are turned on. The turned-on second transistor T2 transmits a low-level signal of the first clock signal terminal CK to the tenth node N10, the sixth node N6 continues to maintain a low-level signal of a previous stage, the fifth transistor T5 and the sixth transistor T6 are turned on, the high-level signal of the second clock signal terminal CB is written to the first node N1 through the turned-on sixth transistor T6, and then written to the fourth node N4 through the turned-on seventh transistor T7, and the high-level signal of the second clock signal terminal CB is written to the fifth node N5 through the turned-on fourth transistor T4. A high-level signal of the first power supply terminal VH1 is transmitted to the fourth node N4 through the turned-on eighth transistor T8, and the ninth transistor T9 is turned off. A low-level signal of the second power supply terminal VL1 is transmitted to the cascaded signal output terminal OUTC through the turned-on tenth transistor T10, and a signal of the cascaded signal output terminal OUTC becomes a low-level signal. In this stage, the second node N2, the third node N3, and the ninth node N9 are low-level signals, signals of the first node N1, the fourth node N4, and the fifth node N5 are high-level signals, and a signal of the cascaded signal output terminal OUTC is a low-level signal.

As shown in FIG. 66, a working process of the shift sub-circuit provided in FIG. 59 may include following stages.

In a first stage A1, signals of the signal input terminal IN and the second clock signal terminal CB are high-level signals, and a signal of the first clock signal terminal CK is a low-level signal. The first transistor T1, the third transistor T3, and the fourteenth transistor T14 are turned on, and the seventh transistor T7 is turned off.

The turned-on first transistor T1 transmits a high-level signal of the signal input terminal IN to the third node N3, the turned-on twelfth transistor T12 transmits a high-level signal of the third node N3 to the second node N2, the fourteenth transistor T14 and the fifteenth transistor T15 that are turned on transmits the high-level signal of the signal input terminal IN to the second node N2, and the fourth transistor T4 is turned off. The third transistor T3 and the eleventh transistor T11 that are turned on transmit a low-level signal of the second power supply terminal VL2 to the sixth node N6 and the tenth node N10, the fifth transistor T5 and the sixth transistor T6 are turned on, a high-level signal of the first power supply terminal VH1 is written to the fifth node N5, the high-level signal of the second clock signal terminal CB is written to the first node N1, since the seventh transistor T7 is turned off, a signal of the first node N1 is not written to the fourth node N4, a low-level signal is maintained, the ninth transistor T9 is turned off, and a signal of the cascaded signal output terminal OUTC maintains a previous low level. In this stage, signals of the first node N1, the second node N2, the third node N3, the fourth node N4, and the fifth node N5 are high-level signals, and a signal of the cascaded signal output terminal OUTC is a low-level signal.

In a second stage A2, a signal of the second clock signal terminal CB is a low-level signal, and signals of the signal input terminal IN and the first clock signal terminal CK are high-level signals. The first transistor T1, the third transistor T3, and the fourteenth transistor T14 are turned off, and the seventh transistor T7 is turned on.

Under an action of the first capacitor C1, signals of the sixth node N6 and the tenth node N10 maintain low-level signals, the fifth transistor T5 and the sixth transistor T6 are turned on, a high-level signal of the first power supply terminal VH1 is written to the fifth node N5, the low-level signal of the second clock signal terminal CB is written to the first node N1, a signal of the first node N1 is written to the fourth node N4 through the turned-on seventh transistor T7, the ninth transistor T9 is turned on, and a high-level signal of the first power supply terminal VH1 is transmitted to the cascaded signal output terminal OUTC through the turned-on ninth transistor T9. Under an action of the third capacitor C3, the second node N2 may continue to maintain a high-level signal of a previous stage, the third node N3 and the second node N2 maintain high-level signals of the previous stage, and the second transistor T2, the fourth transistor T4, the eighth transistor T8, and the tenth transistor T10 are turned off. In this stage, signals of the second node N2, the third node N3, and the fifth node N5 are high-level signals, signals of the first node N1 and the fourth node N4 are low-level signals, and a signal of the cascaded signal output terminal OUTC is a high-level signal.

In a third stage A3, a signal of the first clock signal terminal CK is a low-level signal, and signals of the signal input terminal IN and the second clock signal terminal CB are high-level signals. The first transistor T1, the third transistor T3, and the fourteenth transistor T14 are turned on, and the seventh transistor T7 is turned off.

The turned-on first transistor T1 transmits a high-level signal of the signal input terminal IN to the third node N3, the turned-on twelfth transistor T12 transmits a high-level signal of the third node N3 to the second node N2, the fourteenth transistor T14 and the fifteenth transistor T15 that are turned on transmits the high-level signal of the signal input terminal IN to the second node N2, and the fourth transistor T4 is turned off. The third transistor T3 and the eleventh transistor T11 that are turned on transmit a low-level signal of the second power supply terminal VL2 to the sixth node N6 and the tenth node N10, the fifth transistor T5 and the sixth transistor T6 are turned on, a high-level signal of the first power supply terminal VH1 is written to the fifth node N5, a high-level signal of the second clock signal terminal CB is written to the first node N1, since the seventh transistor T7 is turned off, the fourth node N4 maintains a low-level signal of a previous stage under an action of the second capacitor C2, and the ninth transistor T9 is turned on, and a signal of the cascaded signal output terminal OUTC is a high-level signal. In this stage, signals of the first node N1, the second node N2, the third node N3, and the fifth node N5 are high-level signals, a signal of the fourth node N4 is a low-level signal, and a signal of the cascaded signal output terminal OUTC is a low-level signal.

In a fourth stage A4, signals of the signal input terminal IN and the second clock signal terminal CB are low-level signals, and a signal of the first clock signal terminal CK is a high-level signal. The first transistor T1, the third transistor T3, and the fourteenth transistor T14 are turned off, and the seventh transistor T7 is turned on.

Under an action of the third capacitor C3, signals of the second node N2, the third node N3, and the second node N2 maintain high-level signals of a previous stage, and the second transistor T2, the fourth transistor T4, the eighth transistor T8, and the tenth transistor T10 are turned off. Under an action of the first capacitor C1, the sixth node N6 and the tenth node N10 maintain low-level signals of the previous stage, the fifth transistor T5 and the sixth transistor T6 are turned on, a high-level signal of the first power supply terminal VH1 is written to the fifth node N5, a low-level signal of the second clock signal terminal CB is written to the first node N1, a signal of the first node N1 is written to the fourth node N4 through the turned-on seventh transistor T7, the ninth transistor T9 is turned on, and the high-level signal of the first power supply terminal VH1 is transmitted to the cascaded signal output terminal OUTC through the turned-on ninth transistor T9. In this stage, signals of the second node N2, the third node N3, and the fifth node N5 are high-level signals, signals of the first node N1 and the fourth node N4 are low-level signals, and a signal of the cascaded signal output terminal OUTC is a high-level signal.

In a fifth stage A5, a signal of the second clock signal terminal CB is a high-level signal, and signals of the signal input terminal IN and the first clock signal terminal CK are low-level signals. The first transistor T1, the third transistor T3, and the fourteenth transistor T14 are turned on, and the seventh transistor T7 is turned off.

The turned-on first transistor T1 transmits a low-level signal of the signal input terminal IN to the third node N3, the turned-on twelfth transistor T12 transmits a low-level signal of the third node N3 to the second node N2, a signal of the second node N2 becomes a low-level signal, the fourteenth transistor T14 and fifteenth transistor T15 that are turned on transmit the low-level signal of the signal input terminal IN to the second node N2, a signal of the second node N2 is a low-level signal, and the second transistor T2, the fourth transistor T4, the eighth transistor T8, and the tenth transistor T10 are turned on. The turned-on second transistor T2 transmits a low-level signal of the first clock signal terminal CK to the tenth node N10, the sixth node N6 continues to maintain a low-level signal of a previous stage, the fifth transistor T5 and the sixth transistor T6 are turned on, the high-level signal of the second clock signal terminal CB is written to the first node N1 through the turned-on sixth transistor T6, and then written to the fourth node N4 through the turned-on seventh transistor T7, and the high-level signal of the second clock signal terminal CB is written to the fifth node N5 through the turned-on fourth transistor. A high-level signal at the first power supply terminal VH1 is transmitted to the fourth node N4 through the turned-on eighth transistor T8, the ninth transistor T9 is turned off. A low-level signal of the second power supply terminal VL1 is transmitted to the cascaded signal output terminal OUTC through the turned-on tenth transistor T10, and a signal of the cascaded signal output terminal OUTC becomes a low-level signal. In this stage, signals of the second node N2 and the third node N3 are low-level signals, signals of the first node N1, the fourth node N4 and the fifth node N5 are high-level signals, and the signal of the cascaded signal output terminal OUTC is a low-level signal.

As shown in FIG. 66, when an output signal of the cascaded signal output terminal OUTC is a high-level signal, the fourth node N4 has a low-level signal, and the second node N2 and the third node N3 have high-level signals. When the output signal of the cascaded signal output terminal OUTC is a low-level signal, the fourth node N4 has a high-level signal, and the second node N2 and the third node N3 have low-level signals.

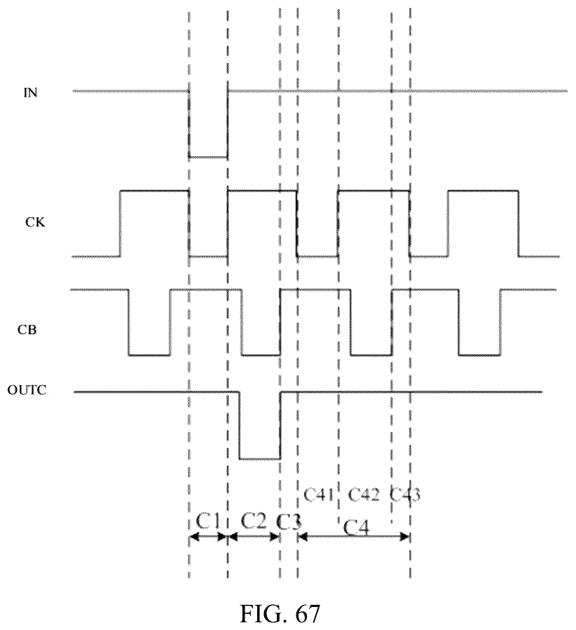

FIG. 67 is a working timing diagram of the shift sub-circuit provided in FIG. 61. FIG. 66 is illustrated by taking a case in which the first transistor T1 to the eighth transistor T8 are P-type transistors as an example. As shown in FIG. 66, a working process of the shift sub-circuit provided in FIG. 61 may include following stages.

In a first stage C1, signals of the first clock signal terminal CK and the signal input terminal IN are low-level signals, and a signal of and the second clock signal terminal CB is a high-level signal. The first transistor T1 and the third transistor T3 are turned on, and the seventh transistor T7 is turned off.

The turned-on first transistor T1 writes a low-level signal of the signal input terminal IN to the third node N3, the turned-on eighth transistor T8 writes a low-level signal of the third node N3 to the ninth node N9, the fifth transistor T5 is turned on, and the high-level signal of the second clock signal terminal CB is written to the cascaded signal output terminal OUTC.

The turned-on third transistor T3 writes a low-level signal of the second power supply terminal VL2 to the fourth node N4, the fourth transistor T4 and the sixth transistor T6 are turned on, and a high-level signal of the first power supply terminal VH1 is written to the cascaded signal output terminal OUTC. In this stage, signals of the third node N3, the fourth node N4, and the ninth node N9 are low-level signals, and a signal of the cascaded signal output terminal OUTC is a high-level signal.

In a second stage C2, signals of the first clock signal terminal CK and the signal input terminal IN are high-level signals, and a signal of the second clock signal terminal CB is a low-level signal. The first transistor T1 and the third transistor T3 are turned off, and the seventh transistor T7 is turned on.

The third node N3 and the ninth node N9 maintain low-level signals, the fifth transistor T5 is turned on, the low-level signal of the second clock signal terminal CB is written to the cascaded signal output terminal OUTC, the second transistor T2 is turned on, a high-level signal of the first clock signal terminal CK is written to the fourth node N4, and the fourth transistor T4 is turned off. In this stage, signals of the third node N3 and the ninth node N9 are low-level signals, a signal of the fourth node N4 is a high-level signal, and a signal of the cascaded signal output terminal OUTC is a low-level signal.

In a third stage C3, signals of the first clock signal terminal CK and the second clock signal terminal CB are both high-level signals, and a signal of the signal input terminal IN is a high-level signal. The first transistor T1, the third transistor T3, and the seventh transistor T7 are turned on.

The third node N3 and the ninth node N9 maintain low-level signals, the fifth transistor T5 is turned on, a low-level signal of the second clock signal terminal CB is written to the cascaded signal output terminal OUTC, the second transistor T2 is turned on, a high-level signal of the first clock signal terminal CK is written to the fourth node N4, and the fourth transistor T4 is turned off. In this stage, signals of the third node N3 and the ninth node N9 are low-level signals, a signal of the fourth node N4 is a high-level signal, and a signal of the cascaded signal output terminal OUTC is a low-level signal.

In a first sub-stage C41 of a fourth stage C4, a signal of the first clock signal terminal CK is a low-level signal, and signals of the second clock signal terminal CB and the signal input terminal IN are high-level signals. The first transistor T1 and the third transistor T3 are turned on, and the seventh transistor T7 is turned off.

The turned-on first transistor T1 writes a high-level signal of the signal input terminal IN to the third node N3, the turned-on eighth transistor T8 writes a high-level signal of the third node N3 to the ninth node N9, and the fifth transistor T5 is turned off. The turned-on third transistor T3 writes a low-level signal of the second power supply terminal VL1 to the fourth node N4, the fourth transistor T4 and the sixth transistor T6 are both turned on, and the turned-on fourth transistor T4 writes a high-level signal of the first power supply terminal VH1 to the cascaded signal output terminal OUTC. In this stage, signals of the third node N3 and the ninth node N9 are high-level signals, a signal of the fourth node N4 is a low-level signal, and a signal of the cascaded signal output terminal OUTC is a high-level signal.

In a second sub-stage C42 of the stabilization stage C4, signals of the first clock signal terminal CK and the signal input terminal IN are high-level signals, and a signal of the second clock signal terminal CB is a low-level signal. The first transistor T1 and the third transistor T3 are turned off, and the seventh transistor T7 is turned on.

The third node N3 and the ninth node N9 maintain high-level signals, the second transistor T2 is turned off, and a high-level signal of the first clock signal terminal CK cannot be written to the fourth node N4. In addition, under a holding action of the first capacitor C1, the fourth node N4 maintain a low-level signal of a previous stage, the fourth transistor T4 and the sixth transistor T6 are both turned on, and a high-level signal of the first power supply terminal VH1 is written to the cascaded signal output terminal OUTC. In this stage, signals of the third node N3 and the ninth node N9 are high-level signals, a signal of the fourth node N4 is a low-level signal, and a signal of the cascaded signal output terminal OUTC is a high-level signal.

In a third sub-stage C43, signals of the first clock signal terminal CK, the second clock signal terminal CB, and the signal input terminal IN are all high-level signals, and the first transistor T1, the third transistor T3, and the seventh transistor T7 are turned off.

The third node N3 and the ninth node N9 still maintain high-level signals, the second transistor T2 is turned off, and a high-level signal of the first clock signal terminal CK cannot be written to the fourth node N4. In addition, under a holding action of the first capacitor C1, the fourth node N4 maintains a low-level signal of a previous stage, the fourth transistor T4 and the sixth transistor T6 are both turned on, and a high-level signal of the first power supply terminal VH1 is written to the cascaded signal output terminal OUTC. In this stage, signals of the third node N3 and the ninth node N9 are high-level signals, a signal of the fourth node N4 is a low-level signal, and a signal of the cascaded signal output terminal OUTC is a high-level signal.

As shown in FIG. 67, when an output signal of the cascaded signal output terminal OUTC is a high-level signal, a signal of the fourth node N4 is a low-level signal. When the output signal of the cascaded signal output terminal OUTC is a low-level signal, a signal of the third node N3 is a low-level signal.

In an exemplary implementation mode, as shown in FIG. 63, when the signal of the cascaded signal output terminal OUTC in the shift register is a low-level signal, signals of the second node N2, the third node N3, and the ninth node N9 are low-level signals, the tenth transistor T10 is turned on, and a signal of the second power supply terminal VL1 is written to the cascaded signal output terminal OUTC. Since a signal of the second node N2 is a low-level signal, the sixteenth transistor T16 and the seventeenth transistor T17 are turned on, a signal of the sixth node N6 is a low-level signal, the twenty-fourth transistor T24 and the twenty-sixth transistor T26 are turned on, a signal of the fourth power supply terminal VL2 is written to the drive signal output terminal OUT, a high-level signal of the third power supply terminal VH2 is written to the eighth node N8, the twenty-fifth transistor T25 is turned off, and a high-level signal of the third power supply terminal VH2 cannot be written to the drive signal output terminal OUT. That is, a signal of the cascaded signal output terminal OUTC in the shift register is a low-level signal, and the drive signal output terminal OUT also outputs a low-level signal.

In an exemplary implementation mode, as shown in FIG. 64, when a signal of the cascaded signal output terminal OUTC in the shift register is a low-level signal, signals of the second node N2 and the third node N3 are low-level signals, the tenth transistor T10 is turned on, and a signal of the second power supply terminal VL1 is written to the cascaded signal output terminal OUTC. Since a signal of the second node N2 is a low-level signal, the seventeenth transistor T17 is turned on, a signal of the sixth node N6 is a low-level signal, the twenty-fourth transistor T24 and the twenty-sixth transistor T26 are turned on, a signal of the fourth power supply terminal VL2 is written into the drive signal output terminal OUT, a high-level signal of the third power supply terminal VH2 is written into the eighth node N8, the twenty-fifth transistor T25 is turned off, and a high-level signal of the third power supply terminal VH2 cannot be written into the drive signal output terminal OUT. That is, a signal of the cascaded signal output terminal OUTC in the shift register is a low-level signal, and the drive signal output terminal OUT also outputs a low-level signal.

In an exemplary implementation mode, in the shift register provided in FIGS. 63 and 64, when the signal of the cascaded signal output terminal in the shift register is a high-level signal, a signal of the fourth node N4 is a low-level signal, and the ninth transistor T9 is turned on. Due to existence of the twenty-first transistor T21, the signal of the fourth node N4 is not directly written into the twenty-fifth transistor T25, and the gate electrode of the twenty-first transistor T21 is determined by the nineteenth transistor T19, the twentieth transistor T20, and the fifth capacitor C5.

In an exemplary implementation mode, in the shift register provided in FIG. 65, when a signal of the cascaded signal output terminal in the shift register is a high-level signal, a signal of the fourth node N4 is a low-level signal, and the fourth transistor T4 is turned on. Due to existence of the twenty-first transistor T21, the signal of the fourth node N4 is not directly written into the twenty-fifth transistor T25, and the gate electrode of the twenty-first transistor T21 is determined by the nineteenth transistor T19, the twentieth transistor T20, and the fifth capacitor C5, which may be called a latch sub-circuit. In the shift register provided in FIG. 65, when the signal of the cascaded signal output terminal in the shift register is a low-level signal, a signal of the third node N3 is a low-level signal, the fifth transistor T5 is turned on, and the signal of the third node N3 is not directly written to the twenty-sixth transistor T26 due to presence of the eighteenth transistor T18, and the gate electrode of the eighteenth transistor T18 is determined by the nineteenth transistor T19, the twentieth transistor T20, and the fifth capacitor C5.

In an exemplary implementation mode, the nineteenth transistor T19, the twentieth transistor T20, and the fifth capacitor C5 may be referred to as a latch sub-circuit. The gate electrode of the nineteenth transistor T19 is electrically connected with the second control signal terminal V2 (also a first node of a previous stage shift register), and the gate electrode of the twentieth transistor T20 is connected with the cascaded signal output terminal OUTC. When the signal of the cascaded signal output terminal OUTC and a signal of the first node of the previous stage shift register are both low-level signals, the nineteenth transistor T19 and the twentieth transistor T20 are turned on, and a signal of the latch signal terminal MS is written to the seventh node N7 and the fifth capacitor C5, thereby controlling whether the eighteenth transistor T18 and the twentieth transistor T21 are turned on. Whether the twenty-first transistor T21 is turned on or not determines whether the signal of the fourth node N4 is written to the eighth node N8, that is, determines whether the twenty-fifth transistor T25 is turned on, and whether the twenty-fifth transistor T25 is turned on determines whether a signal of the third power supply terminal VH3 is written to the drive signal output terminal. Whether the eighteenth transistor T18 is turned on determines whether a signal of the third node N3 is written to the sixth node N6, that is, whether the twenty-fifth transistor T25 is turned on, and whether the twenty-fifth transistor T25 is turned on determines whether a signal of the fourth power supply terminal VHL is written to the drive signal output terminal OUT.

In an exemplary implementation mode, the twenty-second transistor T22 and the twenty-third transistor T23 may be referred to as an initial stabilization unit. The fifth power supply terminal NCX is a low-level signal during a startup initialization stage, and the twenty-second transistor T22 is turned on. Since the display substrate does not perform displaying at this time, a signal of the fourth node N4 is a high-level signal, a signal of the fourth power supply terminal VL2 is written to the seventh node N7, the twenty-first transistor T21 is turned on, the high-level signal of the fourth node N4 is written to the eighth node N8, and the twenty-fifth transistor T25 is turned off, thereby preventing the drive signal output terminal from outputting a high-level signal to the pixel drive circuit. In addition, in the startup initialization stage, the cascaded signal output terminal OUTC outputs a low-level signal, a signal of the first control signal terminal V1 (also the fifth node N5) is a low-level signal, the twenty-third transistor T23 is turned on, a signal of the fourth power supply terminal VL2 is written to the seventh node N7, a signal of the latch signal terminal MS pre-stored in the latch sub-circuit is replaced by the signal of the fourth power supply terminal VL2, the twenty-first transistor T21 is turned on, the high-level signal of the fourth node N4 is written to the eighth node N8, and the twenty-fifth transistor T25 is turned off. The initial stabilization unit may prevent the drive signal output terminal from outputting a high-level signal to the pixel drive circuit during the startup initialization stage. The initial stabilization unit may ensure that at least one stage shift register has no leakage during the startup initialization stage, thereby improving reliability of the shift register.

In an exemplary implementation mode, a drive signal output by the drive signal output terminal of the shift register is mainly used for controlling at least one transistor in the pixel drive circuit of the display substrate. When the display substrate is in a refresh frame, the drive signal output terminal outputs a high-level signal in a time period, and outputs a low-level signal during remaining time periods within one frame time, to achieving refreshing of a data voltage. When the display substrate is not in the refresh frame, the drive signal output terminal always outputs a low-level signal.

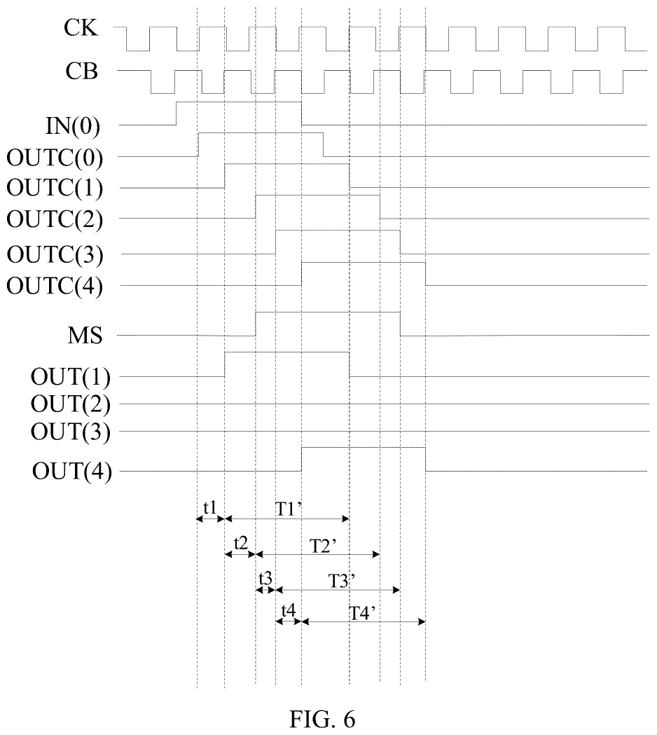

FIG. 6 is a working timing diagram of part of shift registers. In the following, taking shift registers shown in FIGS. 5A and 5B as an example, a working principle of the above shift register according to the embodiment of the present disclosure controlling a display panel to achieve different refresh rates in different regions is described with reference to a signal timing diagram shown in FIG. 6. FIG. 6 is illustrated by taking first four stages of shift registers as an example.

In the signal timing diagram shown in FIG. 6, first four stages of shift registers are only taken as an example. For example, when regions corresponding to a second row of sub-pixels and a third row of sub-pixels in the display substrate are low refresh rate regions and regions corresponding to a first row of sub-pixels and a fourth row of sub-pixels are high refresh rate regions, the nineteenth transistor T19 and the twentieth transistor T20 are both turned on when a signal of a cascaded signal output terminal OUTC(1) of a first-stage shift register and a signal of a first node of a previous stage shift register are both low-level signals (time T1), that is, the low-level signal of the latch signal terminal MS is latched in the fifth capacitor C5 at time t1, when the cascaded signal output terminal OUTC(1) of the first-stage shift register outputs a high level (time T1′), since the fifth capacitor C5 maintains the low-level signal of the latch signal terminal MS at time t1, the twenty-first transistor T21 and the twenty-fifth transistor T25 is turned on, then at time T1′, a drive signal output terminal OUT(1) of the first-stage shift register outputs a high-level signal of the third power supply terminal VH3 to achieve a high refresh rate of the first row of sub-pixels in the display region; a duration during in which the drive signal output terminal OUT(1) of the first-stage shift register outputs the high-level signal of the third power supply terminal VH3 may be set according to an actual demand. For example, a duration in which the drive signal output terminal OUT(1) of the first-stage shift register outputs the high-level signal of the third power supply terminal VH3 may be overlapped with a duration in which a drive signal output terminal OUT(4) of a fourth-stage shift register outputs a high-level signal of the third power supply terminal VH3, and a pixel drive circuit corresponding to the drive signal output terminal OUT(4) of the fourth-stage shift register may be pre-charged. Similarly, a duration in which a drive signal output terminal OUT(n) of another stage shift register outputs a level signal is similar, and will not be described in detail.

As shown in FIG. 6, when a signal of a cascaded signal output terminal OUTC(2) of a second-stage shift register and a signal of a first node of a first-stage shift register are both low-level signals (time t2), both the nineteenth transistor T19 and the twentieth transistor T20 are turned on, that is, the high-level signal of the latch signal terminal MS is latched in the fifth capacitor C5 at time t2; when the cascaded signal output terminal OUTC(2) of the second-stage shift register outputs a high level (time T2′), since the fourth capacitor C4 maintains the high-level signal of the latch signal terminal MS at time t2, the twenty-fifth transistor T25 is turned off and the twenty-sixth transistor T26 is turned on, and at time T2′, the drive signal output terminal OUT(2) of the second-stage shift register outputs a low-level signal of the fourth power supply terminal VL2 to achieve a low refresh rate of the second row of sub-pixels in the display region.

As shown in FIG. 6, when a signal of a cascaded signal output terminal OUTC(3) of a third-stage shift register and a signal of a first node of a second-stage shift register are both low-level signals (time t3), both the nineteenth transistor T19 and the twentieth transistor T20 are turned on, that is, the high-level signal of the latch signal terminal MS is latched in the fifth capacitor C5 at time t3; when the cascaded signal output terminal OUTC(3) of the third-stage shift register outputs a high level (time T3′), since the fourth capacitor C4 maintains the high-level signal of the latch signal terminal MS at time t3, the twenty-fifth transistor T25 is turned off and the twenty-sixth transistor T26 is turned on, and then the drive signal output terminal OUT(3) of the third-stage shift register outputs a low-level signal of the fourth power supply terminal VL2 at time T3′ to achieve a low refresh rate of the third row of sub-pixels in the display region.

As shown in FIG. 6, when a signal of a cascaded signal output terminal OUTC(4) of a fourth-stage shift register and a signal of a first node of a third-stage shift register are both low-level signals (time T4), the nineteenth transistor T19 and the twentieth transistor T20 are turned on, that is, the low-level signal of the latch signal terminal MS is latched in the fifth capacitor C5 at time t4, when the cascaded signal output terminal OUTC(4) of the fourth-stage shift register outputs a high level (time T4′), since the fourth capacitor C4 maintains the low-level signal of the latch signal terminal MS at time t4, the twenty-first transistor T21 and the twenty-fifth transistor T25 are turned on, and the drive signal output terminal OUT(4) of the fourth-stage shift register outputs a high-level signal of the third power supply terminal VH2 at time T4′ to achieve a high refresh rate of the fourth row of sub-pixels in the display region.

Therefore, when a low refresh rate is needed in a certain region of the display substrate, a high-level signal is supplied through the latch signal terminal MS, and a drive signal output terminal keeps outputting a low-level signal, so that some of transistors corresponding to the pixel drive circuit in the display substrate are turned off, and then a data voltage in the display substrate is not charged, and a state of a previous frame is maintained, thereby achieving a low refresh rate in this region.

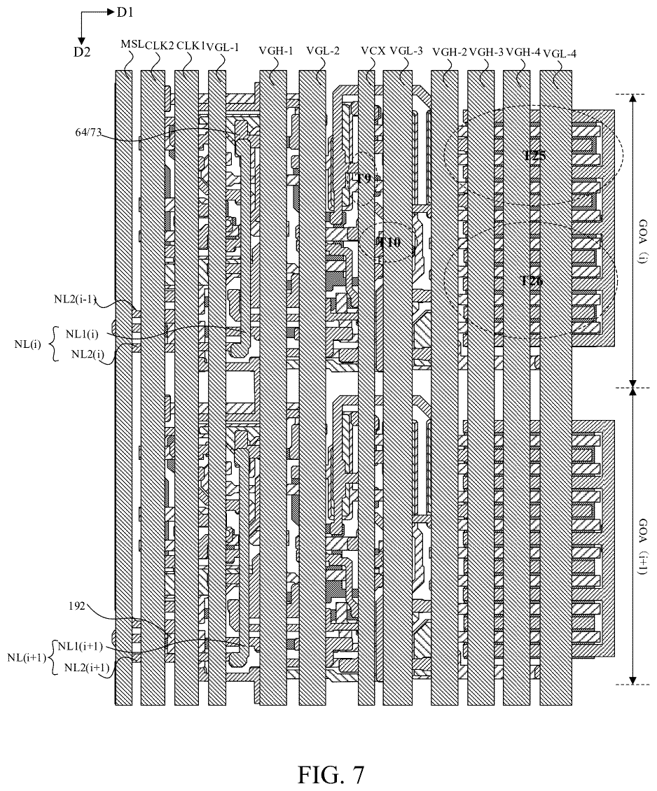

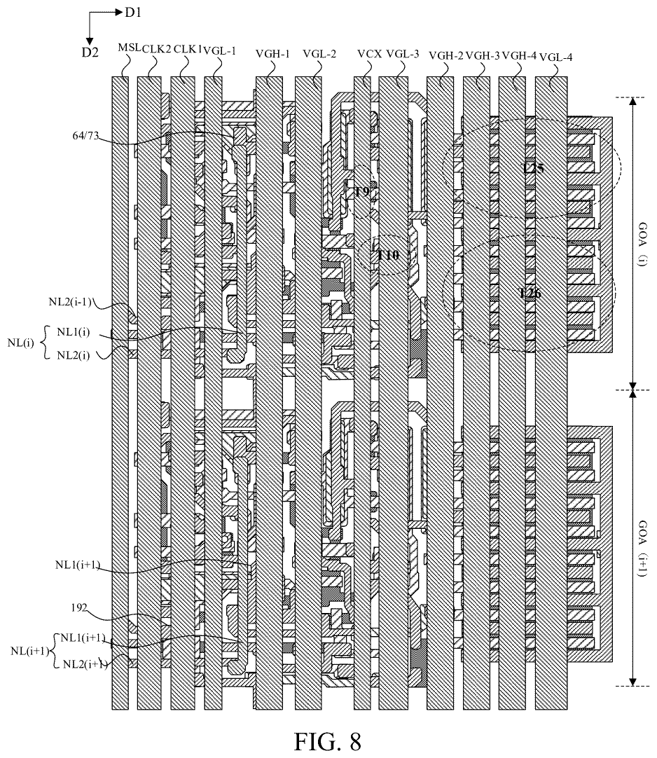

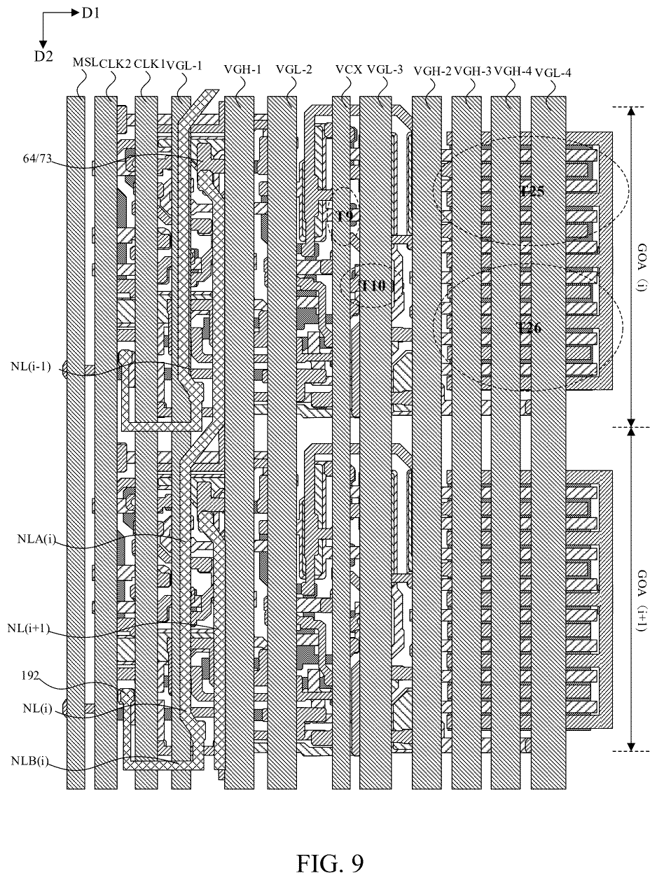

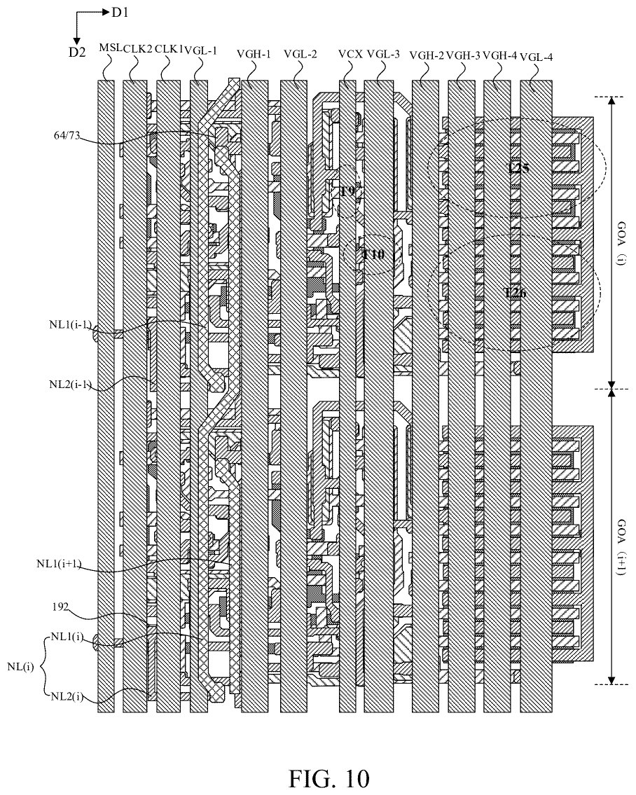

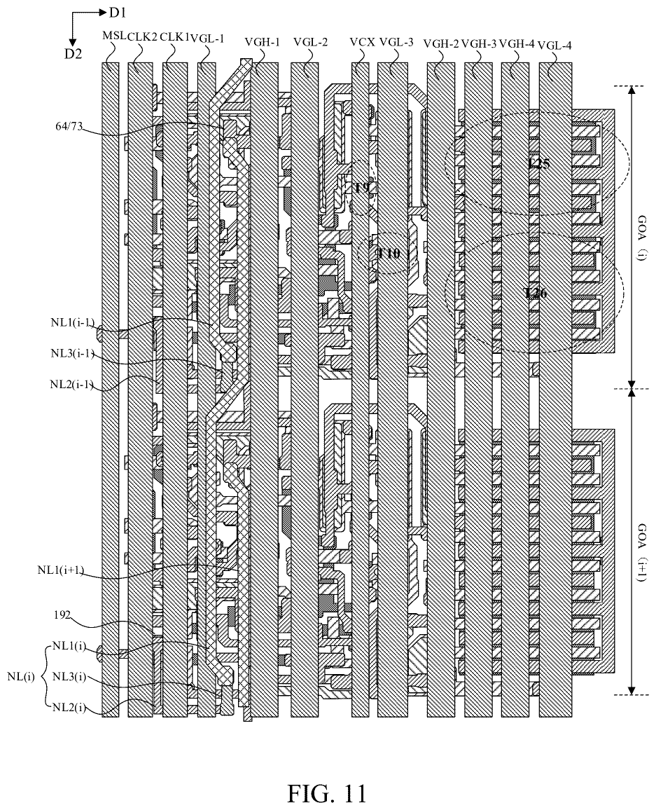

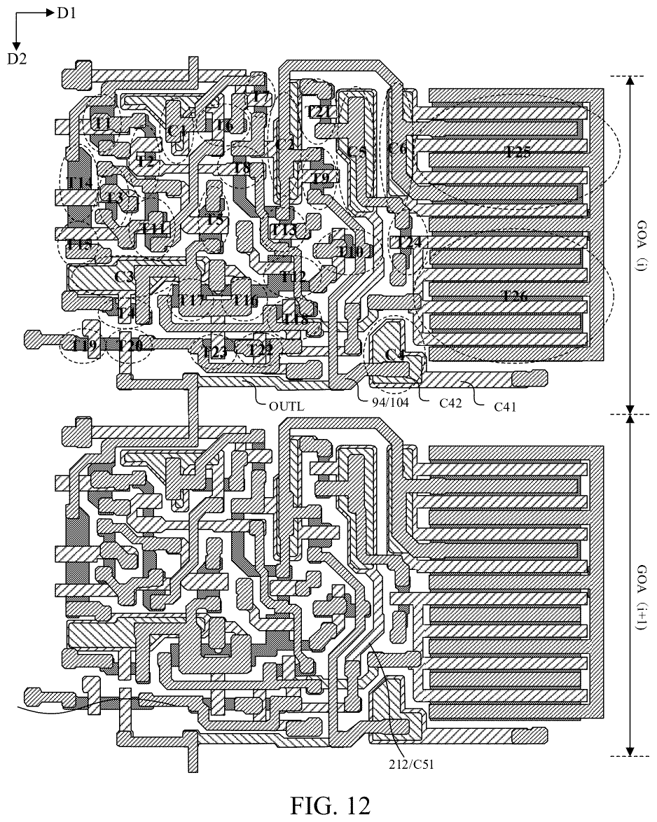

In an exemplary implementation mode, FIG. 7 is a first schematic diagram of a structure of a display substrate, FIG. 8 is a second schematic diagram of a structure of a display substrate structure, FIG. 9 is a third schematic diagram of a structure of a display substrate, FIG. 10 is a fourth schematic diagram of a structure of a display substrate, FIG. 11 is a fifth schematic diagram of a structure of a display substrate, FIG. 12 is a schematic diagram of a partial structure of the display substrate according to FIGS. 7, 9, 10, and 11, and FIG. 13 is a schematic diagram of a partial structure of the display substrate according to FIG. 8. FIGS. 7 to 11 are illustrated by taking two shift registers GOA(i) and GOA(i+1), and a case that the shift registers in FIGS. 7, 9, 10, and 11 are the shift register of FIG. 5B and the shift register in FIG. 8 is the shift register according to FIG. 5A as an example.

In an exemplary implementation mode, as shown in FIGS. 7 to 13, a transistor includes an active pattern. Among them, a length of an active pattern of at least one of the twenty-fifth transistor T25 and the twenty-sixth transistor T26 in a first direction D1 is greater than a length of an active pattern of at least one of the ninth transistor T9 and the tenth transistor T10 in the first direction D1, and a length of the active pattern of at least one of the twenty-fifth transistor T25 and the twenty-sixth transistor T26 in a second direction D2 is greater than a length of the active pattern of at least one of the ninth transistor T9 and the tenth transistor T10 in the second direction D2, wherein the first direction D1 intersects with the second direction D2.

In an exemplary implementation mode, a channel width-to-length ratio of the active pattern of at least one of the twenty-fifth transistor T25 and the twenty-sixth transistor T26 is greater than or equal to 80/3.

In an exemplary implementation mode, as shown in FIGS. 7 to 11, a plurality of signal lines located in the non-display region are further included, and a shift register includes a plurality of transistors and a plurality of capacitors. The plurality of signal lines are connected with the shift register, at least one of the plurality of signal lines extends at least partially in the second direction D2, and a transistor includes an active pattern, a gate electrode, a first electrode, and a second electrode.

In an exemplary implementation mode, the display substrate includes a base substrate and a drive structure layer disposed on the base substrate. The drive structure layer is provided with a pixel drive circuit and a gate drive circuit, and the drive structure layer includes a semiconductor layer, a first conductive layer, a second conductive layer, a third conductive layer, and a fourth conductive layer sequentially stacked on the base substrate.

The semiconductor layer includes at least: an active pattern of at least one transistor among the plurality of transistors.

The first conductive layer includes at least: a gate electrode of at least one of the plurality of transistors and a first electrode plate of at least one of the plurality of capacitors.

The second conductive layer includes at least: a second electrode plate of at least one capacitor of the plurality of capacitors.

The third conductive layer includes at least: a first electrode and a second electrode of at least one transistor of the plurality of transistors.

The fourth conductive layer includes at least: at least one of the plurality of signal lines.

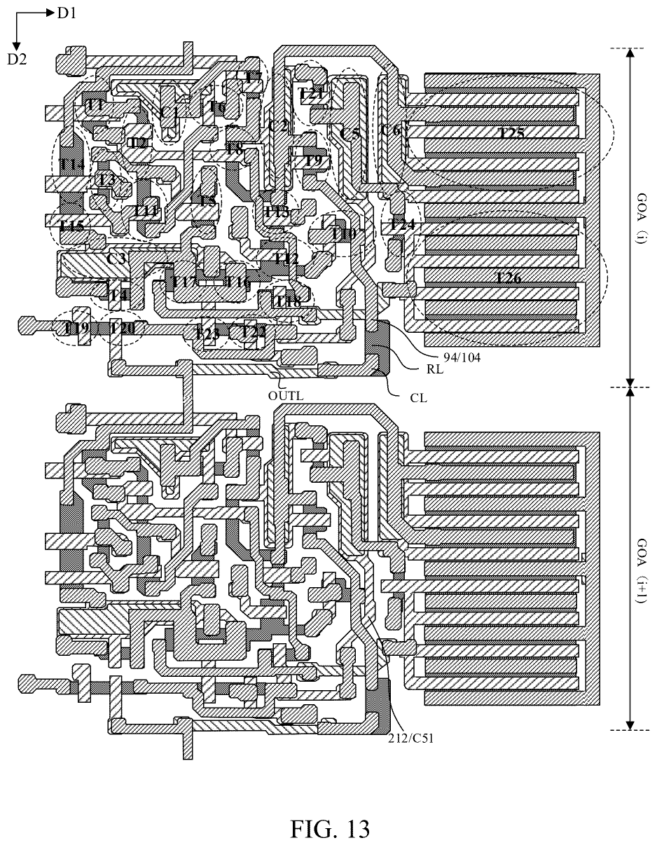

In an exemplary implementation mode, as shown in FIGS. 12 and 13, orthographic projections of all transistors (the seventeenth transistor T17 to the twenty-sixth transistor T26) and all capacitors (the fifth capacitor C5 and the sixth capacitor C6) included in the output sub-circuit on the base substrate are disposed around one side of orthographic projections of all transistors (the first transistor T1 to the sixteenth transistor T16) and the first capacitor C1 to the third capacitor C3 included in the shift sub-circuit on the base substrate, and are located on a side of the shift sub-circuit close to the display region.

In an exemplary implementation mode, as shown in FIGS. 12 and 13, the seventeenth transistor T17 to the twentieth transistor T20, the twenty-second transistor T22, and the twenty-third transistor T23 are located on a side of some transistors in the shift sub-circuit close to a next stage shift register, the twenty-first transistor T21 and the twenty-fourth transistor T24 are located on a side of some transistors in the shift sub-circuit close to the display region, and the twenty-fifth transistor T25 and the twenty-sixth transistor T26 are located on a side of at least one of the first transistor T1 to the twenty-fourth transistor T24 close to the display region.

In an exemplary implementation mode, as shown in FIG. 12, when the shift sub-circuit includes the fourth capacitor C4, orthographic projections of all transistors included in the output sub-circuit on the base substrate are disposed around at least one side of an orthographic projection of the fourth capacitor C4 on the base substrate. The fourth capacitor C4 is located on a side of the twenty-fourth transistor T24 close to a next stage shift register, on a side of the seventeenth transistor T17 to the twentieth transistor T20, the twenty-second transistor T22, and the twenty-third transistor T23 close to the display region, and on a side of the twenty-fifth transistor T25 and the twenty-sixth transistor T26 away from the display region.

In an exemplary implementation mode, as shown in FIGS. 8 and 13, when the shift register includes the first transistor T1 to the twenty-sixth transistor T26 and the first capacitor C1 to the third capacitor C3, the display substrate further includes N voltage stabilization connection lines RL, N cascaded connection lines CL, and N cascaded output lines OUTL. A second electrode 94 of the ninth transistor T9 and a second electrode 104 of the tenth transistor T10 in the shift register are of an integral structure, and a gate electrode 212 of the twenty-first transistor T21 and a first electrode plate C51 of the fifth capacitor C5 are of an integral structure. Among them, an n-th voltage stabilization connection line RL is respectively connected with an n-th cascaded connection line CL and an integral structure of a second electrode of a ninth transistor T9 and a second electrode of a tenth transistor T10 in an n-th stage shift register, and an n-th cascaded output line OUTL is respectively connected with the n-th cascaded connection line CL and a first electrode of a first transistor T1 of an (n+1)-th stage shift register, wherein 1≤n≤N, and N is a total number of stages of shift registers.

In an exemplary implementation mode, as shown in FIGS. 8 and 13, for at least one stage shift register, an orthographic projection of the integral structure of the second electrode of the ninth transistor T9 and the second electrode of the tenth transistor T10 on the base substrate is at least partially overlapped with an orthographic projection of the integral structure of the gate electrode of the twenty-first transistor T21 and the first electrode plate C51 of the fifth capacitor C5 on the base substrate.

In an exemplary implementation mode, the voltage stabilization connection lines RL are located in the semiconductor layer, the cascaded output lines OUTL are located in the second conductive layer, and the cascaded connection lines CL are located in the third conductive layer.

In an exemplary implementation mode, a line width of a voltage stabilization connection line RL is greater than a line width of a cascaded connection line and a line width of a cascaded output line.

In an exemplary implementation mode, a range of a resistance value of the voltage stabilization connection line RL is from 500 ohms to 5000 ohms.

In an exemplary implementation mode, an arrangement of the voltage stabilization connection line RL may increase a load of a connection structure connecting the integral structure of the second electrode of the ninth transistor T9 and the second electrode of the tenth transistor T10 in the n-th stage shift register with the first electrode of the first transistor T1 in the (n+1)-th stage shift register, and may ensure stability of a signal transmitted between the integral structure of the second electrode of the ninth transistor T9 and the second electrode of the tenth transistor T10 in the n-th stage shift register and the first electrode of the first transistor T1 in the (n+1)-th stage shift register.

In an exemplary implementation mode, as shown in FIGS. 7, 9, 10, 11, and 12, when the shift register includes the first transistor T1 to the twenty-sixth transistor T26 and the first capacitor C1 to the fourth capacitor C4, the display substrate further includes N cascaded output lines OUTL. The second electrode of the ninth transistor T9 and the second electrode of the tenth transistor T10 in the shift register are of an integral structure, and the gate electrode of the twenty-first transistor T21 and the first electrode plate of the fifth capacitor are of an integral structure. An integral structure of a second electrode of a ninth transistor T9 and a second electrode of a tenth transistor T10 in an i-th stage shift register is respectively connected with an i-th cascaded output line OUTL and a second electrode plate C42 of a fourth capacitor C4 in the n-th stage shift register.

In an exemplary implementation mode, as shown in FIGS. 7, 9, 10, 11, and 12, for at least one stage shift register, there is no overlapping region between an orthographic projection of an integral structure of a second electrode of a ninth transistor T9 and a second electrode of a tenth transistor T10 on the base substrate and an orthographic projection of an integral structure of a gate electrode of a twenty-first transistor T21 and a first electrode plate of a fifth capacitor on the base substrate.

In an exemplary implementation mode, as shown in FIGS. 7, 9, 10, 11, and 12, the cascaded output lines are located in the second conductive layer.

In an exemplary implementation mode, as shown in FIGS. 7 to 11, the display substrate further includes N−1 node connection lines NL, and a second electrode of the sixth transistor T6 and a first electrode of the seventh transistor T7 in the shift register are of an integral structure. Among them, an i-th node connection line NL(i) is connected with an integral structure of a second electrode 64 of a sixth transistor T6 and a first electrode 73 of a seventh transistor T7 in an i-th stage shift register GOA(i) and a gate electrode 192 of a nineteenth transistor T19 of an (i+1)-th stage shift register GOA(i+1) respectively, wherein 1≤i≤N−1.

In an exemplary implementation mode, as shown in FIGS. 7 and 8, a node connection line includes a first node connection line and a second node connection line disposed in different layers. For the i-th node connection line NL(i), a first node connection line NL1(i) is connected with a second node connection line NL2(i) and the integral structure of the second electrode 64 of the sixth transistor T6 and the first electrode 73 of the seventh transistor T7 in the i-th stage shift register GOA(i) respectively, and the second node connection line NL1(i) is electrically connected with the gate electrode 192 of the nineteenth transistor T19 of the (i+1)-th stage shift register GOA(i+1).

In an exemplary implementation mode, as shown in FIGS. 7 and 8, at least one of the first node connection line and the second node connection line extends at least partially in the second direction D2.

In an exemplary implementation mode, as shown in FIGS. 7 and 8, there is no overlapping region between an orthographic projection of the first node connection line on the base substrate and an orthographic projection of at least one of the plurality of signal lines on the base substrate. An orthographic projection of the second node connection line on the base substrate is at least partially overlapped with orthographic projections of some of the plurality of signal lines on the base substrate, and an orthographic projection of a part of the second node connection line on the base substrate is at least partially overlapped with an orthographic projection of a first signal line on the base substrate, wherein the first signal line is a signal line among the plurality of signal lines away from the display region.

In an exemplary implementation mode, as shown in FIGS. 7 and 8, the first node connection line is located in the fourth conductive layer, and the second node connection line is located in the third conductive layer.

In an exemplary implementation mode, as shown in FIG. 9, a node connection line includes a first node connection portion and a second node connection portion, and the first node connection portion and the second node connection portion are of an integral structure. For the i-th node connection line NL(i), a first node connection portion NLA(i) is connected with the integral structure of the second electrode 64 of the sixth transistor T6 and the first electrode 73 of the seventh transistor T7 in the i-th stage shift register GOA(i) and a second node connection portion NLB(i) respectively, and the second node connection portion NLB(i) is electrically connected with the gate electrode 192 of the nineteenth transistor T19 in the (i+1)-th stage shift register GOA(i+1).

In an exemplary implementation mode, as shown in FIG. 9, the first node connection portion extends at least partially along the second direction D2, the second node connection portion extends at least partially along the first direction D1, an orthographic projection of the second node connection portion on the base substrate is at least partially overlapped with orthographic projections of some of the plurality of signal lines on the base substrate, and an orthographic projection of a part of the second node connection portion on the base substrate is located at a side of an orthographic projection of the first signal line on the base substrate close to the display region, wherein the first signal line is a signal line among the plurality of signal lines away from the display region. An arrangement mode of node connection lines may reduce coupling capacitance between the node connection lines and the signal lines, avoid signals of the node connection lines from being disturbed, and improve reliability of the display substrate.

In an exemplary implementation mode, as shown in FIG. 9, an orthographic projection of the first node connection portion on the base substrate may be at least partially overlapped with orthographic projections of some of the plurality of signal lines on the base substrate.

In an exemplary implementation mode, as shown in FIG. 9, the drive structure layer further includes: a fifth conductive layer located on a side of the fourth conductive layer away from the base substrate, and the node connection lines are located in the fifth conductive layer.

In an exemplary implementation mode, as shown in FIG. 10, a node connection line includes a first node connection line and a second node connection line disposed in different layers. For the i-th node connection line NL(i), a first node connection line NL1(i) is connected with the integral structure of the second electrode 64 of the sixth transistor T6 and the first electrode 73 of the seventh transistor T7 in the i-th stage shift register GOA(i) and a second node connection line NL2(i) respectively, and the second node connection line NL2(i) is electrically connected with the gate electrode 192 of the nineteenth transistor T19 of the (i+1)-th stage shift register GOA(i+1).

In an exemplary implementation mode, as shown in FIG. 10, the first node connection line extends at least partially along the second direction D2, the second node connection line extends at least partially along the first direction D1, an orthographic projection of the second node connection line on the base substrate is at least partially overlapped with orthographic projections of some of the plurality of signal lines on the base substrate, and an orthographic projection of a part of the second node connection line on the base substrate is located at a side of an orthographic projection of the first signal line on the base substrate close to the display region, wherein the first signal line is a signal line among the plurality of signal lines away from the display region. An arrangement mode of the node connection lines may reduce coupling capacitance between the node connection lines and the signal lines, avoid signals of the node connection lines from being disturbed, and improve reliability of the display substrate.

In an exemplary implementation mode, as shown in FIG. 10, an orthographic projection of the first node connection line on the base substrate may be at least partially overlapped with orthographic projections of some of the plurality of signal lines on the base substrate.

In an exemplary implementation mode, as shown in FIG. 10, the drive structure layer further includes: a fifth conductive layer located on a side of the fourth conductive layer away from the base substrate. The first node connection line is located in the fifth conductive layer, and the second node connection line is located in the third conductive layer.

In an exemplary implementation mode, as shown in FIG. 11, a node connection line includes a first node connection line, a second node connection line, and a third node connection line disposed in different layers. For the i-th node connection line NL(i), a first node connection line NL1(i) is connected with the integral structure of the second electrode 64 of the sixth transistor T6 and the first electrode 73 of the seventh transistor T7 in the i-th stage shift register GOA(i) and a third node connection line NL3(i) respectively, and the second node connection line NL2(i) is electrically connected with the third node connection line NL3(i) and the gate electrode 192 of the nineteenth transistor T19 of the (i+1)-th stage shift register GOA(i+1).

In an exemplary implementation mode, as shown in FIG. 11, the first node connection line and the third node connection line extend at least partially along the second direction D2, the second node connection line extends at least partially along the first direction D1, there is no overlapping region between an orthographic projection of the third node connection line on the base substrate and an orthographic projection of at least one signal line of the plurality of signal lines on the base substrate, an orthographic projection of the second node connection line on the base substrate is at least partially overlapped with orthographic projections of some of the plurality of signal lines on the base substrate, and an orthographic projection of a part of the second node connection line on the base substrate is located at a side of an orthographic projection of the first signal line on the base substrate close to the display region, wherein the first signal line is a signal line among the plurality of signal lines away from the display region. An arrangement mode of the node connection lines may reduce coupling capacitors between the node connection lines and the signal lines, avoid the signals of the node connection lines from being disturbed, and improve the reliability of the display substrate.

In an exemplary implementation mode, as shown in FIG. 11, the drive structure layer further includes: a fifth conductive layer located on a side of the fourth conductive layer away from the base substrate. The first node connection line is located in the fifth conductive layer, the third node connection line is located in the fourth conductive layer, and the second node connection line is located in the third conductive layer.

In an exemplary implementation mode, as shown in FIGS. 7 to 11, the plurality of signal lines include a latch signal line MSL, a second clock signal line CLK2, a first clock signal line CLK1, a first power supply line VGL-1, a second power supply line VGH-1, a third power supply line VGL-2, a fourth power supply line VCX, a fifth power supply line VGL-3, a sixth power supply line VGH-2, a seventh power supply line VGH-3, an eighth power supply line VGH-4, and a ninth power supply line VGL-4 disposed sequentially along the display region. Herein, the latch signal line MSL is configured to provide a signal to a latch signal terminal with which the shift register is connected, at least one of the first power supply line VGL-1, the third power supply line VGL-2, the fifth power supply line VGL-3, and the ninth power supply line VGL-4 is configured to provide a signal to a second power supply terminal or a fourth power supply terminal with which the shift register is connected; the second power supply line VGH-1, the sixth power supply line VGH-2, the seventh power supply line VGH-3, and eighth power supply line VGH-4 are configured to provide signals to a first power supply terminal and a third power supply terminal with which the shift register is connected, and the fourth power supply line VCX is configured to provide a signal to a fifth power supply terminal with which the shift register is connected. The seventh power supply line VGH-3 is configured to provide a signal to a third power supply terminal with which an i-th stage shift register is connected, and the eighth power supply line VGH-4 is configured to provide a signal to a third power supply terminal with which an (i+1)-th stage shift register is connected.

In an exemplary implementation mode, a first power supply line with which some of transistors in the shift sub-circuit are connected and a first power supply line with which some of transistors in the output sub-circuit are connected are separately provided. A second power supply line with which some of the transistors in the shift sub-circuit and a second power supply line with which some of the transistors in the output sub-circuit are connected are separately provided, so that independent regulation of the shift sub-circuit and the output sub-circuit may be achieved.

In an exemplary implementation mode, the seventh power supply line VGH-3 is configured to provide a signal to a third power supply terminal connected with the i-th stage shift register, and the eighth power supply line VGH-4 is configured to provide a signal to a third power supply terminal connected with the (i+1)-th stage shift register. Third power supply terminals connected with shift registers of adjacent stages are connected with different power supply lines, which may improve output stability of high-level signals of adjacent shift registers, thereby improving reliability of the display substrate.

In an exemplary implementation mode, an orthographic projection of the latch signal line MSL on the base substrate is located at a side of orthographic projections of the plurality of transistors in the shift register on the base substrate away from the display region, and an orthographic projection of at least one signal line of the first clock signal line CLK1, the second clock signal line CLK2, the first power supply line VGL-1, the second power supply line VGH-1, the third power supply line VGL-2, the fourth power supply line, the fifth power supply line VGL-3, the sixth power supply line VGH-2, the seventh power supply line VGH-3, the eighth power supply line VGL-4, and the ninth power supply line VGL-4 on the base substrate is at least partially overlapped with orthographic projections of some transistors in the shift register on the base substrate. An arrangement mode of the above signal lines may reduce regions occupied by the pixel drive circuit and signal lines connected thereto, and a narrow bezel of the display substrate may be achieved.

In an exemplary implementation mode, signals of at least two of the second power supply line VGH-1, the sixth power supply line VGH-2, the seventh power supply line VGH-3, and the eighth power supply line VGH-4 are the same, or, signals of the second power supply line VGH-1 and the sixth power supply line VGH-2 are the same, signals of the seventh power supply line VGH-3 and the eighth power supply line VGH-4 are the same, and voltage values of signals of the second power supply line VGH-1 and the seventh power supply line VGH-3 are different, or, signals of the sixth power supply line VGH-2, the seventh power supply line VGH-3, and the eighth power supply line VGH-4 are the same, and voltage values of signals of the second power supply line VGH-1 and the sixth power supply line VGH-2 are different.

In an exemplary implementation mode, signals of at least two of the first power supply line VGL-1, the third power supply line VGL-2, the fifth power supply line VGL-3, and the ninth power supply line VGL-4 are the same, or, signals of at least two of the first power supply line VGL-1, the third power supply line VGL-2, and the fifth power supply line VGL-3 are the same and are different from a signal of the ninth power supply line VGL-4.

In an exemplary implementation mode, the display substrate further includes a light emitting structure layer located on a side of the drive circuit layer away from the base substrate. Among them, the light emitting structure layer may include an anode, a pixel definition layer, an organic emitting layer, and a cathode. The anode is connected with the pixel drive circuit through a via, the organic emitting layer is connected with the anode, the cathode is connected with the organic emitting layer, and the organic emitting layer emits light of a corresponding color under drive of the anode and the cathode.

In an exemplary implementation mode, the display substrate may further include an encapsulation structure layer located on a side of the light emitting structure layer away from the base substrate. Among them, the encapsulation structure layer may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is disposed between the first encapsulation layer and the third encapsulation layer, which may ensure that external moisture cannot enter the light emitting structure layer.

In an exemplary implementation mode, the display substrate may further include a touch structure layer located on a side of the encapsulation structure layer away from the base substrate. Among them, the touch structure layer may include a first touch insulation layer disposed on the encapsulation structure layer, a first touch metal layer disposed on the first touch insulation layer, a second touch insulation layer covering the first touch metal layer, a second touch metal layer disposed on the second touch insulation layer, and a touch protection layer covering the second touch metal layer. The first touch metal layer may include a plurality of bridge electrodes, the second touch metal layer may include a plurality of first touch electrodes and second touch electrodes, and the first touch electrodes or the second touch electrodes may be connected with the bridge electrodes through vias.

In an exemplary implementation mode, the display substrate according to the present disclosure may be applied to a display apparatus with a gate drive circuit, such as an OLED, a quantum dot display (QLED), a light emitting diode display (Micro LED or Mini LED), or a Quantum Dot Light Emitting Diode display (QDLED), etc., which is not limited here in the present disclosure.

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in an entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a dimension of the film layer in a direction perpendicular to a display substrate. In an exemplary implementation mode of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A is overlapped with the boundary of the orthographic projection of B.

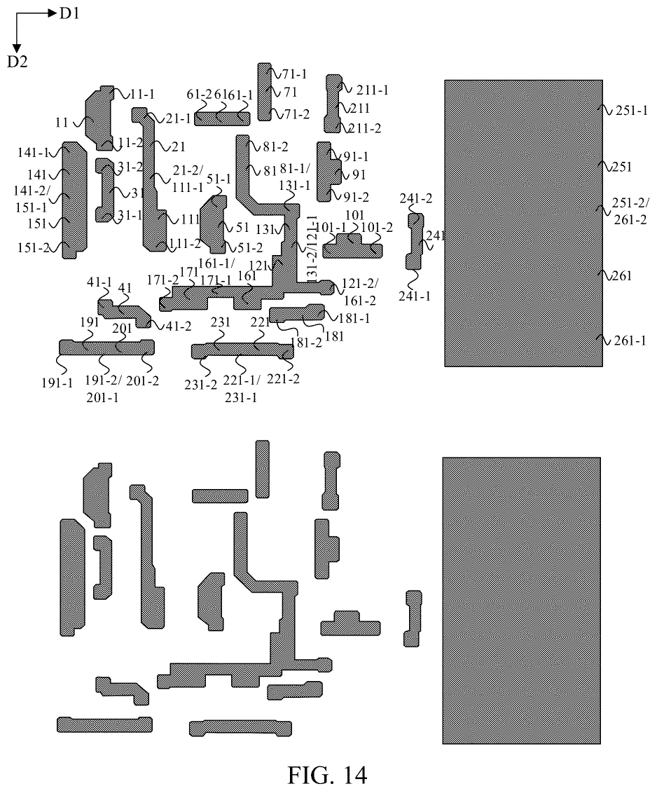

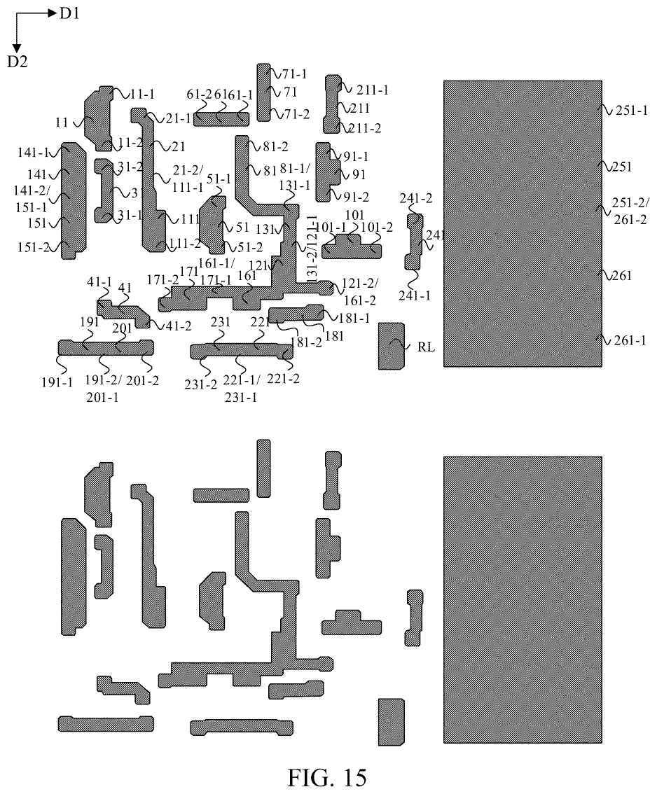

(1) A pattern of a semiconductor layer is formed on a base substrate. In an exemplary implementation mode, forming the pattern of the semiconductor layer on a base substrate may include: depositing a semiconductor thin film on the base substrate, patterning the semiconductor thin film through a patterning process to form the pattern of the semiconductor layer. As shown in FIGS. 14 and 15, FIG. 14 is a schematic diagram of the display substrate according to FIGS. 7 and 9 to 11 after the pattern of the semiconductor layer is formed, and FIG. 15 is a schematic diagram of the display substrate according to FIG. 8 after the pattern of the semiconductor layer is formed.

In an exemplary implementation mode, as shown in FIG. 14, the pattern of the semiconductor layer in the display substrate according to FIGS. 7 and 9 to 11 may include at least an active pattern 11 of a first transistor to an active pattern 231 of a twenty-sixth transistor located in each stage shift register.

In an exemplary implementation mode, as shown in FIG. 15, the pattern of the semiconductor layer in the display substrate according to FIG. 8 may include at least an active pattern 11 of a first transistor to an active pattern 231 of a twenty-sixth transistor located in each stage shift register and a stabilization connection line RL.

In an exemplary implementation mode, as shown in FIGS. 14 and 15, the active pattern 21 of the second transistor and the active pattern 111 of the eleventh transistor are of an integral structure, the active pattern 81 of the eighth transistor, the active pattern 121 of the twelfth transistor, the active pattern 131 of the thirteenth transistor, the active pattern 161 of the sixteenth transistor, and the active pattern 171 of the seventeenth transistor are of an integral structure, the active pattern 141 of the fourteenth transistor and the active pattern 151 of the fifteenth transistor are of an integral structure, the active pattern 191 of the nineteenth transistor and the active pattern 201 of the twentieth transistor are of an integral structure, the active pattern 221 of the twenty-second transistor and the active pattern 231 of the twenty-third transistor are of an integral structure, the active pattern 251 of the twenty-fifth transistor and the active pattern 261 of the twenty-sixth transistor are of an integral structure. The active pattern 11 of the first transistor, the active pattern 31 of the third transistor, the active pattern 41 of the fourth transistor, the active pattern 51 of the fifth transistor, the active pattern 61 of the sixth transistor, the active pattern 71 of the seventh transistor, the active pattern 91 of the ninth transistor, the active pattern 101 of the tenth transistor, the active pattern 181 of the eighteenth transistor, the active pattern 211 of the twenty-first transistor, and the active pattern 241 of the twenty-fourth transistor are separately disposed.

In an exemplary implementation mode, as shown in FIG. 15, the stabilization connection line RL is separately disposed.

In an exemplary implementation mode, as shown in FIGS. 14 and 15, the active pattern 11 of the first transistor is located on a side of an integral structure of the active pattern 141 of the fourteenth transistor and the active pattern 151 of the fifteenth transistor close to the display region, and is arranged in the second direction D2 with the active pattern 31 of the third transistor. An active pattern 31 of a third transistor of a current stage shift register is located on a side of an active pattern 11 of a first transistor close to a next stage shift register. An integral structure of the active pattern 21 of the second transistor and the active pattern 111 of the eleventh transistor are located on a side of the active pattern 31 of the third transistor close to the display region, the active pattern 51 of the fifth transistor and the active pattern 61 of the sixth transistor are located on a side of an integral structure of the active pattern 21 of the second transistor and the active pattern 111 of the eleventh transistor close to the display region, an active pattern 51 of the fifth transistor of the current stage shift register is located on a side of the active pattern 61 of the sixth transistor close to the next stage shift register, the active pattern 71 of the seventh transistor is located on a side of the active pattern 61 of the sixth transistor close to the display region, the active pattern 211 of the twenty-first transistor is located on a side of the active pattern 71 of the seventh transistor close to the display region, an integral structure of the active pattern 81 of the eighth transistor, the active pattern 121 of the twelfth transistor, the active pattern 131 of the thirteenth transistor, the active pattern 161 of the sixteenth transistor, and the active pattern 171 of the seventeenth transistor is located on a side of the active pattern 51 of the fifth transistor close to the display region, the active pattern 91 of the ninth transistor and the active pattern 101 of the tenth transistor are located on a side of an integral structure of the active pattern 81 of the eighth transistor, the active pattern 121 of the twelfth transistor, the active pattern 131 of the thirteenth transistor, the active pattern 161 of the sixteenth transistor, and the active pattern 171 of the seventeenth transistor close to the display region, the active pattern 241 of the twenty-fourth transistor is located on a side of the active pattern 101 of the tenth transistor and the active pattern 181 of the eighteenth transistor close to the display region, the active pattern 41 of the fourth transistor is located on a side of the active pattern 31 of the third transistor of the current stage shift register close to the next stage shift register, an integral structure of the active pattern 191 of the nineteenth transistor and the active pattern 201 of the twentieth transistor of the current stage shift register is located on a side of the active pattern 41 of the fourth transistor close to the next stage shift register, an integral structure of the active pattern 221 of the twenty-second transistor and the active pattern 231 of the twenty-third transistor is located on a side of an integral structure of the active pattern 191 of the nineteenth transistor and the active pattern 201 of the twentieth transistor close to the display region, and is arranged along the first direction D1 with the integral structure of the active pattern 191 of the nineteenth transistor and the active pattern 201 of the twentieth transistor, the active pattern 181 of the eighteenth transistor is located on a side of the active pattern 41 of the fourth transistor close to the display region, an integral structure of the active pattern 251 of the twenty-fifth transistor and the active pattern 261 of the twenty-sixth transistor is located on a side of the active pattern 241 of the twenty-fourth transistor close to the display region.

In an exemplary implementation mode, as shown in FIG. 15, the voltage stabilization connection line RL is located between the integral structure of the active pattern 221 of the twenty-second transistor and the active pattern 231 of the twenty-third transistor and the integral structure of the active pattern 251 of the twenty-fifth transistor and the active pattern 261 of the twenty-sixth transistor, and is located on a side of the active pattern 241 of the twenty-fourth transistor of in the current stage shift register close to the next stage shift register.

In an exemplary implementation mode, at least one of the active pattern 11 of the first transistor, the integral structure of the active pattern 21 of the second transistor and the active pattern 111 of the eleventh transistor, the active pattern 31 of the third transistor, the active pattern 51 of the fifth transistor, the active pattern 71 of the seventh transistor, the active pattern 91 of the ninth transistor, the integral structure of the active pattern 141 of the fourteenth transistor and the active pattern 151 of the fifteenth transistor, the active pattern 211 of the twenty-first transistor, the active pattern 241 of the twenty-fourth transistor, the integral structure of the active pattern 251 of the twenty-fifth transistor and the active pattern 261 of the twenty-sixth transistor is in a shape of a strip, and extends in the second direction D2.

In an exemplary implementation mode, at least one of the active pattern 41 of the fourth transistor, the active pattern 61 of the sixth transistor, the active pattern 101 of the tenth transistor, the active pattern 181 of the eighteenth transistor, the integral structure of the active pattern 191 of the nineteenth transistor and the active pattern 201 of the twentieth transistor, the integral structure of the active pattern 221 of the twenty-second transistor and the active pattern 231 of the twenty-third transistor is in a shape of a strip, and extends in the first direction D1.

In an exemplary implementation mode, a shape of the integral structure of the active pattern 81 of the eighth transistor, the active pattern 121 of the twelfth transistor, the active pattern 131 of the thirteenth transistor, the active pattern 161 of the sixteenth transistor, and the active pattern 171 of the seventeenth transistor is an inverted “T”.

In an exemplary implementation mode, the voltage stabilization connection line RL is in a shape of a strip, and extends in the second direction D2.

In an exemplary implementation mode, an active pattern of each transistor may include a first region, a second region, and a channel region located between the first region and the second region. In an exemplary implementation mode, a second region 21-2 of the active pattern 21 of the second transistor may serve as a first region 111-1 of the active pattern 111 of the eleventh transistor, a first region 81-1 of the active pattern 81 of the eighth transistor may serve as a first region 131-1 of the active pattern 131 of the thirteenth transistor, a first region 121-1 of the active pattern 121 of the twelfth transistor may serve as a second region 131-2 of the active pattern 131 of the thirteenth transistor, a second region 121-2 of the active pattern 121 of the twelfth transistor may serve as a second region 161-2 of the active pattern 161 of the sixteenth transistor, a second region 141-2 of the active pattern 141 of the fourteenth transistor may serve as a first region 151-1 of the active pattern 151 of the fifteenth transistor, a first region 161-1 of the active pattern 161 of the sixteenth transistor may serve as a first region 171-1 of the active pattern 171 of the seventeenth transistor, a second region 191-2 of the active pattern 191 of the nineteenth transistor may serve as a first region 201-1 of the active pattern of the twentieth transistor, a first region 221-1 of the active pattern 221 of the twenty-second transistor may serve as a first region 231-1 of the active pattern 231 of the twenty-third transistor, a second region 251-2 of the active pattern of the twenty-fifth transistor may serve as a second region 261-2 of the active pattern of the twenty-sixth transistor. The first region 11-1 and the second region 11-2 of the active pattern 11 of the first transistor, the first region 21-1 of the active pattern 21 of the second transistor, the first region 31-1 and the second region 31-2 of the active pattern 31 of the third transistor, the first region 41-1 and the second region 41-2 of the active pattern 41 of the fourth transistor, the first region 51-1 and the second region 51-2 of the active pattern 51 of the fifth transistor, the first region 61-1 and the second region 61-2 of the active pattern 61 of the sixth transistor, the first region 71-1 and the second region 71-2 of the active pattern 71 of the seventh transistor, the second region 81-2 of the active pattern 81 of the eighth transistor, the first region 91-1 and the second region 91-2 of the active pattern 91 of the ninth transistor, the first region 101-1 and the second region 101-2 of the active pattern 101 of the tenth transistor, the second region 111-2 of the active pattern 111 of the eleventh transistor, the second region 131-2 of the active pattern 131 of the thirteenth transistor, the first region 141-1 of the active pattern 141 of the fourteenth transistor, the second region 151-2 of the active pattern 151 of the fifteenth transistor, the second region 171-2 of the active pattern 171 of the seventeenth transistor, the first region 181-1 and the second region 181-2 of the active pattern 181 of the eighteenth transistor, the first region 191-1 of the active pattern 191 of the nineteenth transistor, the second region 201-2 of the active pattern of the twentieth transistor, the first region 211-1 and the second region 211-2 of the active pattern 211 of the twenty-first transistor, the second region 221-2 of the active pattern 221 of the twenty-second transistor, the first region 231-1 of the active pattern 231 of the twenty-third transistor, the first region 241-1 and the second region 241-2 of the active pattern of the twenty-fourth transistor, the first region 251-1 of the active pattern of the twenty-fifth transistor, and the first region 261-1 of the active pattern of the twenty-sixth transistor are separately disposed.

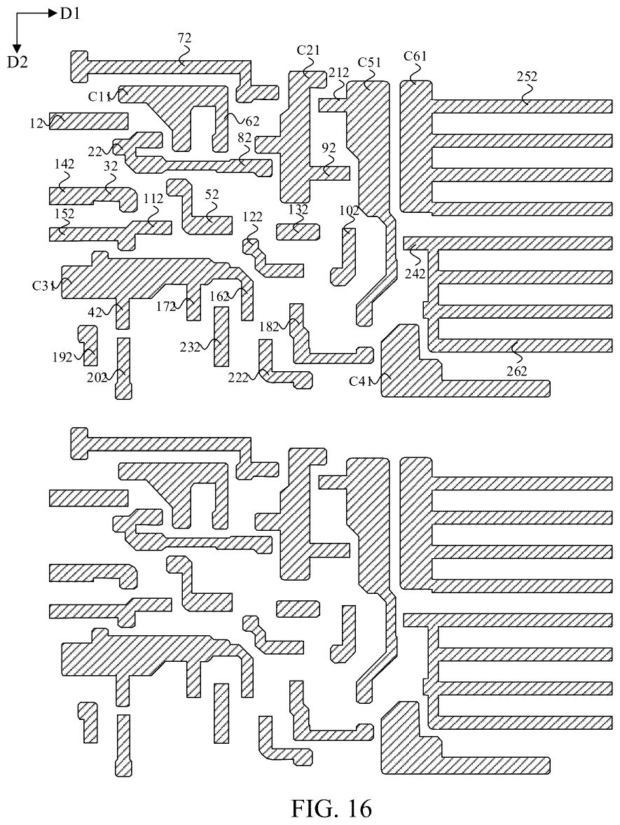

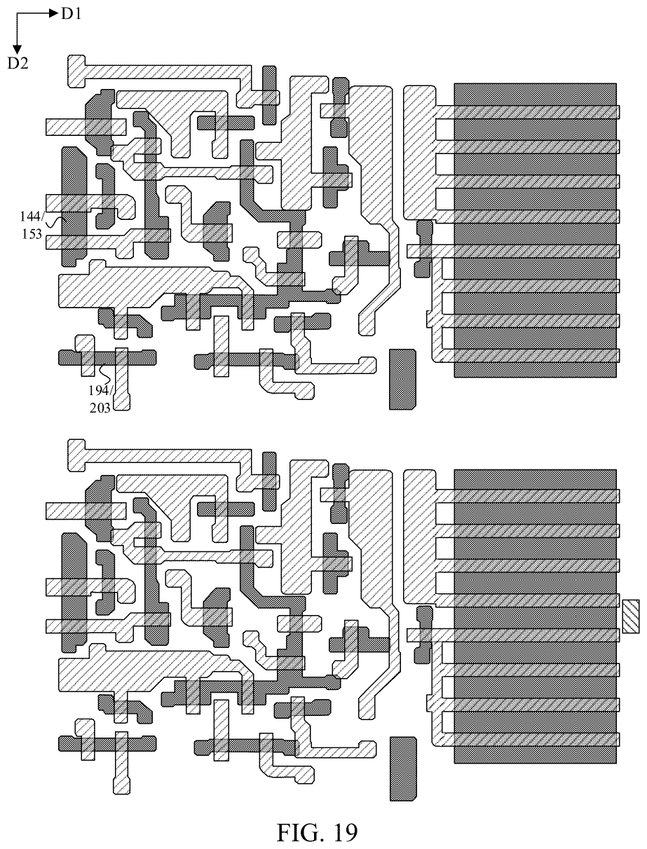

(2) A pattern of a first conductive layer is formed. In an exemplary implementation mode, forming the pattern of the first conductive layer may include: depositing a first insulation thin film and a first conductive thin film on the base substrate on which the above-mentioned pattern is formed, patterning the first conductive thin film through a patterning process, forming a first insulation layer covering the pattern of the semiconductor layer, and the pattern of the first conductive layer disposed on the first insulation layer, as shown in FIGS. 16 to 19, FIG. 16 is a schematic diagram of a pattern of a first conductive layer in the display substrate according to FIGS. 7 and 9 to 11, FIG. 17 is a schematic diagram of forming a pattern of a first conductive layer in the display substrate according to FIGS. 7 and 9 to 11, FIG. 18 is a schematic diagram of a pattern of a first conductive layer in the display substrate according to FIG. 8, FIG. 19 is a schematic diagram of forming a pattern of a first conductive layer in the display substrate according to FIG. 8. In an exemplary implementation mode, the first conductive layer may be referred to as a first gate metal (GATE1) layer.

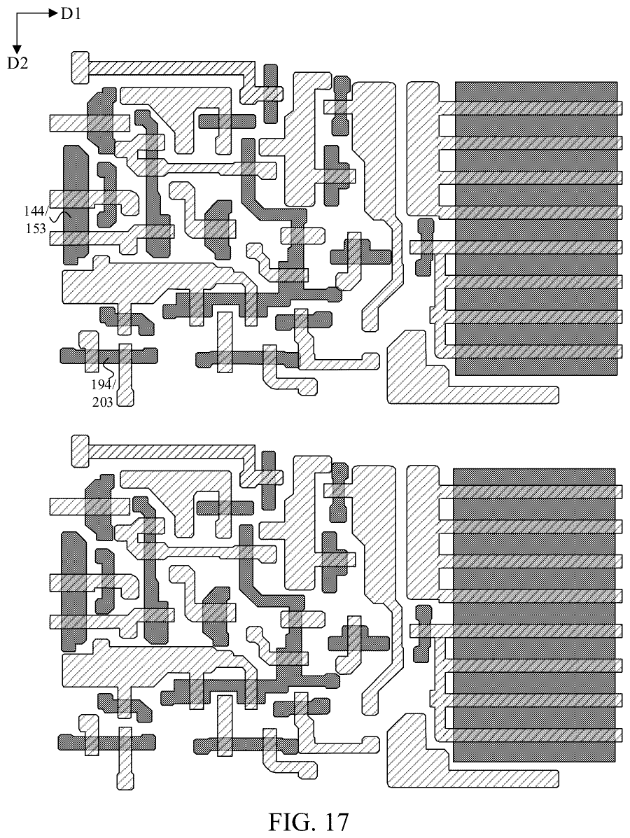

In an exemplary implementation mode, as shown in FIGS. 16 and 17, the pattern of the first conductive layer in the display substrate according to FIGS. 7 and 9 to 11 may include at least a gate electrode 12 of a first transistor to a gate electrode 262 of a twenty-sixth transistor, a first electrode plate C11 of a first capacitor to a first electrode plate C61 of a sixth capacitor located in each stage shift register.

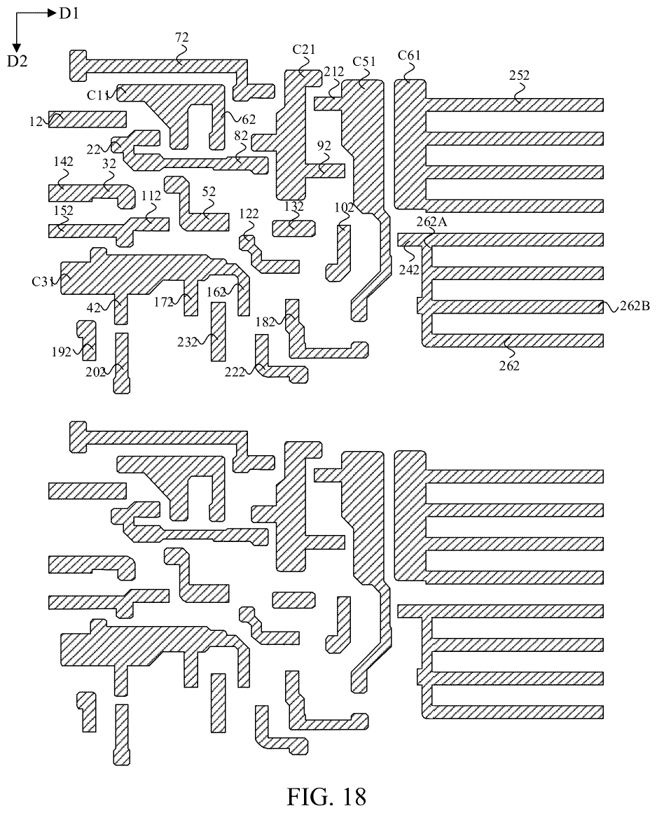

In an exemplary implementation mode, as shown in FIGS. 18 and 19, the pattern of the first conductive layer in the display substrate according to FIG. 8 may include at least a gate electrode 12 of a first transistor to a gate electrode 262 of a twenty-sixth transistor, a first electrode plate C11 of a first capacitor to a first electrode plate C31 of a third capacitor, a first electrode plate C51 of a fifth capacitor, and a first electrode plate C61 of a sixth capacitor located in each stage shift register.

In an exemplary implementation mode, the gate electrode 12 of the first transistor is disposed separately. The gate electrode 12 of the first transistor is in a shape of a strip, and extends in the first direction D1.

In an exemplary implementation mode, a gate electrode 22 of the second transistor and a gate electrode 82 of the eighth transistor are of an integral structure. The gate electrode 22 of the second transistor may have a shape of a letter “n” with an opening facing the display region, and the gate electrode 82 of the eighth transistor may have a polyline shape and extends at least partially in the first direction D1.

In an exemplary implementation mode, a gate electrode 32 of the third transistor and a gate electrode 142 of the fourteenth transistor are of an integral structure. The integral structure of the gate electrode 32 of the third transistor and the gate electrode 142 of the fourteenth transistor may have a shape of a strip, and extend in the first direction D1.

In an exemplary implementation mode, a gate electrode 42 of the fourth transistor, a gate electrode 162 of the sixteenth transistor, a gate electrode 172 of the seventeenth transistor, and the first electrode plate C31 of the third capacitor are of an integral structure. A shape of C31 of the third capacitor is a rectangular shape. The gate electrode 42 of the fourth transistor and the gate electrode 172 of the seventeenth transistor in a current stage shift register are located on a side of the third capacitor C31 close to a next stage shift register, and the gate electrode 42 of the fourth transistor and the gate electrode 172 of the seventeenth transistor have a shape of a stripe, and extend in the second direction D2. The gate electrode 162 of the sixteenth transistor is located on a side of the first electrode plate C31 of the third capacitor close to the display region, and the gate electrode 162 of the sixteenth transistor has a shape of “┐”. The integral structure of the gate electrode 42 of the fourth transistor, the gate electrode 162 of the sixteenth transistor, the gate electrode 172 of the seventeenth transistor, and the first electrode plate C31 of the third capacitor may have a shape of a letter “m”.

In an exemplary implementation mode, a gate electrode 52 of the fifth transistor is disposed separately. The gate electrode 52 of the fifth transistor may have a shape of “└”.

In an exemplary implementation mode, a gate electrode 62 of the sixth transistor and the first electrode plate C11 of the first capacitor are of an integral structure. The gate electrode 62 of the sixth transistor is located on a side of the first electrode plate C11 of the first capacitor close to the display region. The first electrode plate C11 of the first capacitor may have a shape of a letter “T”, and the gate electrode 62 of the sixth transistor may have a shape of a strip and extends at least partially in the second direction D2. The integral structure of the gate electrode 62 of the sixth transistor and the first electrode plate C11 of the first capacitor may have a shape of a letter “n”.

In an exemplary implementation mode, a gate electrode 72 of the seventh transistor is disposed separately. The gate electrode 72 of the seventh transistor has a polyline shape and extends at least partially in the first direction D1. The gate electrode 72 of the seventh transistor is at least partially disposed around one side of the first electrode plate C11 of the first capacitor.

In an exemplary implementation mode, a gate electrode 92 of the ninth transistor and a first electrode plate C21 of a second capacitor are of an integral structure. The gate electrode 92 of the ninth transistor is located on a side of the first electrode plate C21 of the second capacitor close to the display region. The gate electrode 92 of the ninth transistor and the first electrode plate C21 of the second capacitor are of an integral structure and may have a shape of a letter “F”.

In an exemplary implementation mode, a gate electrode 102 of the tenth transistor is disposed separately. The gate electrode 102 of the tenth transistor has a shape of a strip and extends in the second direction D2.

In an exemplary implementation mode, a gate electrode 112 of the eleventh transistor and a gate electrode 152 of the fifteenth transistor are of an integral structure, and the gate electrode 112 of the eleventh transistor (also the gate electrode 152 of the fifteenth transistor) has a shape of a strip and extends in the first direction D1.

In an exemplary implementation mode, a gate electrode 122 of the twelfth transistor is disposed separately. The gate electrode 122 of the twelfth transistor may have a shape of a strip and extend at least partially in the first direction D1.

In an exemplary implementation mode, a gate electrode 132 of the thirteenth transistor is disposed separately. The gate electrode 132 of the thirteenth transistor has a shape of a strip and extends in the first direction D1.

In an exemplary implementation mode, a gate electrode 182 of the eighteenth transistor is disposed separately. The gate electrode 182 of the eighteenth transistor may have a shape of “└”.

In an exemplary implementation mode, a gate electrode 192 of the nineteenth transistor is disposed separately. The gate electrode 192 of the nineteenth transistor has a shape of a strip and extends in the second direction D2.

In an exemplary implementation mode, a gate electrode 202 of the twentieth transistor is disposed separately, and the gate electrode 202 of the twentieth transistor may have a shape of a strip and extend in the second direction D2.

In an exemplary implementation mode, a gate electrode 212 of the twenty-first transistor and the first electrode plate C51 of the fifth capacitor are of an integral structure. The gate electrode 212 of the twenty-first transistor is located on a side of the first electrode plate C51 of the fifth capacitor away from the display region. The integral structure of the gate electrode 212 of the twenty-first transistor and the first electrode plate C51 of the fifth capacitor has a shape of a strip and extends at least partially in the second direction D2.

In an exemplary implementation mode, a gate electrode 222 of the twenty-second transistor is disposed separately. The gate electrode 222 of the twenty-second transistor may have a shape of “└”.

In an exemplary implementation mode, a gate electrode 232 of the twenty-third transistor is disposed separately, and the gate electrode 232 of the twenty-third transistor may have a shape of a strip and extend in the second direction D2.

In an exemplary implementation mode, a gate electrode 242 of the twenty-fourth transistor and the gate electrode 262 of the twenty-sixth transistor are of an integral structure.

The gate electrode 242 of the twenty-fourth transistor is located on a side of the gate electrode 262 of the twenty-sixth transistor away from the display region. The integral structure of the gate electrode 242 of the twenty-fourth transistor and the gate electrode 262 of the twenty-sixth transistor has a “comb-like” structure in shape, whose comb teeth are located on a side of a comb back close to the display region.

In an exemplary implementation mode, a gate electrode 252 of the twenty-fifth transistor and the first electrode plate C61 of the sixth capacitor are of an integral structure. The gate electrode 252 of the twenty-fifth transistor is located on a side of the first electrode plate C61 of the sixth capacitor close to the display region. The integral structure of the gate electrode 252 of the twenty-fifth transistor and the first electrode plate C61 of the sixth capacitor has a “comb-like” structure in shape, whose comb teeth are located on a side of a comb back close to the display region.

In an exemplary implementation mode, the first electrode plate C1 of the fourth capacitor is disposed separately. The first electrode plate C1 of the fourth capacitor may have a shape of “└”.

In an exemplary implementation mode, the gate electrode 12 of the first transistor is disposed across the active pattern of the first transistor, the gate electrode 22 of the second transistor (also the gate electrode 82 of the eighth transistor) is disposed across the active pattern of the second transistor and the active pattern of the eighth transistor, the gate electrode 32 of the third transistor (also the gate electrode 142 of the fourteenth transistor) is disposed across the active pattern of the third transistor and the active pattern of the fourteenth transistor, the gate electrode 42 of the fourth transistor (also the first electrode plate C31 of the third capacitor, the gate electrode 162 of the sixteenth transistor, and the gate electrode 172 of the seventeenth transistor) is disposed across the active pattern of the fourth transistor, the active pattern of the sixteenth transistor, and the active pattern of the seventeenth transistor, the gate electrode 52 of the fifth transistor is disposed across the active pattern of the fifth transistor, the gate electrode 62 of the sixth transistor (also the first electrode plate C11 of the first capacitor) is disposed across the active pattern of the sixth transistor, the gate electrode 72 of the seventh transistor is disposed across the active pattern of the seventh transistor, the gate electrode 92 of the ninth transistor (also the first electrode plate C21 of the second capacitor) is disposed across the active pattern of the ninth transistor, the gate electrode 102 of the tenth transistor is disposed across the active pattern of the tenth transistor, the gate electrode 112 of the eleventh transistor (also the gate electrode 152 of the fifteenth transistor) is disposed across the active pattern of the eleventh transistor and the active pattern of the fifteenth transistor, the gate electrode 122 of the twelfth transistor is disposed across the active pattern of the twelfth transistor, the gate electrode 132 of the thirteenth transistor is disposed across the active pattern of the thirteenth transistor, the gate electrode 182 of the eighteenth transistor is disposed across the active pattern of the eighteenth transistor, the gate electrode 192 of the nineteenth transistor is disposed across the active pattern of the nineteenth transistor, the gate electrode 202 of the twentieth transistor is disposed across the active pattern of the twentieth transistor, the gate electrode 212 of the twenty-first transistor (also the first electrode plate C51 of the fifth capacitor) is disposed across the active pattern of the twenty-first transistor, the gate electrode 222 of the twenty-second transistor is disposed across the active pattern of the twenty-second transistor, the gate electrode 232 of the twenty-third transistor is disposed across the active pattern of the twenty-third transistor, the gate electrode 242 of the twenty-fourth transistor (also the gate electrode 262 of the twenty-sixth transistor) is disposed across the active pattern of the twenty-fourth transistor and the active pattern of the twenty-sixth transistor, the gate electrode 252 of the twenty-fifth transistor is disposed across the active pattern of the twenty-fifth transistor, that is to say, an extension direction of a gate electrode of at least one transistor is perpendicular to an extension direction of an active pattern.

In an exemplary implementation mode, after the pattern of the first conductive layer is formed, a conductive treatment may be performed on the semiconductor layer by using the first conductive layer as a shield. The semiconductor layer in a region which is shielded by the first conductive layer, forms channel regions of the first transistor to the twenty-sixth transistor, and the semiconductor layer in a region which is not shielded by the first conductive layer, is made to be conductive, that is, a first region and a second region of an active pattern of any of the first transistor to the twenty-sixth transistor are all made to be conductive. As shown in FIGS. 17 and 19, the second region of the active pattern of the fourteenth transistor (also the first region of the active pattern of the fifteenth transistor) after the conductive treatment in the present disclosure is used as the second electrode 144 of the fourteenth transistor (also the first electrode 153 of the fifteenth transistor), and the second region of the active pattern of the nineteenth transistor (also the first region of the active pattern of the twentieth transistor) is used as the second electrode 194 of the nineteenth transistor (also the first electrode 203 of the twentieth transistor).

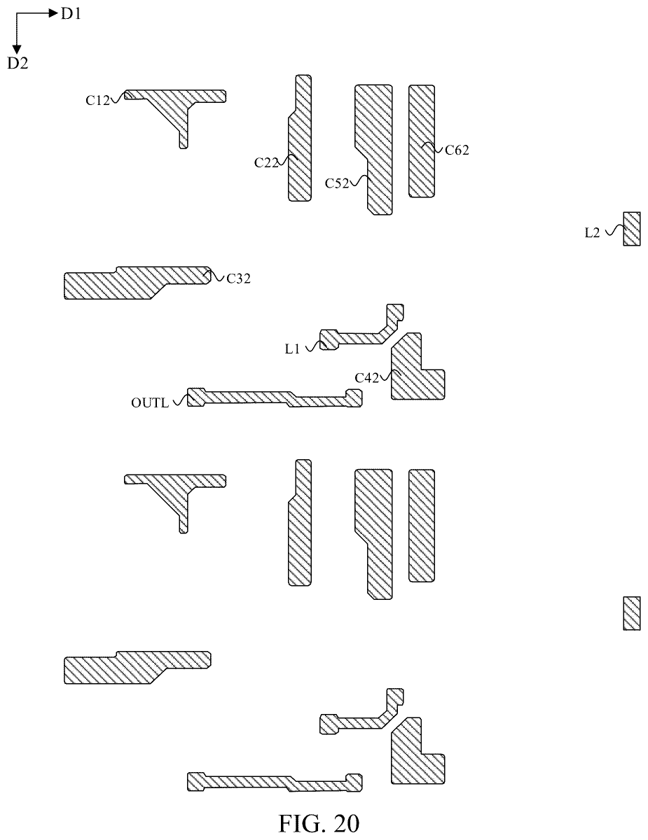

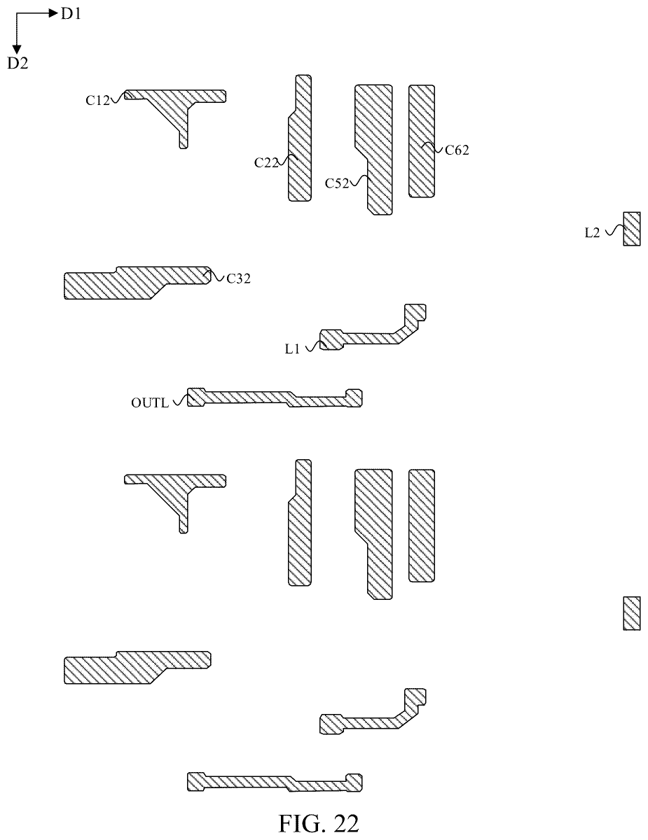

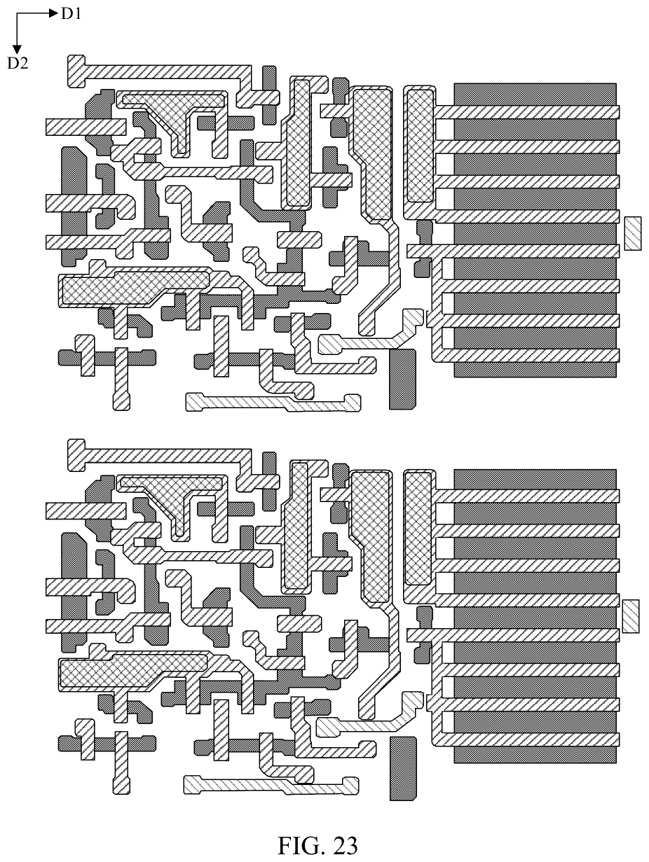

(3) A pattern of a second conductive layer is formed. In an exemplary implementation mode, forming the pattern of the second conductive layer may include: depositing a second insulation thin film and a second conductive thin film on the base substrate on which the above-mentioned patterns are formed, patterning the second conductive thin film through a patterning process, forming a pattern of a second insulation layer covering the pattern of the first conductive layer and the pattern of the second conductive layer located on the pattern of the second insulation layer, as shown in FIGS. 20 to 23, FIG. 20 is a schematic diagram of a pattern of a second conductive layer in the display substrate according to FIGS. 7 and 9 to 11, FIG. 21 is a schematic diagram of forming a pattern of a second conductive layer in the display substrate according to FIGS. 7 and 9 to 11, FIG. 22 is a schematic diagram of a pattern of a second conductive layer in the display substrate according to FIG. 8, FIG. 23 is a schematic diagram of forming a pattern of a second conductive layer in the display substrate according to FIG. 8. In an exemplary implementation mode, the second conductive layer may be referred to as a second gate metal (GATE2) layer.

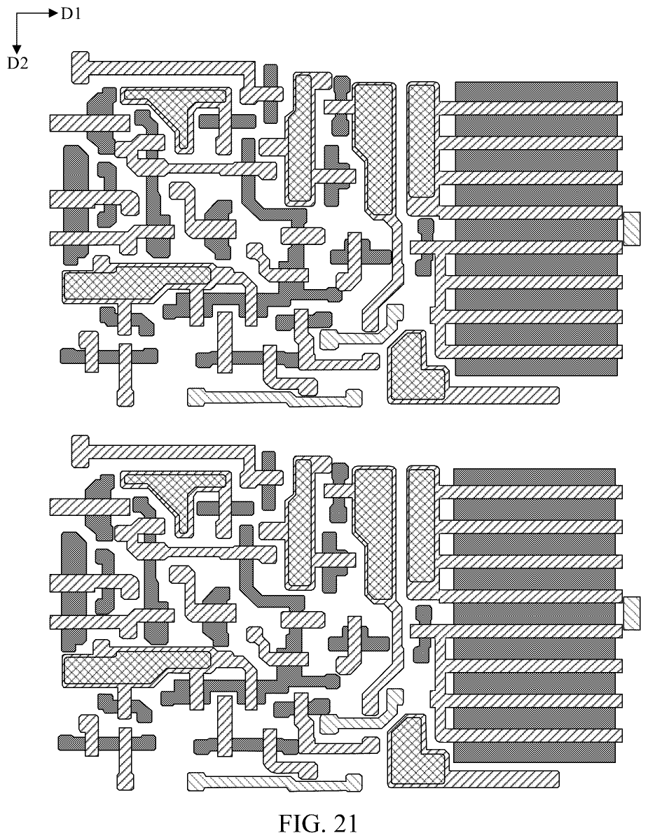

In an exemplary implementation mode, as shown in FIGS. 20 and 21, in the display substrate according to FIGS. 7 and 9 to 11, the pattern of the second conductive layer may include at least a second electrode plate C12 of a first capacitor to a second electrode plate C62 of a sixth capacitor, a cascaded output line OUTL, a first connection line L1, and a second connection line L2 located in each stage shift register.

In an exemplary implementation mode, in the display substrate according to FIG. 8, the pattern of the second conductive layer may include at least a second electrode plate C12 of a first capacitor to a second electrode plate C32 of a third capacitor, a second electrode plate C52 of a fifth capacitor, a second electrode plate C62 of a sixth capacitor, a cascaded output line OUTL, a first connection line L1, and a second connection line L2 located in each stage shift register.

In an exemplary implementation mode, an orthographic projection of the second electrode plate C12 of the first capacitor on the base substrate is at least partially overlapped with an orthographic projection of the first electrode plate of the first capacitor on the base substrate. An area of the second electrode plate C12 of the first capacitor is smaller than an area of the first electrode plate of the first capacitor. A shape of the second electrode plate C12 of the first capacitor is the same as a shape of the first electrode plate of the first capacitor.

In an exemplary implementation mode, an orthographic projection of a second electrode plate C22 of a second capacitor on the base substrate is at least partially overlapped with an orthographic projection of the first electrode plate of the second capacitor on the base substrate. An area of the second electrode plate C22 of the second capacitor is smaller than an area of the first electrode plate of the second capacitor. A shape of the second electrode plate C22 of the second capacitor is the same as a shape of the first electrode plate of the second capacitor.

In an exemplary implementation mode, an orthographic projection of the second electrode plate C32 of the third capacitor on the base substrate is at least partially overlapped with an orthographic projection of the first electrode plate of the third capacitor on the base substrate. An area of the second electrode plate C32 of the third capacitor is smaller than an area of the first electrode plate of the third capacitor. A shape of the second electrode plate C32 of the third capacitor is the same as a shape of the first electrode plate of the third capacitor.

In an exemplary implementation mode, an orthographic projection of a second electrode plate C42 of the fourth capacitor on the base substrate is at least partially overlapped with an orthographic projection of the first electrode plate of the fourth capacitor on the base substrate. An area of the second electrode plate C42 of the fourth capacitor is smaller than an area of the first electrode plate of the fourth capacitor.

In an exemplary implementation mode, an orthographic projection of the second electrode plate C52 of the fifth capacitor on the base substrate is at least partially overlapped with an orthographic projection of the first electrode plate of the fifth capacitor on the base substrate. The second electrode plate C52 of the fifth capacitor has a same shape as the first electrode plate of the fifth capacitor, and an area of the second electrode plate C52 of the fifth capacitor is less than an area of the first electrode plate of the fifth capacitor.

In an exemplary implementation mode, an orthographic projection of the second electrode plate C62 of the sixth capacitor on the base substrate is at least partially overlapped with an orthographic projection of the first electrode plate of the sixth capacitor on the base substrate. The second electrode plate C62 of the sixth capacitor has a same shape as the first electrode plate C51 of the sixth capacitor, and an area of the second electrode plate C62 of the sixth capacitor is less than an area of the first electrode plate of the sixth capacitor.

In an exemplary implementation mode, the cascaded output line OUTL has a shape of a strip and extends in the first direction D1.

In an exemplary implementation mode, an orthographic projection of the first connection line L1 on the base substrate is located between an orthographic projection of the gate electrode of the eighteenth transistor on the base substrate and an orthographic projection of the gate electrode of the twenty-first transistor (also the first electrode plate of the fifth capacitor) on the base substrate. The first connection line L1 has a polyline shape and extends at least partially in the first direction D1.

In an exemplary implementation mode, an orthographic projection of the second connection line L2 on the base substrate is located on a side of an orthographic projection of the gate electrode of the twenty-fifth transistor (also the gate electrode of the twenty-sixth transistor) on the base substrate close to the display region. The second connection line L2 has a shape of a strip and extends in the second direction D2.

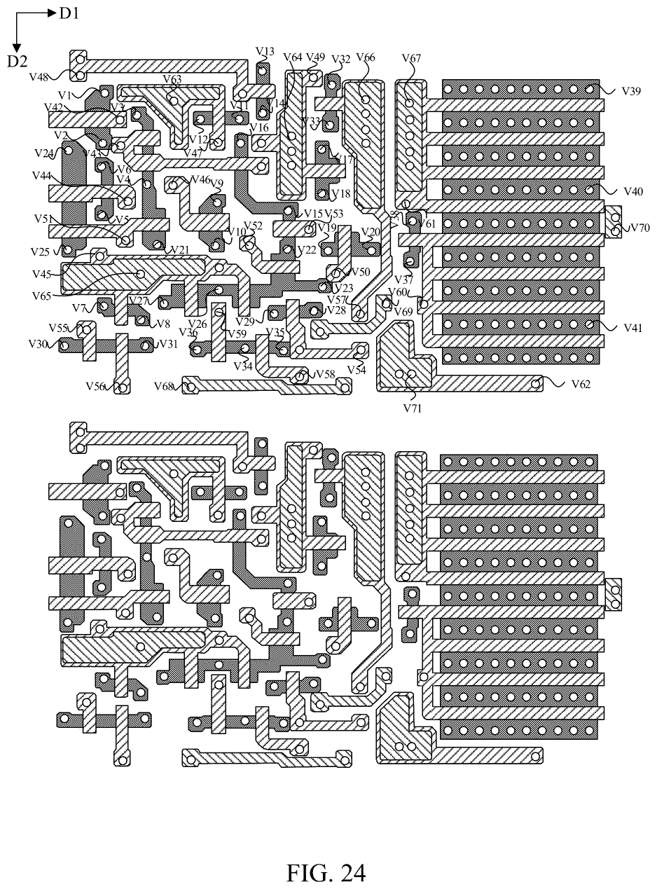

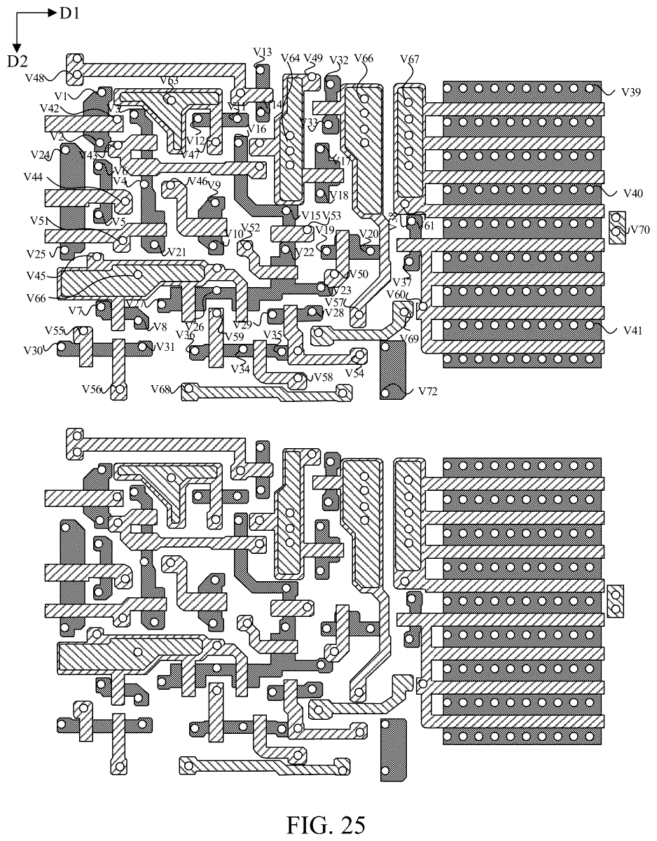

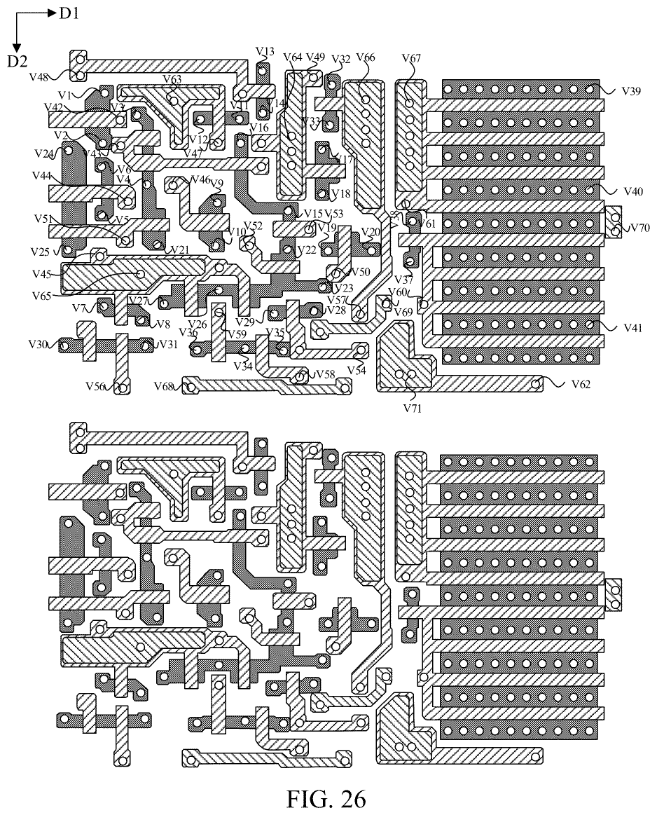

(4) A pattern of a third insulation layer is formed. In an exemplary implementation mode, forming the pattern of the third insulation layer may include: depositing a third insulation thin film on the base substrate on which the above-mentioned patterns are formed, patterning the third insulation thin film through a patterning process to form the pattern of the third insulation layer covering the above-mentioned structure, and the third insulation layer is provided with patterns of a plurality of vias, as shown in FIGS. 24 and 25, FIG. 24 is a schematic diagram of the display substrate according to FIGS. 7, 10, and 11 after a pattern of a third insulation layer is formed, FIG. 25 is a schematic diagram of the display substrate according to FIG. 8 after a pattern of a third insulation layer is formed, and FIG. 26 is a schematic diagram of the display substrate according to FIG. 9 after a pattern of a third insulation layer is formed.

In an exemplary implementation mode, as shown in FIG. 24, in the display substrate according to FIGS. 7, 10, and 11, the pattern of the third insulation layer may include at least a first via V1 to a seventy-first via V71 located in each stage shift register.

In an exemplary implementation mode, as shown in FIG. 25, in the display substrate according to FIG. 8, the pattern of the third insulation layer may include at least a first via V1 to a sixty-first via V61, a sixty-third via V63 to a seventieth via V70, and a seventy-second via V72 located in each stage shift register.

In an exemplary implementation mode, as shown in FIG. 26, in the display substrate according to FIG. 9, the pattern of the third insulation layer may include at least a first via V1 to a fifty-fourth via V54, a fifty-sixth via V56 to a seventy-first via V71 located in each stage shift register.

In an exemplary implementation mode, an orthographic projection of the first via V1 on the base substrate is located within a range of an orthographic projection of the first region of the active pattern of the first transistor on the base substrate. The first insulation layer and the second insulation layer within the first via V1 are etched away to expose a surface of the first region of the active pattern of the first transistor, and the first via V1 is configured such that the first electrode of the first transistor (also the first electrode of the fourteenth transistor) formed subsequently is connected with the first region of the active pattern of the first transistor through the via.

In an exemplary implementation mode, an orthographic projection of the second via V2 on the base substrate is located within a range of an orthographic projection of a second region of the active pattern of the first transistor on the base substrate, the first insulation layer and the second insulation layer within the second via V2 are etched away to expose a surface of the second region of the active pattern of the first transistor, and the second via V2 is configured such that a second electrode of the first transistor formed subsequently is connected with the second region of the active pattern of the first transistor through the via.

In an exemplary implementation mode, an orthographic projection of the third via V3 on the base substrate is located within a range of an orthographic projection of a first region of the active pattern of the second transistor on the base substrate, the first insulation layer and the second insulation layer within the third via V3 are etched away to expose a surface of the first region of the active pattern of the second transistor, and the third via V3 is configured such that a first electrode of the second transistor formed subsequently is connected with the first region of the active pattern of the second transistor through the via.

In an exemplary implementation mode, an orthographic projection of the fourth via V4 on the base substrate is located within a range of an orthographic projection of a second region of the active pattern of the second transistor (also a first region of the active pattern of the eleventh transistor) on the base substrate, and the first insulation layer and the second insulation layer within the fourth via V4 are etched away to expose a surface of the second region of the active pattern of the second transistor (also the first region of the active pattern of the eleventh transistor), and the fourth via V4 is configured such that a second electrode of the second transistor of the second transistor (also a second electrode of the third transistor and a first electrode of the eleventh transistor) formed subsequently is connected with the second region of the active pattern of the second transistor (also the first region of the active pattern of the eleventh transistor) through the via.

In an exemplary implementation mode, an orthographic projection of the fifth via V5 on the base substrate is located within a range of an orthographic projection of a first region of the active pattern of the third transistor on the base substrate, the first insulation layer and the second insulation layer within the fifth via V5 are etched away to expose a surface of the first region of the active pattern of the third transistor, and the fifth via V5 is configured such that a first electrode of the third transistor formed subsequently is connected with the first region of the active pattern of the third transistor through the via.

In an exemplary implementation mode, an orthographic projection of the sixth via V6 on the base substrate is located within a range of an orthographic projection of the second region of the active pattern of the third transistor on the base substrate. The first insulation layer and the second insulation layer within the sixth via V6 are etched away to expose a surface of the second region of the active pattern of the third transistor, and the sixth via V6 is configured such that the second electrode of the second transistor (also the second electrode of the third transistor and the first electrode of the eleventh transistor) formed subsequently is connected with the second region of the active pattern of the third transistor through the via.

In an exemplary implementation mode, an orthographic projection of the seventh via V7 on the base substrate is located within a range of an orthographic projection of a first region of the active pattern of the fourth transistor on the base substrate, the first insulation layer and the second insulation layer within the seventh via V7 are etched away to expose a surface of the first region of the active pattern of the fourth transistor, and the seventh via V7 is configured such that a first electrode of the fourth transistor formed subsequently is connected with the first region of the active pattern of the fourth transistor through the via.

In an exemplary implementation mode, an orthographic projection of the eighth via V8 on the base substrate is located within a range of an orthographic projection of a second region of the active pattern of the fourth transistor on the base substrate. The first insulation layer and the second insulation layer within the eighth via V8 are etched away to expose a surface of the second region of the active pattern of the fourth transistor, and the eighth via V8 is configured such that a second electrode of the fourth transistor (also the second electrode of the fifth transistor) formed subsequently is connected with the second region of the active pattern of the fourth transistor through the via.

In an exemplary implementation mode, an orthographic projection of the ninth via V9 on the base substrate is located within a range of an orthographic projection of a first region of the active pattern of the fifth transistor on the base substrate, the first insulation layer and the second insulation layer within the ninth via V9 are etched away to expose a surface of the second region of the active pattern of the fifth transistor, and the ninth via V9 is configured such that a first electrode of the fifth transistor formed subsequently is connected with the first region of the active pattern of the fifth transistor through the via.

In an exemplary implementation mode, an orthographic projection of the tenth via V10 on the base substrate is located within a range of an orthographic projection of a second region of the active pattern of the fifth transistor on the base substrate. The first insulation layer and the second insulation layer within the tenth via V10 are etched away to expose a surface of the second region of the active pattern of the fifth transistor, and the tenth via V10 is configured such that a second electrode of the fourth transistor (also a second electrode of the fifth transistor) formed subsequently is connected with the second region of the active pattern of the fifth transistor through the via.

In an exemplary implementation mode, an orthographic projection of the eleventh via V11 on the base substrate is located within a range of an orthographic projection of a first region of the active pattern of the sixth transistor on the base substrate, the first insulation layer and the second insulation layer within the eleventh via V11 are etched away to expose a surface of the first region of the active pattern of the sixth transistor, and the eleventh via V11 is configured such that a first electrode of the sixth transistor formed subsequently is connected with the first region of the active pattern of the sixth transistor through the via.

In an exemplary implementation mode, an orthographic projection of the twelfth via V12 on the base substrate is located within a range of an orthographic projection of a second region of the active pattern of the sixth transistor on the base substrate. The first insulation layer and the second insulation layer within the twelfth via V12 is etched away to expose a surface of the second region of the active pattern of the sixth transistor, and the twelfth via V12 is configured such that a second electrode of the sixth transistor (also a first electrode of the seventh transistor) formed subsequently is connected with the second region of the active pattern of the sixth transistor through the via.

In an exemplary implementation mode, an orthographic projection of the thirteenth via V13 on the base substrate is located within a range of an orthographic projection of a first region of the active pattern of the seventh transistor on the base substrate, the first insulation layer and the second insulation layer within the thirteenth via V13 are etched away to expose a surface of the first region of the active pattern of the seventh transistor, and the thirteenth via V13 is configured such that a second electrode of the sixth transistor (also a first electrode of the seventh transistor) formed subsequently is connected with the first region of the active pattern of the seventh transistor through the via.

In an exemplary implementation mode, an orthographic projection of the fourteenth via V14 on the base substrate is located within a range of an orthographic projection of a second region of the active pattern of the seventh transistor on the base substrate, the first insulation layer and the second insulation layer within the fourteenth via V14 are etched away to expose a surface of the second region of the active pattern of the seventh transistor, and the fourteenth via V14 is configured such that a second electrode of the seventh transistor (also a second electrode of the eighth transistor) formed subsequently is connected with the second region of the active pattern of the seventh transistor through the via.

In an exemplary implementation mode, an orthographic projection of the fifteenth via V15 on the base substrate is located within a range of an orthographic projection of a first region of the active pattern of the eighth transistor (a first region of the active pattern of the thirteenth transistor) on the base substrate, the first insulation layer and the second insulation layer within the fifteenth via V15 are etched away to expose a surface of the first region of the active pattern of the eighth transistor (the first region of the active pattern of the thirteenth transistor), and the fifteenth via V15 is configured such that a first electrode of the eighth transistor (also a first electrode of the ninth transistor, a first electrode of the thirteenth transistor, and a first electrode of the twenty-fifth transistor) formed subsequently is connected with the first region of the active pattern of the eighth transistor (the first region of the active pattern of the thirteenth transistor) through the via.

In an exemplary implementation mode, an orthographic projection of the sixteenth via V16 on the base substrate is located within a range of an orthographic projection of a second region of the active pattern of the eighth transistor on the base substrate, the first insulation layer and the second insulation layer within the sixteenth via V16 are etched away to expose a surface of the second region of the active pattern of the eighth transistor, and the sixteenth via V16 is configured such that a second electrode of the seventh transistor (also a first electrode of the eighth transistor) formed subsequently is connected with the second region of the active pattern of the eighth transistor through the via.

In an exemplary implementation mode, an orthographic projection of the seventeenth via V17 on the base substrate is located within a range of an orthographic projection of a first region of the active pattern of the ninth transistor on the base substrate, the first insulation layer and the second insulation layer within the seventeenth via V17 are etched away to expose a surface of the first region of the active pattern of the ninth transistor, and the seventeenth via V17 is configured such that a first electrode of the eighth transistor (also a first electrode of the ninth transistor, a first electrode of the thirteenth transistor, and a first electrode of the twenty-fifth transistor) formed subsequently is connected with the first region of the active pattern of the ninth transistor through the via.

In an exemplary implementation mode, an orthographic projection of the eighteenth via V18 on the base substrate is located within a range of an orthographic projection of a second region of the active pattern of the ninth transistor on the base substrate, the first insulation layer and the second insulation layer within the eighteenth via V18 are etched away to expose a surface of the second region of the active pattern of the ninth transistor, and the eighteenth via V18 is configured such that a second electrode of the ninth transistor (also a second electrode of the tenth transistor) formed subsequently is connected with the second region of the active pattern of the ninth transistor through the via.

In an exemplary implementation mode, an orthographic projection of the nineteenth via V19 on the base substrate is located within a range of an orthographic projection of a first region of the active pattern of the tenth transistor on the base substrate, the first insulation layer and the second insulation layer within the nineteenth via V19 are etched away to expose a surface of the first region of the active pattern of the tenth transistor, and the nineteenth via V19 is configured such that a first electrode of the tenth transistor formed subsequently is connected with the first region of the active pattern of the tenth transistor through the via.

In an exemplary implementation mode, an orthographic projection of the twentieth via V20 on the base substrate is located within a range of an orthographic projection of a second region of the active pattern of the tenth transistor on the base substrate. The first insulation layer and the second insulation layer within the twentieth via V20 are etched away, to expose a surface of the second region of the active pattern of the tenth transistor. The twentieth via V20 is configured such that the second electrode of the ninth transistor (also the second electrode of the tenth transistor) formed subsequently is connected with the second region of the active pattern of the tenth transistor through the via.

In an exemplary implementation mode, an orthographic projection of the twenty-first via V21 on the base substrate is located within a range of an orthographic projection of the second region of the active pattern of the eleventh transistor on the base substrate. The first insulation layer and the second insulation layer within the twenty-first via V21 are etched away, to expose a surface of the second region of the active pattern of the eleventh transistor. The twenty-first via V21 is configured such that a second electrode of the eleventh transistor formed subsequently is connected with the second region of the active pattern of the eleventh transistor through the via.

In an exemplary implementation mode, an orthographic projection of the twenty-second via V22 on the base substrate is located within a range of an orthographic projection of a first region of the active pattern of the twelfth transistor (also a second region of the active pattern of the thirteenth transistor) on the base substrate, the first insulation layer and the second insulation layer within the twenty-second via V22 are etched away to expose a surface of the first region of the active pattern of the twelfth transistor (also the second region of the active pattern of the thirteenth transistor), and the twenty-second via V22 is configured such that a first electrode of the twelfth transistor (also a second electrode of the thirteenth transistor and a first electrode of the eighteenth transistor) formed subsequently is connected with the first region of the active pattern of the twelfth transistor (also the second region of the active pattern of the thirteenth transistor) through the via.

In an exemplary implementation mode, an orthographic projection of the twenty-third via V23 on the base substrate is located within a range of an orthographic projection of the second region of the active pattern of the twelfth transistor (also the second region of the active pattern of the sixteenth transistor) on the base substrate. The first insulation layer and the second insulation layer within the twenty-third via V23 are etched away to expose a surface of the second region of the active pattern of the twelfth transistor (also the second region of the active pattern of the sixteenth transistor), and the twenty-third via V23 is configured such that a second electrode of the twelfth transistor (also a second electrode of the sixteenth transistor) formed subsequently is connected with the second region of the active pattern of the twelfth transistor (also the second region of the active pattern of the sixteenth transistor) through the via.

In an exemplary implementation mode, an orthographic projection of the twenty-fourth via V24 on the base substrate is located within a range of an orthographic projection of the first region of the active pattern of the fourteenth transistor on the base substrate. The first insulation layer and the second insulation layer within the twenty-fourth via V24 are etched away to expose a surface of the first region of the active pattern of the fourteenth transistor, and the twenty-fourth via V24 is configured such that a first electrode of the first transistor (also a first electrode of the fourteenth transistor) formed subsequently is connected with the first region of the active pattern of the fourteenth transistor through the via.

In an exemplary implementation mode, an orthographic projection of the twenty-fifth via V25 on the base substrate is located within a range of an orthographic projection of a second region of the active pattern of the fifteenth transistor on the base substrate, the first insulation layer and the second insulation layer within the twenty-fifth via V25 are etched away to expose a surface of the second region of the active pattern of the fifteenth transistor, and the twenty-fifth via V25 is configured such that a second electrode of the fifteenth transistor formed subsequently is connected with the second region of the active pattern of the fifteenth transistor through the via.

In an exemplary implementation mode, an orthographic projection of the twenty-sixth via V26 on the base substrate is located within a range of an orthographic projection of a first region of the active pattern of the sixteenth transistor (also a first region of the active pattern of the seventeenth transistor) on the base substrate, the first insulation layer and the second insulation layer within the twenty-sixth via V26 are etched away to expose a surface of the first region of the active pattern of the sixteenth transistor (also the first region of the active pattern of the seventeenth transistor), and the twenty-sixth via V26 is configured such that a first electrode of the sixteenth transistor (also a first electrode of the seventeenth transistor) formed subsequently is connected with the first region of the active pattern of the sixteenth transistor (also the first region of the active pattern of the seventeenth transistor) through the via.

In an exemplary implementation mode, an orthographic projection of the twenty-seventh via V27 on the base substrate is located within a range of an orthographic projection of a second region of the active pattern of the seventeenth transistor on the base substrate, the first insulation layer and the second insulation layer within the twenty-seventh via V27 are etched away to expose a surface of the second region of the active pattern of the seventeenth transistor, and the twenty-seventh via V27 is configured such that a second electrode of the seventeenth transistor (also a second electrode of the eighteenth transistor) formed subsequently is connected with the second region of the active pattern of the seventeenth transistor through the via.

In an exemplary implementation mode, an orthographic projection of the twenty-eighth via V28 on the base substrate is located within a range of an orthographic projection of a first region of the active pattern of the eighteenth transistor on the base substrate, the first insulation layer and the second insulation layer within the twenty-eighth via V28 are etched away to expose a surface of the first region of the active pattern of the eighteenth transistor, and the twenty-eighth via V28 is configured such that a first electrode of the twelfth transistor (also a second electrode of the thirteenth transistor and a first electrode of the eighteenth transistor) formed subsequently is connected with the first region of the active pattern of the eighteenth transistor through the via.

In an exemplary implementation mode, an orthographic projection of the twenty-ninth via V29 on the base substrate is located within a range of an orthographic projection of a second region of the active pattern of the eighteenth transistor on the base substrate, the first insulation layer and the second insulation layer within the twenty-ninth via V29 are etched away to expose a surface of the second region of the active pattern of the eighteenth transistor, and the twenty-ninth via V29 is configured such that a second electrode of the seventeenth transistor (also a second electrode of the eighteenth transistor) formed subsequently is connected with the second region of the active pattern of the eighteenth transistor through the via.

In an exemplary implementation mode, an orthographic projection of the thirtieth via V30 on the base substrate is located within a range of an orthographic projection of a first region of the active pattern of the nineteenth transistor on the base substrate, the first insulation layer and the second insulation layer within the thirtieth via V30 are etched away to expose a surface of the first region of the active pattern of the nineteenth transistor, and the thirtieth via V30 is configured such that a first electrode of the nineteenth transistor formed subsequently is connected with the first region of the active pattern of the nineteenth transistor through the via.

In an exemplary implementation mode, an orthographic projection of the thirty-first via V31 on the base substrate is located within a range of an orthographic projection of a second region of the active pattern of the twentieth transistor on the base substrate, the first insulation layer and the second insulation layer within the thirty-first via V31 are etched away to expose a surface of the second region of the active pattern of the twentieth transistor, and the thirty-first via V31 is configured such that a second electrode of the twentieth transistor (also a second electrode of the twenty-second transistor and a second electrode of the twenty-third transistor) formed subsequently is connected with the second region of the active pattern of the twentieth transistor through the via.

In an exemplary implementation mode, an orthographic projection of the thirty-second via V32 on the base substrate is located within a range of an orthographic projection of a first region of the active pattern of the twenty-first transistor on the base substrate, the first insulation layer and the second insulation layer within the thirty-second via V32 are etched away to expose a surface of the first region of the active pattern of the twenty-first transistor, and the thirty-second via V32 is configured such that a first electrode of the twenty-first transistor formed subsequently is connected with the first region of the active pattern of the twenty-first transistor through the via.

In an exemplary implementation mode, an orthographic projection of the thirty-third via V33 on the base substrate is located within a range of an orthographic projection of a second region of the active pattern of the twenty-first transistor on the base substrate, the first insulation layer and the second insulation layer within the thirty-third via V33 are etched away to expose a surface of the second region of the active pattern of the twenty-first transistor, and the thirty-third via V33 is configured such that a second electrode of the twenty-first transistor (also a second electrode of the twenty-fourth transistor) formed subsequently is connected with the second region of the active pattern of the twenty-first transistor through the via.

In an exemplary implementation mode, an orthographic projection of the thirty-fourth via V34 on the base substrate is located within a range of an orthographic projection of a first region of the active pattern of the twenty-second transistor (also a first region of the active pattern of the twenty-third transistor) on the base substrate, the fourth insulation layer within the thirty-fourth via V34 is etched away to expose a surface of the first region of the active pattern of the twenty-second transistor (also the first region of the active pattern of the twenty-third transistor), and the thirty-fourth via V34 is configured such that a first electrode of the twenty-second transistor (also a first electrode of the twenty-third transistor) formed subsequently is connected with the first region of the active pattern of the twenty-second transistor (also the first region of the active pattern of the twenty-third transistor) through the via.

In an exemplary implementation mode, an orthographic projection of the thirty-fifth via V35 on the base substrate is located within a range of an orthographic projection of a second region of the active pattern of the twenty-second transistor on the base substrate. The fourth insulation layer within the thirty-fifth via V35 is etched away, to expose a surface of the second region of the active pattern of the twenty-second transistor. The thirty-fifth via V35 is configured such that a second electrode of the twentieth transistor (also a second electrode of the twenty-second transistor and a second electrode of the twenty-third transistor) formed subsequently is connected with the second region of the active pattern of the twenty-second transistor through the via.

In an exemplary implementation mode, an orthographic projection of the thirty-sixth via V36 on the base substrate is located within a range of an orthographic projection of the second region of the active pattern of the twenty-third transistor on the base substrate. The first insulation layer and the second insulation layer within the thirty-sixth via V36 are etched away, to expose a surface of the second region of the active pattern of the twenty-third transistor. The thirty-sixth via V36 is configured such that a second electrode of the twentieth transistor (also a second electrode of the twenty-second transistor and a second electrode of the twenty-third transistor) formed subsequently is connected with the second region of the active pattern of the twenty-third transistor through the via.

In an exemplary implementation mode, an orthographic projection of the thirty-seventh via V37 on the base substrate is located within a range of an orthographic projection of a first region of the active pattern of the twenty-fourth transistor on the base substrate. The first insulation layer and the second insulation layer within the thirty-seventh via V37 are etched away, to expose a surface of the first region of the active pattern of the twenty-fourth transistor. The thirty-seventh via V37 is configured such that a first electrode of the twenty-fourth transistor formed subsequently is connected with the first region of the active pattern of the twenty-fourth transistor through the via.

In an exemplary implementation mode, an orthographic projection of the thirty-eighth via V38 on the base substrate is located within a range of an orthographic projection of a second region of the active pattern of the twenty-fourth transistor on the base substrate. The first insulation layer and the second insulation layer within the thirty-eighth via V38 are etched away, to expose a surface of the second region of the active pattern of the twenty-fourth transistor. The thirty-eighth via V38 is configured such that a second electrode of the twenty-first transistor (also a second electrode of the twenty-fourth transistor) formed subsequently is connected with the second region of the active pattern of the twenty-fourth transistor through the via.

In an exemplary implementation mode, an orthographic projection of the thirty-ninth via V39 on the base substrate is located within a range of an orthographic projection of a first region of the active pattern of the twenty-fifth transistor on the base substrate. The first insulation layer and the second insulation layer within the thirty-ninth via V39 are etched away, to expose a surface of the first region of the active pattern of the twenty-fifth transistor. The thirty-ninth via V39 is configured such that a first electrode of the eighth transistor (also a first electrode of the ninth transistor, a first electrode of the thirteenth transistor, and a first electrode of the twenty-fifth transistor) formed subsequently is connected with the first region of the active pattern of the twenty-fifth transistor through the via.

In an exemplary implementation mode, an orthographic projection of the fortieth via V40 on the base substrate is located within a range of an orthographic projection of a second region of the active pattern of the twenty-fifth transistor (also a second region of the active pattern of the twenty-sixth transistor) on the base substrate. The first insulation layer and the second insulation layer within the thirty-ninth via V39 are etched away, to expose a surface of the second region of the active pattern of the twenty-fifth transistor (also the second region of the active pattern of the twenty-sixth transistor). The thirty-ninth via V39 is configured such that a second electrode of the twenty-fifth transistor (also a second electrode of the twenty-sixth transistor) formed subsequently is connected with the second region of the active pattern of the twenty-fifth transistor (also the second region of the active pattern of the twenty-sixth transistor) through the via.

In an exemplary implementation mode, an orthographic projection of the forty-first via V41 on the base substrate is located within a range of an orthographic projection of a first region of the active pattern of the twenty-sixth transistor on the base substrate. The first insulation layer and the second insulation layer within the forty-first via V41 are etched away, to expose a surface of the first region of the active pattern of the twenty-sixth transistor. The forty-first via V41 is configured such that a first electrode of the twenty-sixth transistor formed subsequently is connected with the first region of the active pattern of the twenty-sixth transistor through the via.

In an exemplary implementation mode, an orthographic projection of the forty-second via V42 on the base substrate is located within a range of an orthographic projection of a gate electrode of the first transistor on the base substrate. The second insulation layer within the forty-second via V42 is etched away, to expose a surface of the gate electrode of the first transistor. The forty-second via V42 is configured such that one signal line of a first clock signal line and a second clock signal line and a first electrode of the second transistor formed subsequently are connected with the gate electrode of the first transistor through the via.

In an exemplary implementation mode, an orthographic projection of the forty-third via V43 on the base substrate is located within a range of an orthographic projection of a gate electrode of the second transistor (also a gate electrode of the eighth transistor) on the base substrate. The second insulation layer within the forty-third via V43 is etched away, to expose a surface of the gate electrode of the second transistor (also the gate electrode of the eighth transistor). The forty-third via V43 is configured such that a second electrode of the first transistor and a first electrode of the twelfth transistor (also a second electrode of the thirteenth transistor and a first electrode of the eighteenth transistor) formed subsequently are connected with the gate electrode of the second transistor (also the gate electrode of the eighth transistor) through the via.

In an exemplary implementation mode, an orthographic projection of the forty-fourth via V44 on the base substrate is located within a range of an orthographic projection of a gate electrode of the third transistor (also a gate electrode of the fourteenth transistor) on the base substrate. The second insulation layer within the forty-fourth via V44 is etched away, to expose a surface of the gate electrode of the third transistor (also the gate electrode of the fourteenth transistor). The forty-fourth via V44 is configured such that one of the first clock signal line and the second clock signal line and a third connection line formed subsequently are connected with the gate electrode of the third transistor (also the gate electrode of the fourteenth transistor) through the via.

In an exemplary implementation mode, an orthographic projection of the forty-fifth via V45 on the base substrate is located within a range of an orthographic projection of a gate electrode of the fourth transistor (also a gate electrode of the sixteenth transistor, a gate electrode of the seventeenth transistor, and a first electrode plate of the third capacitor) on the base substrate, the second insulation layer within the forty-fifth via V45 is etched away to expose a surface of the gate electrode of the fourth transistor (also the gate electrode of the sixteenth transistor, the gate electrode of the seventeenth transistor, and the first electrode plate of the third capacitor), and the forty-fifth via V45 is configured such that a second electrode of the fifteenth transistor and a first electrode of the sixteenth transistor formed subsequently are connected with the gate electrode of the fourth transistor (also the gate electrode of the sixteenth transistor, the gate electrode of the seventeenth transistor, and the first electrode plate of the third capacitor) through the via.

In an exemplary implementation mode, an orthographic projection of the forty-sixth via V46 on the base substrate is located within a range of an orthographic projection of a gate electrode of the fifth transistor on the base substrate. The second insulation layer within the forty-sixth via V46 is etched away, to expose a surface of the gate electrode of the fifth transistor. The forty-sixth via V46 is configured such that a second electrode of the second transistor (also a second electrode of the third transistor and a first electrode of the eleventh transistor) formed subsequently is connected with the gate electrode of the fifth transistor through the via.

In an exemplary implementation mode, an orthographic projection of the forty-seventh via V47 on the base substrate is located within a range of an orthographic projection of a gate electrode of the sixth transistor (a first electrode plate of the first capacitor) on the base substrate. The second insulation layer within the forty-seventh via V47 is etched away, to expose a surface of the gate electrode of the sixth transistor (the first electrode plate of the first capacitor). The forty-seventh via V47 is configured such that a second electrode of the eleventh transistor formed subsequently is connected with the gate electrode of the sixth transistor (the first electrode plate of the first capacitor) through the via.

In an exemplary implementation mode, an orthographic projection of the forty-eighth via V48 on the base substrate is located within a range of an orthographic projection of a gate electrode of the seventh transistor on the base substrate. The second insulation layer within the forty-eighth via V48 is etched away, to expose a surface of the gate electrode of the seventh transistor. The forty-eighth via V48 is configured such that a fourth connection line and a first electrode of the sixth transistor are connected with the gate electrode of the seventh transistor through the via.

In an exemplary implementation mode, an orthographic projection of the forty-ninth via V49 on the base substrate is located within a range of an orthographic projection of a gate electrode of the ninth transistor (also a first electrode plate of the second capacitor) on the base substrate, the second insulation layer within the forty-ninth via V49 is etched away to expose a surface of the gate electrode of the ninth transistor (also the first electrode plate of the second capacitor), and the forty-ninth via V49 is configured such that a second electrode of the seventh transistor (also a second electrode of the eighth transistor) formed subsequently is connected with the gate electrode of the ninth transistor (also the first electrode plate of the second capacitor) through the via.

In an exemplary implementation mode, an orthographic projection of the fiftieth via V50 on the base substrate is located within a range of an orthographic projection of the gate electrode of the tenth transistor on the base substrate. The second insulation layer within the fiftieth via V50 is etched away, to expose a surface of the gate electrode of the tenth transistor. The fiftieth via V50 is configured such that a second electrode of the twelfth transistor (also a second electrode of the sixteenth transistor) formed subsequently is connected with the gate electrode of the tenth transistor through the via.

In an exemplary implementation mode, an orthographic projection of the fifty-first via V51 on the base substrate is located within a range of an orthographic projection of a gate electrode of the eleventh transistor (also a gate electrode of the fifteenth transistor) on the base substrate. The second insulation layer within the fifty-first via V51 is etched away, to expose a surface of the gate electrode of the eleventh transistor (also the gate electrode of the fifteenth transistor). The fifty-first via V51 is configured such that a first electrode of the third transistor subsequently formed is connected with the gate electrode of the eleventh transistor (also the gate electrode of the fifteenth transistor) through the via.

In an exemplary implementation mode, an orthographic projection of the fifty-second via V52 on the base substrate is located within a range of an orthographic projection of a gate electrode of the twelfth transistor on the base substrate. The second insulation layer within the fifty-second via V52 is etched away, to expose a surface of the gate electrode of the twelfth transistor. The fifty-second via V52 is configured such that a fifth connection line formed subsequently is connected with the gate electrode of the twelfth transistor through the via.

In an exemplary implementation mode, an orthographic projection of the fifty-third via V53 on the base substrate is located within a range of an orthographic projection of a gate electrode of the thirteenth transistor on the base substrate. The second insulation layer within the fifty-third via V53 is etched away, to expose a surface of the gate electrode of the thirteenth transistor. The fifty-third via V53 is configured such that a sixth connection line formed subsequently is connected with the gate electrode of the thirteenth transistor through the via.

In an exemplary implementation mode, an orthographic projection of the fifty-fourth via V54 on the base substrate is located within a range of an orthographic projection of a gate electrode of the eighteenth transistor on the base substrate. The second insulation layer within the fifty-fourth via V54 is etched away, to expose a surface of the gate electrode of the eighteenth transistor. The fifty-fourth via V54 is configured such that a second electrode of the twentieth transistor (also a second electrode of the twenty-second transistor and a second electrode of the twenty-third transistor) and a seventh connection line formed subsequently are connected with the gate electrode of the eighteenth transistor through the via.

In an exemplary implementation mode, an orthographic projection of the fifty-fifth via V55 on the base substrate is located within a range of an orthographic projection of a gate electrode of the nineteenth transistor on the base substrate. The second insulation layer within the fifty-fifth via V55 is etched away, to expose a surface of the gate electrode of the nineteenth transistor. The fifty-fifth via V55 is configured such that a node connection line formed subsequently is connected with the gate electrode of the nineteenth transistor through the via.

In an exemplary implementation mode, an orthographic projection of the fifty-sixth via V56 on the base substrate is located within a range of an orthographic projection of a gate electrode of the twentieth transistor on the base substrate. The second insulation layer within the fifty-sixth via V56 is etched away, to expose a surface of the gate electrode of the twentieth transistor. The fifty-sixth via V56 is configured such that a first electrode of a first transistor (also a first electrode of a fourteenth transistor) in a next stage shift register formed subsequently is connected with the gate electrode of the twentieth transistor through the via.

In an exemplary implementation mode, an orthographic projection of the fifty-seventh via V57 on the base substrate is located within a range of an orthographic projection of a gate electrode of the twenty-first transistor (also a first electrode plate of the fifth capacitor) on the base substrate, the second insulation layer within the fifty-sixth via V56 is etched away to expose a surface of the gate electrode of the twentieth transistor, and the fifty-sixth via V56 is configured such that a seventh connection line formed subsequently is connected with the gate electrode of the twentieth transistor through the via.

In an exemplary implementation mode, an orthographic projection of the fifty-eighth via V58 on the base substrate is located within a range of an orthographic projection of a gate electrode of the twenty-second transistor on the base substrate. The second insulation layer within the fifty-eighth via V58 is etched away, to expose a surface of the gate electrode of the twenty-second transistor. The fifty-eighth via V58 is configured such that an eighth connection line subsequently formed is connected with the gate electrode of the twenty-second transistor through the via.

In an exemplary implementation mode, an orthographic projection of the fifty-ninth via V59 on the base substrate is located within a range of an orthographic projection of a gate electrode of the twenty-third transistor on the base substrate. The fifty-ninth via V59 exposes a surface of the gate electrode of the twenty-third transistor. The fifty-ninth via V59 is configured such that the eighth connection line and the seventh connection line formed subsequently are connected with the gate electrode of the twenty-third transistor through the via.

In an exemplary implementation mode, an orthographic projection of the fifty-ninth via V59 on the base substrate is located within a range of an orthographic projection of a gate electrode of the twenty-third transistor on the base substrate. The second insulation layer within the fifty-ninth via V59 is etched away, to expose a surface of the gate electrode of the twenty-third transistor. The fifty-ninth via V59 is configured such that a second electrode of the fourth transistor (also a second electrode of the fifth transistor) formed subsequently is connected with the gate electrode of the twenty-third transistor through the via.

In an exemplary implementation mode, an orthographic projection of the sixtieth via V60 on the base substrate is located within a range of an orthographic projection of a gate electrode of the twenty-fourth transistor (a gate electrode of the twenty-sixth transistor) on the base substrate, the second insulation layer within the sixtieth via V60 is etched away to expose a surface of the gate electrode of the twenty-fourth transistor (the gate electrode of the twenty-sixth transistor), and the sixtieth via V60 is configured such that a ninth connection line formed subsequently is connected with the gate electrode of the twenty-fourth transistor (the gate electrode of the twenty-sixth transistor) through the via.

In an exemplary implementation mode, an orthographic projection of the sixty-first via V61 on the base substrate is located within a range of an orthographic projection of a gate electrode of the twenty-fifth transistor (also a first electrode plate of the sixth capacitor) on the base substrate, the second insulation layer within the sixty-first via V61 is etched away to expose a surface of the gate electrode of the twenty-fifth transistor (also the first electrode plate of the sixth capacitor), and the sixty-first via V61 is configured such that a second electrode of the twenty-first transistor (also a second electrode of the twenty-fourth transistor) formed subsequently is connected with the gate electrode of the twenty-fifth transistor (also the first electrode plate of the sixth capacitor) through the via.

In an exemplary implementation mode, an orthographic projection of the sixty-second via V62 on the base substrate is located within a range of an orthographic projection of a first electrode plate of the fourth capacitor on the base substrate, the second insulation layer within the sixty-second via V62 is etched away to expose a surface of the first electrode plate of the fourth capacitor, and the sixty-second via V62 is configured such that a tenth connection line formed subsequently is connected with the first electrode plate of the fourth capacitor through the via.

In an exemplary implementation mode, an orthographic projection of the sixty-third via V63 on the base substrate is located within a range of an orthographic projection of a second electrode plate of the first capacitor on the base substrate. The sixty-third via V63 exposes a surface of the second electrode plate of the first capacitor. The sixty-third via V63 is configured such that a second electrode of the sixth transistor (also the first electrode of the seventh transistor) formed subsequently is connected with the second electrode plate of the first capacitor through the via.

In an exemplary implementation mode, an orthographic projection of the sixty-fourth via V64 on the base substrate is located within a range of an orthographic projection of a second electrode plate of the second capacitor on the base substrate. The sixty-fourth via V64 exposes a surface of the second electrode plate of the second capacitor. The sixty-fourth via V64 is configured such that a first electrode of the eighth transistor (also a first electrode of the ninth transistor, a first electrode of the thirteenth transistor, and a first electrode of the twenty-fifth transistor) formed subsequently is connected with the second electrode plate of the second capacitor through the via.

In an exemplary implementation mode, an orthographic projection of the sixty-fifth via V65 on the base substrate is located within a range of an orthographic projection of a second electrode plate of the third capacitor on the base substrate. The sixty-fifth via V65 exposes a surface of the second electrode plate of the third capacitor. The sixty-fifth via V65 is configured such that a second electrode of the fourth transistor (also a second electrode of the fifth transistor) formed subsequently is connected with the second electrode plate of the third capacitor through the via.

In an exemplary implementation mode, an orthographic projection of the sixty-sixth via V66 on the base substrate is located within a range of an orthographic projection of a second electrode plate of the fifth capacitor on the base substrate. The sixty-sixth via V66 exposes a surface of the second electrode plate of the fifth capacitor. The sixty-sixth via V66 is configured such that a second electrode of the twenty-first transistor (also a second electrode of the twenty-fourth transistor) formed subsequently is connected with the second electrode plate of the fifth capacitor through the via.

In an exemplary implementation mode, an orthographic projection of the sixty-seventh via V67 on the base substrate is located within a range of an orthographic projection of a second electrode plate of the sixth capacitor on the base substrate. The sixty-seventh via V67 exposes a surface of the second electrode plate of the sixth capacitor. The sixty-seventh via V67 is configured such that a first electrode of the eighth transistor (also a first electrode of the ninth transistor, a first electrode of the thirteenth transistor, and a first electrode of the twenty-fifth transistor) formed subsequently is connected with the second electrode plate of the sixth capacitor through the via.

In an exemplary implementation mode, an orthographic projection of the sixty-eighth via V68 on the base substrate is located within a range of an orthographic projection of a cascaded output line on the base substrate. The sixty-eighth via V68 exposes a surface of the cascaded output line. The sixty-eighth via V68 is configured such that a first electrode of a first transistor (also a first electrode of a fourteenth transistor) and a second electrode of a ninth transistor (also a second electrode of a tenth transistor) in a next stage shift register or a cascaded connection line formed subsequently are connected with the cascaded output line through the via.

In an exemplary implementation mode, an orthographic projection of the sixty-ninth via V69 on the base substrate is located within a range of an orthographic projection of a first connection line on the base substrate. The sixty-ninth via V69 exposes a surface of the first connection line. The sixty-ninth via V69 is configured such that a second electrode of the seventeenth transistor (also a second electrode of the eighteenth transistor) and a ninth connection line formed subsequently are connected with the first connection line through the via.

In an exemplary implementation mode, an orthographic projection of the seventieth via V70 on the base substrate is located within a range of an orthographic projection of a second connection line on the base substrate. The seventieth via V70 exposes a surface of the second connection line. The seventieth via V70 is configured such that a second electrode of the twenty-fifth transistor (also a second electrode of the twenty-sixth transistor) formed subsequently is connected with the second connection line through the via.

In an exemplary implementation mode, an orthographic projection of the seventy-first via V71 on the base substrate is located within a range of an orthographic projection of a second electrode plate of the fourth capacitor on the base substrate. The seventy-first via V71 exposes a surface of the second electrode plate of the fourth capacitor. The seventy-first via V71 is configured such that a second electrode of the ninth transistor (also a second electrode of the tenth transistor) formed subsequently is connected with the second electrode plate of the fourth capacitor through the via.

In an exemplary implementation mode, an orthographic projection of the seventy-second via V72 on the base substrate is located within a range of an orthographic projection of a voltage stabilization connection line on the base substrate. The seventy-second via V72 exposes a surface of the voltage stabilization connection line. The seventy-second via V72 is configured such that a second electrode of the ninth transistor (also a second electrode of the tenth transistor) and the cascade connection line formed subsequently are connected with the voltage stabilization connection line through the via.

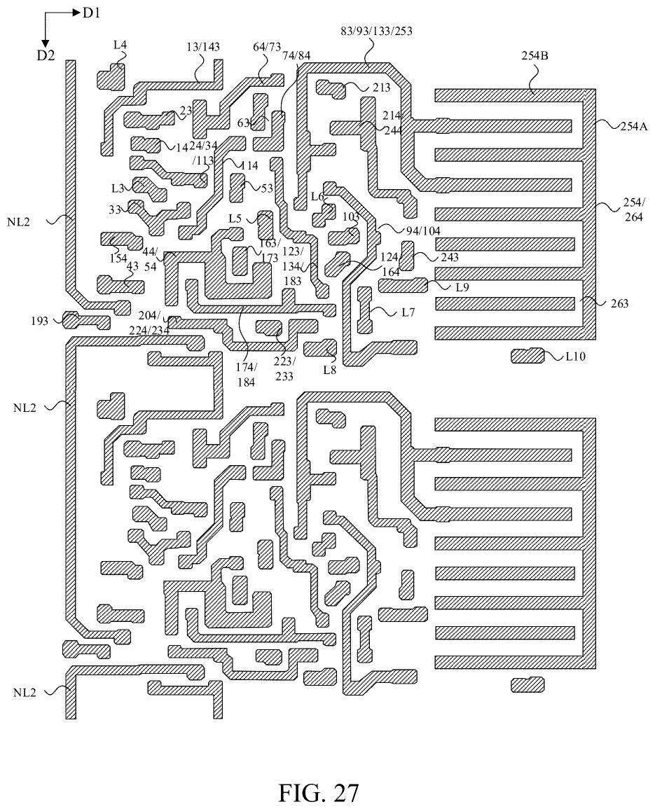

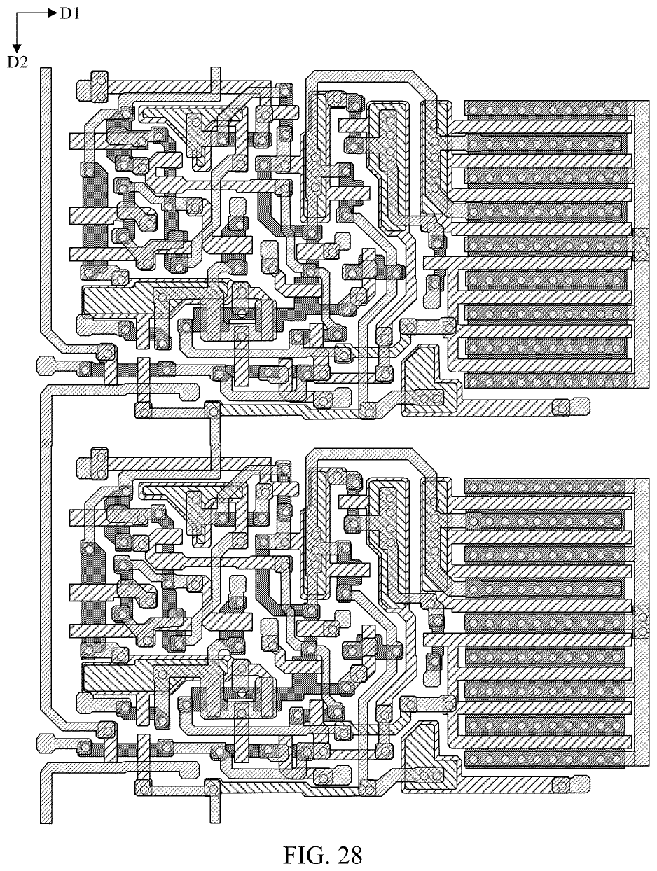

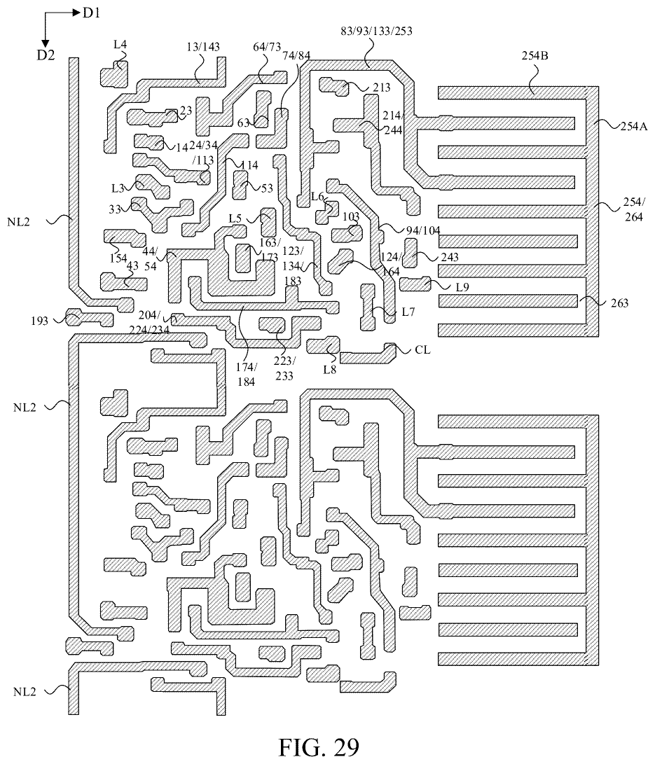

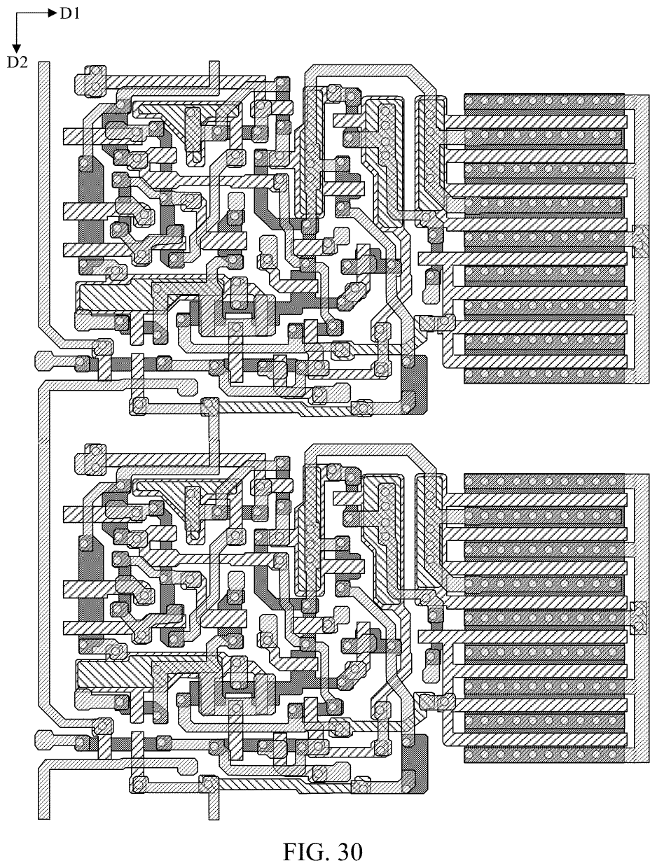

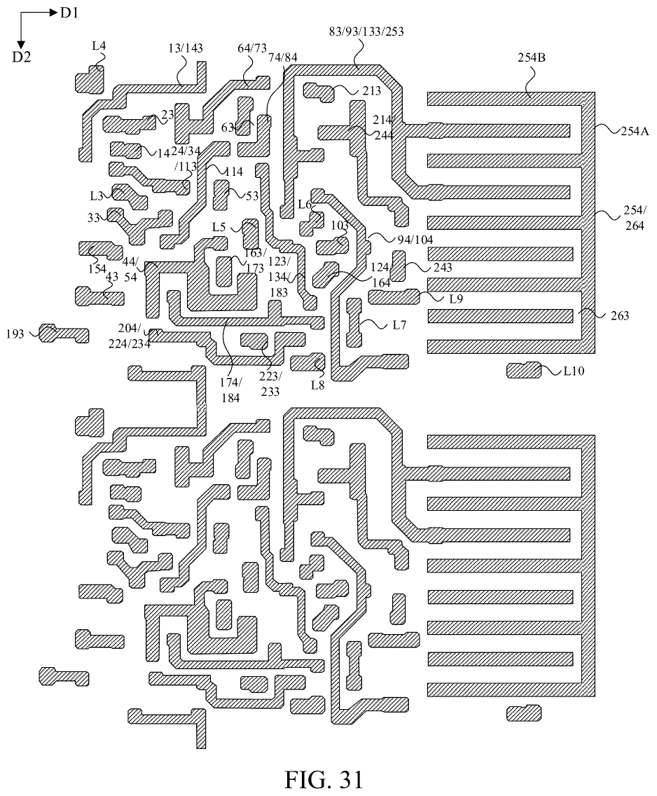

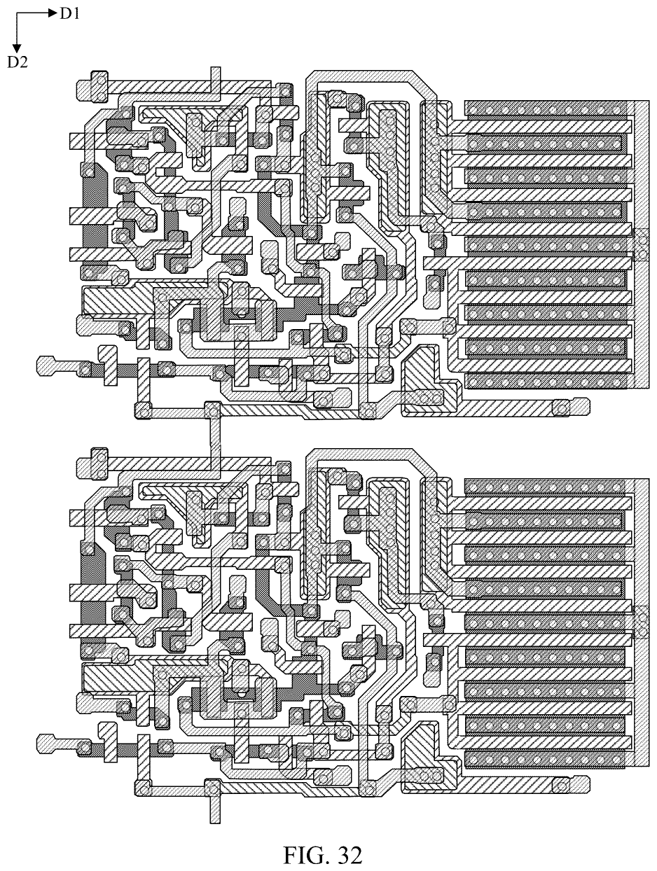

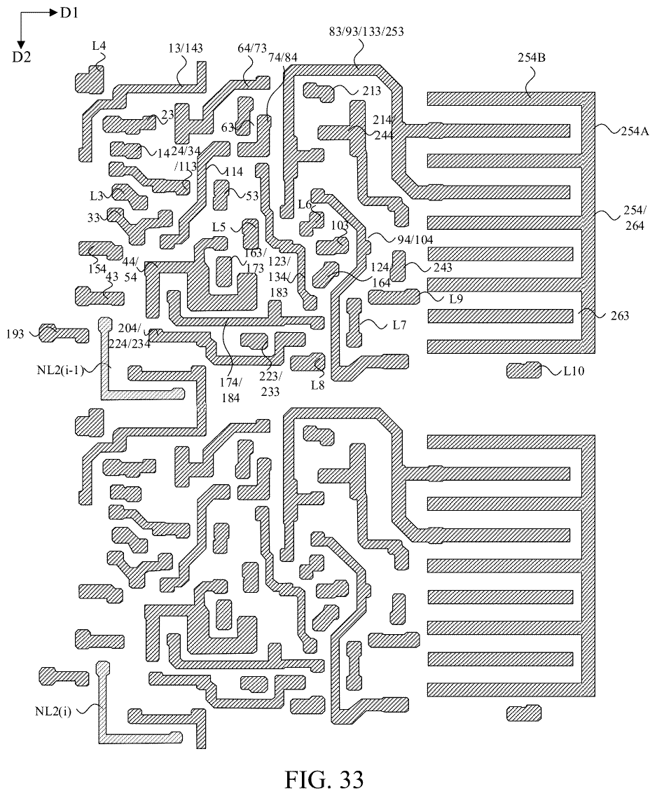

(5) A pattern of a third conductive layer is formed. In an exemplary implementation mode, forming the pattern of the third conductive layer may include: depositing a third conductive thin film on the base substrate on which the above-mentioned patterns are formed, patterning the third conductive thin film through a patterning process, to form a third conductive layer provided on the fifth insulation layer, as shown in FIGS. 27 to 34, FIG. 27 is a schematic diagram of a pattern of a third conductive layer of the display substrate according to FIG. 7, FIG. 28 is a schematic diagram of the display substrate according to FIG. 7 after a pattern of a third conductive layer is formed, FIG. 29 is a schematic diagram of a pattern of a third conductive layer in the display substrate according to FIG. 8, FIG. 30 is a schematic diagram of the display substrate according to FIG. 8 after a pattern of a third conductive layer is formed, FIG. 31 is a schematic diagram of a pattern of a third conductive layer in the display substrate according to FIG. 9, FIG. 32 is a schematic diagram of the display substrate according to FIG. 9 after a pattern of a third conductive layer is formed, FIG. 33 is a schematic diagram of a pattern of a third conductive layer in the display substrate according to FIGS. 10 and 11, FIG. 34 is a schematic diagram of the display substrate according to FIGS. 10 and 11 after a pattern of a third conductive layer is formed. In an exemplary implementation mode, the third conductive layer may be referred to as a first source drain metal (SD1) layer.

In an exemplary implementation mode, as shown in FIGS. 27 to 34, in display substrates according to FIGS. 7 to 11, the pattern of the third conductive layer may include at least a first electrode 13 and a second electrode 14 of a first transistor to a first electrode 143 of a fourteenth transistor, a second electrode 154 of a fifteenth transistor, a first electrode 163 and a second electrode 164 of a sixteenth transistor to a first electrode 183 and a second electrode 184 of an eighteenth transistor, a first electrode 193 of a nineteenth transistor, a second electrode 204 of a twentieth transistor, a first electrode 213 and a second electrode 213 of a twenty-first transistor to a first electrode 263 and a second electrode 264 of a twenty-sixth transistor, and a third connection line L3 to a ninth connection line L9 located in each stage shift register.

In an exemplary implementation mode, as shown in FIGS. 27 and 28, in the display substrate according to FIG. 7, the pattern of the third conductive layer may include at least a tenth connection line L10 and a second node connection line NL2 of a node connection line.

In an exemplary implementation mode, as shown in FIGS. 29 and 30, in the display substrate according to FIG. 8, the pattern of the third conductive layer may include at least a cascaded connection line CL and a second node connection line NL2 of a node connection line.

In an exemplary implementation mode, as shown in FIGS. 31 and 32, in the display substrate according to FIG. 9, the pattern of the third conductive layer may include at least a tenth connection line L10.

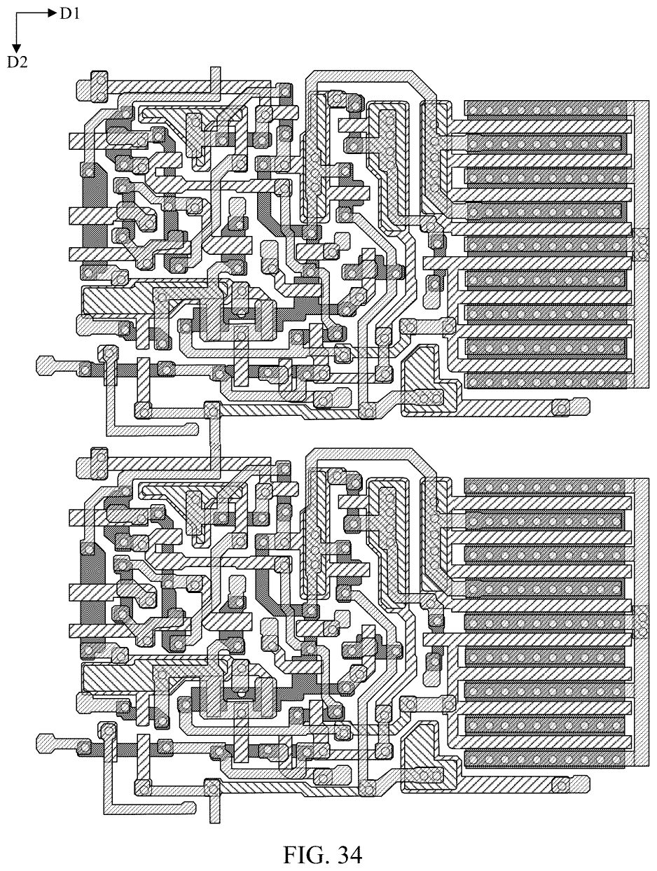

In an exemplary implementation mode, as shown in FIGS. 33 and 34, in the display substrate according to FIGS. 10 and 11, the pattern of the third conductive layer may include at least a second node connection line NL2 of a node connection line.

In an exemplary implementation mode, the first electrode 13 of the first transistor and the first electrode 143 of the fourteenth transistor are of an integral structure. The first electrode 13 of the first transistor (also the first electrode 143 of the fourteenth transistor) has a polyline shape and extends at least partially in the first direction D1. The first electrode 13 of the first transistor (also the first electrode 143 of the fourteenth transistor) is connected with the first region of the active pattern of the first transistor through the first via, is connected with the first region of the active pattern of the fourteenth transistor through the twenty-fourth via, is connected with a gate electrode of a twentieth transistor of a previous stage shift register through the fifty-sixth via, and is connected with the cascade output line through the sixty-eighth via.

In an exemplary implementation mode, the second electrode 14 of the first transistor is disposed separately. The second electrode 14 of the first transistor has a shape of a strip and extends in the first direction D1. The second electrode 14 of the first transistor is connected with the second region of the active pattern of the first transistor through the second via, and is connected with the gate electrode of the second transistor (also the gate electrode of the eighth transistor) through the fourth-third via.

In an exemplary implementation mode, the first electrode 23 of the second transistor is disposed separately. The first electrode 23 of the second transistor has a shape of a strip and extends in the first direction D1. The first electrode 23 of the second transistor is connected with the first region of the active pattern of the second transistor through the third via, and is connected with the gate electrode of the first transistor through the forty-second via.

In an exemplary implementation mode, the second electrode 24 of the second transistor, the second electrode 34 of the third transistor, and the first electrode 113 of the eleventh transistor are of an integral structure. The integral structure of the second electrode 24 of the second transistor, the second electrode 34 of the third transistor, and the first electrode 113 of the eleventh transistor has a polyline shape and extends at least partially in the first direction D1. The second electrode 24 of the second transistor (also the second electrode 34 of the third transistor and the first electrode 113 of the eleventh transistor) is connected with the second region of the active pattern of the second transistor (also the first region of the active pattern of the eleventh transistor) through the fourth via, is connected with the second region of the active pattern of the third transistor through the sixth via, and is connected with the gate electrode of the fifth transistor through the forty-sixth via.

In an exemplary implementation mode, the first electrode 33 of the third transistor is disposed separately. The first electrode 33 of the second transistor has a shape of a strip and extends at least partially in the first direction D1. The first electrode 33 of the third transistor is connected with the first region of the active pattern of the third transistor through the fifth via, and is connected with the gate electrode of the eleventh transistor (also the gate electrode of the fifteenth transistor) through the fifty-first via.

In an exemplary implementation mode, the first electrode 43 of the fourth transistor is disposed separately. The first electrode 43 of the fourth transistor has a shape of a strip and extends at least partially in the first direction D1. The first electrode 43 of the fourth transistor is connected with the first region of the active pattern of the fourth transistor through the seventh via.

In an exemplary implementation mode, the second electrode 44 of the fourth transistor and the second electrode 54 of the fifth transistor are of an integral structure and disposed separately. The second electrode 44 of the fourth transistor (also the second electrode 54 of the fifth transistor) is connected with the second region of the active pattern of the fourth transistor through the eighth via, is connected with the second region of the active pattern of the fifth transistor through the tenth via, is connected with the gate electrode of the twenty-third transistor through the fifty-ninth via, and is connected with the second electrode plate of the third capacitor through the sixty-fifth via.

In an exemplary implementation mode, the first electrode 53 of the fifth transistor is disposed separately. The first electrode 53 of the fifth transistor has a shape of a strip and extends in the second direction D2. The first electrode 53 of the fifth transistor is connected with the first region of the active pattern of the fifth transistor through the ninth via.

In an exemplary implementation mode, the first electrode 63 of the sixth transistor is disposed separately. The first electrode 63 of the sixth transistor has a shape of “I”. The first electrode 63 of the sixth transistor is connected with the first region of the active pattern of the sixth transistor through the eleventh via, and is connected with the gate electrode of the seventh transistor through the forty-eighth via.

In an exemplary implementation mode, the second electrode 64 of the sixth transistor and the first electrode 73 of the seventh transistor are of an integral structure. The integral structure of the second electrode 64 of the sixth transistor and the first electrode 73 of the seventh transistor has a polyline shape and extends at least partially in the first direction D1. The second electrode 64 of the sixth transistor (also the first electrode 73 of the seventh transistor) is connected with the second region of the active pattern of the sixth transistor through the twelfth via, is connected with the first region of the active pattern of the seventh transistor through the thirteenth via, and is connected with the second electrode plate of the first capacitor through the sixty-third via.

In an exemplary implementation mode, the second electrode 74 of the seventh transistor and the second electrode 84 of the eighth transistor are of an integral structure. The integral structure of the second electrode 74 of the seventh transistor and the first electrode 84 of the eighth transistor has a shape of “¹”. The second electrode 74 of the seventh transistor (also the first electrode 84 of the eighth transistor) is connected with the second region of the active pattern of the seventh transistor through the fourteenth via, is connected with the second region of the active pattern of the eighth transistor through the sixteenth transistor, and is connected with the gate electrode of the ninth transistor (also the first electrode plate of the second capacitor) through the forth-ninth via.

In an exemplary implementation mode, the first electrode 83 of the eighth transistor, the first electrode 93 of the ninth transistor, the first electrode 133 of the thirteenth transistor, and the first electrode 253 of the twenty-fifth transistor are of an integral structure. The first electrode 83 of the eighth transistor (also the first electrode 93 of the ninth transistor, the first electrode 133 of the thirteenth transistor, and the first electrode 253 of the twenty-fifth transistor) is connected with the first region of the active pattern of the eighth transistor (also the first region of the active pattern of the thirteenth transistor) through the fifteenth via, is connected with the first region of the active pattern of the ninth transistor through the seventeenth via, is connected with the first region of the active pattern of the twenty-fifth transistor through the thirty-ninth via, is connected with the second electrode plate of the second capacitor through the sixty-fourth via, and is connected with the second electrode plate of the sixth capacitor through the sixty-seventh via.

In an exemplary implementation mode, the second electrode 94 of the ninth transistor and the first electrode 104 of the tenth transistor are of an integral structure. The integral structure of the second electrode 94 of the ninth transistor and the first electrode 104 of the tenth transistor has a shape of a strip and extends at least partially in the second direction D2. In the display substrate according to FIGS. 7 and 9 to 11, the second electrode 94 of the ninth transistor (also the second electrode 104 of the tenth transistor) is connected with the second region of the active pattern of the ninth transistor through the eighteenth via, is connected with the second region of the active pattern of the tenth transistor through the twentieth via, is connected with the cascaded output line through the sixty-eighth via, and is connected with the second electrode plate of the fourth capacitor through the seventy-first via. In the display substrate according to FIG. 8, the second electrode 94 of the ninth transistor (also the second electrode 104 of the tenth transistor) is connected with the second region of the active pattern of the ninth transistor through the eighteenth via, is connected with the second region of the active pattern of the tenth transistor through the twentieth via, and is connected with the voltage stabilization connection line through the seventy-three via.

In an exemplary implementation mode, the first electrode 103 of the tenth transistor may be disposed separately. The first electrode 103 of the tenth transistor has a shape of a strip and extends in the first direction D1. The first electrode 103 of the tenth transistor is connected with the first region of the active pattern of the tenth transistor through the nineteenth via.

In an exemplary implementation mode, the second electrode 114 of the eleventh transistor may be disposed separately. The second electrode 114 of the eleventh transistor has a polyline shape and extends at least partially in the second direction D2. The second electrode 114 of the eleventh transistor is connected with the second region of the active pattern of the eleventh transistor through the twenty-first via, and is connected with the gate electrode of the sixth transistor (also the first electrode plate of the first capacitor) through the forty-seventh via.

In an exemplary implementation mode, the first electrode 123 of the twelfth transistor, the second electrode 134 of the thirteenth transistor, and the first electrode 183 of the eighteenth transistor are of an integral structure. The integral structure of the first electrode 123 of the twelfth transistor, the second electrode 134 of the thirteenth transistor, and the first electrode 183 of the eighteenth transistor has a polyline shape and extends at least partially in the second direction D2. The first electrode 123 of the twelfth transistor (also the second electrode 134 of the thirteenth transistor and the first electrode 183 of the eighteenth transistor) is connected with the first region of the active pattern of the twelfth transistor (also the second region of the active pattern of the thirteenth transistor) through the twenty-second via, is connected with the first region of the active pattern of the eighteenth transistor through the twenty-eighth via, and is connected with the gate electrode of the second transistor (also the gate electrode of the eighth transistor) through the forty-third via.

In an exemplary implementation mode, the second electrode 124 of the twelfth transistor and the first electrode 164 of the sixteenth transistor are of an integral structure. The integral structure of the second electrode 124 of the twelfth transistor and the first electrode 164 of the sixteenth transistor has a shape of a straight line, and an extension direction intersects with the first direction D1 and the second direction D2. The second electrode 124 of the twelfth transistor (also the second electrode 164 of the sixteenth transistor) is connected with the second region of the active pattern of the twelfth transistor (also the second region of the active pattern of the sixteenth transistor) through the twenty-third via, and is connected with the gate electrode of the tenth transistor through the fiftieth via.

In an exemplary implementation mode, the second electrode 154 of the fifteenth transistor may be disposed separately. The second electrode 154 of the fifteenth transistor has a shape of a strip and extends in the first direction D1. The second electrode 154 of the fifteenth transistor is connected with the second region of the active pattern of the fifteenth transistor through the twenty-fifth via, and is connected with the gate electrode of the fourth transistor (also the gate electrode of the sixteenth transistor, the gate electrode of the seventeenth transistor, and the first electrode plate of the third capacitor) through the forth-fifth via.

In an exemplary implementation mode, the first electrode 163 of the sixteenth transistor and the first electrode 173 of the seventeenth transistor are of an integral structure. The integral structure of the first electrode 163 of the sixteenth transistor and the first electrode 173 of the seventeenth transistor has a shape of a strip and extends in the second direction D2. The first electrode 163 of the sixteenth transistor (also the first electrode 173 of the seventeenth transistor) is connected with the first region of the active pattern of the sixteenth transistor (also the first region of the active pattern of the seventeenth transistor) through the twenty-sixth via, and is connected with the gate electrode of the fourth transistor (also the gate electrode of the sixteenth transistor, the gate electrode of the seventeenth transistor, and the first electrode plate of the third capacitor) through the forty-fifth via.

In an exemplary implementation mode, the second electrode 174 of the seventeenth transistor and the second electrode 184 of the eighteenth transistor are of an integral structure. The integral structure of the second electrode 174 of the seventeenth transistor and the second electrode 184 of the eighteenth transistor has a shape of “F” rotating in a direction. The second electrode 174 of the seventeenth transistor (also the second electrode 184 of the eighteenth transistor) is connected with the second region of the active pattern of the seventeenth transistor through the twenty-seventh via, is connected with the second region of the active pattern of the eighteenth transistor through the twenty-ninth via, and is connected with the first connection line through the sixty-ninth via.

In an exemplary implementation mode, the first electrode 193 of the nineteenth transistor may be disposed separately. The first electrode 193 of the nineteenth transistor has a shape of a strip and extends in the first direction D1. The first electrode 193 of the nineteenth transistor is connected with the first region of the active pattern of the nineteenth transistor through the thirtieth via.

In an exemplary implementation mode, the second electrode 204 of the twentieth transistor, the second electrode 224 of the twenty-second transistor, and the second electrode 234 of the twenty-third transistor are of an integral structure. The second electrode 204 of the twentieth transistor, the second electrode 224 of the twenty-second transistor, and the second electrode 234 of the twenty-third transistor have a polyline shape and extend at least partially in the first direction D1. The second electrode 204 of the twentieth transistor (also the second electrode 224 of the twenty-second transistor and the second electrode 234 of the twenty-third transistor) is connected with the second region of the active pattern of the twentieth transistor through the thirty-first via, is connected with the second region of the active pattern of the twenty-second transistor through the thirty-fifth via, is connected with the second region of the active pattern of the twenty-third transistor through the thirty-sixth via, and is connected with the gate electrode of the eighteenth transistor through the fifty-fourth via.

In an exemplary implementation mode, the first electrode 213 of the twenty-first transistor is disposed separately. The first electrode 213 of the twenty-first transistor has a shape of a strip and extends in the first direction D1. The first electrode 213 of the twenty-first transistor is connected with the first region of the active pattern of the twenty-first transistor through the thirty-second via, and is connected with the gate electrode of the ninth transistor (also the first electrode plate of the second capacitor) through the forty-ninth via.

In an exemplary implementation mode, the second electrode 214 of the twenty-first transistor and the second electrode 244 of the twenty-fourth transistor are of an integral structure. The integral structure of the second electrode 214 of the twenty-first transistor and the second electrode 244 of the twenty-fourth transistor has a polyline shape and extends at least partially in the second direction D2. The second electrode 214 of the twenty-first transistor (also the second electrode 244 of the twenty-fourth transistor) is connected with the second region of the active pattern of the twenty-first transistor through the thirty-third via, is connected with the second region of the active pattern of the twenty-fourth transistor through the thirty-eighth via, is connected with the gate electrode of the twenty-fifth transistor (also the first electrode plate of the sixth capacitor) through the sixty-first via, and is connected with the second electrode plate of the fifth capacitor through the sixty-sixth via.

In an exemplary implementation mode, the second electrode 224 of the twenty-second transistor and the second electrode 234 of the twenty-third transistor are of an integral structure. The integral structure of the second electrode 224 of the twenty-second transistor and the second electrode 234 of the twenty-third transistor has a shape of a strip and extends in the first direction D1. The first electrode 223 of the twenty-second transistor (also the first electrode 233 of the twenty-third transistor) is connected with the first region of the active pattern of the twenty-second transistor (also the first region of the active pattern of the twenty-third transistor) through the thirty-fourth via.

In an exemplary implementation mode, the first electrode 243 of the twenty-fourth transistor is disposed separately. The first electrode 243 of the twenty-fourth transistor has a shape of a strip and extends in the second direction D2. The first electrode 243 of the twenty-fourth transistor is connected with the first region of the active pattern of the twenty-fourth transistor through the thirty-seventh via.

In an exemplary implementation mode, the second electrode 254 of the twenty-fifth transistor and the second electrode 264 of the twenty-sixth transistor are of an integral structure. The integral structure of the second electrode 254 of the twenty-fifth transistor and the second electrode 264 of the twenty-sixth transistor has a comb shape, and comb teeth are located on a side of a comb back away from the display region. The second electrode 254 of the twenty-fifth transistor (also the second electrode 264 of the twenty-sixth transistor) is connected with the second region of the active pattern of the twenty-fifth transistor (also the second region of the active pattern of the twenty-sixth transistor) through the fortieth via, and is connected with the second connection line through the seventieth via.

In an exemplary implementation mode, the first electrode 263 of the twenty-sixth transistor is disposed separately. The first electrode 263 of the twenty-sixth transistor has a shape of a strip and extends in the first direction D1. The first electrode 263 of the twenty-sixth transistor is connected with the first region of the active pattern of the twenty-sixth transistor through the forty-first via.

In an exemplary implementation mode, the third connection line L3 has a shape of a strip and extends at least partially in the first direction D1. The third connection line L3 is connected with the gate electrode of the third transistor (also the gate electrode of the fourteenth transistor) through the forty-forth via.

In an exemplary implementation mode, the fourth connection line L4 has a shape of a strip and extends at least partially in the first direction D1. The fourth connection line L4 is connected with the gate electrode of the seventh transistor through the forty-eighth via.

In an exemplary implementation mode, the fifth connection line L5 has a shape of a strip and extends at least partially in the second direction D2. The fifth connection line L5 is connected with the gate electrode of the twelfth transistor through the fifty-second via.

In an exemplary implementation mode, the sixth connection line L6 has a shape of a strip and extends at least partially in the first direction D1. The sixth connection line L6 is connected with the gate electrode of the thirteenth transistor through the fifty-third via.

In an exemplary implementation mode, the seventh connection line L7 has a shape of a strip and extends at least partially in the second direction D2. The seventh connection line L7 is connected with the gate electrode of the eighteenth transistor through the fifty-fourth via, and is connected with the gate electrode of the twenty-first transistor (also the first electrode plate of the fifth capacitor) through the fifty-seventh via.

In an exemplary implementation mode, the eighth connection line L8 has a shape of a strip and extends at least partially in the first direction D1. The eighth connection line L8 is connected with the gate electrode of the twenty-second transistor through the fifty-eighth via.

In an exemplary implementation mode, the ninth connection line L9 has a shape of a strip and extends at least partially in the first direction D1. The ninth connection line L9 is connected with the gate electrode of the twenty-fourth transistor (the gate electrode of the twenty-sixth transistor) through the sixtieth via, and is connected with the first connection line through the sixty-ninth via.

In an exemplary implementation mode, the tenth connection line L10 is connected with the first electrode plate of the fourth capacitor through the sixty-second via.

In an exemplary implementation mode, the cascaded connection line is connected with the cascaded output line through the sixty-eighth via, and is connected with the voltage stabilization connection line through the seventy-second via.

In an exemplary implementation mode, a second node connection line of an i-th node connection line is connected with the gate electrode of the nineteenth transistor of an (i+1)-th stage shift register.

In an exemplary implementation mode, a second node connection line NL2 in the display substrate according to FIGS. 7 and 8 has a shape of “n” with an opening facing the display region, and a second node connection line NL2 in the display substrate according to FIGS. 10 and 11 has a shape of “└”.

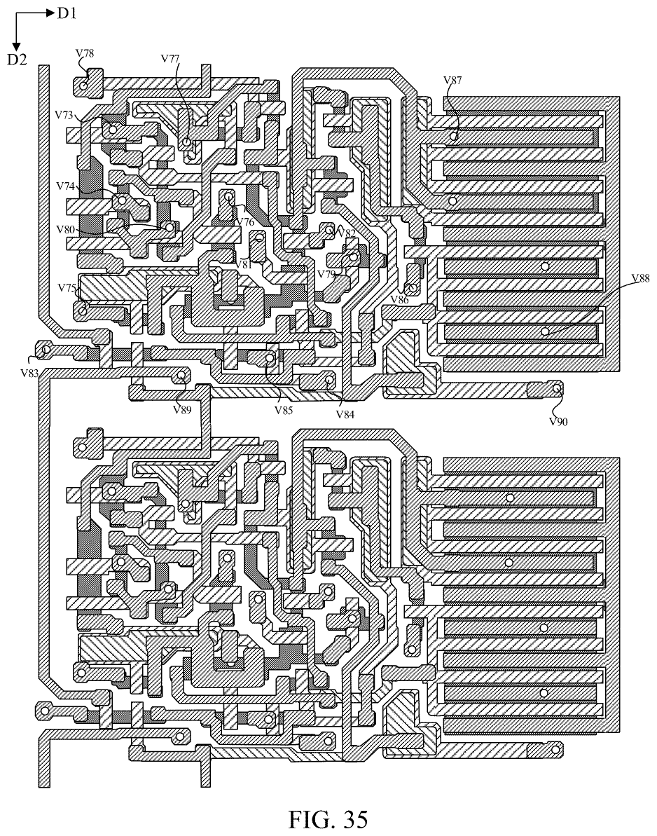

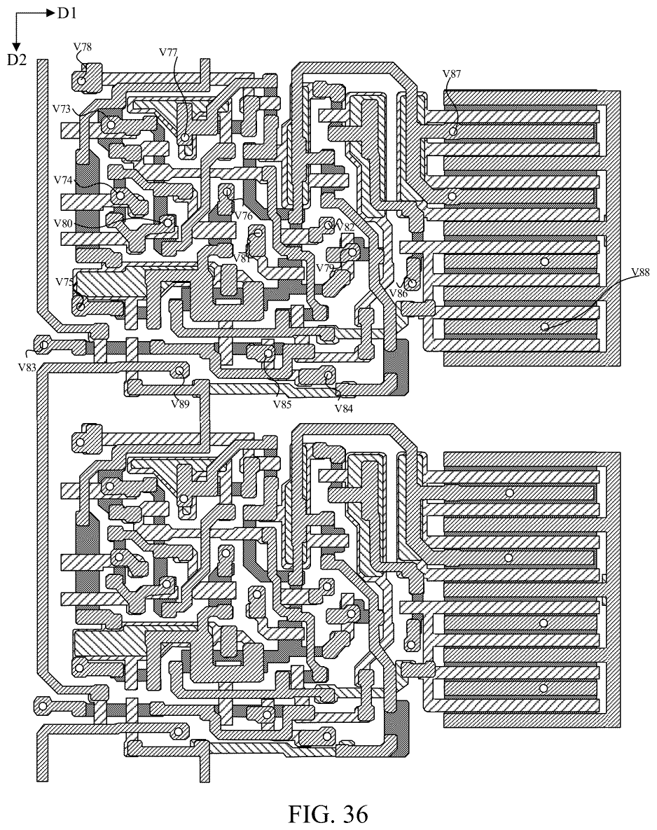

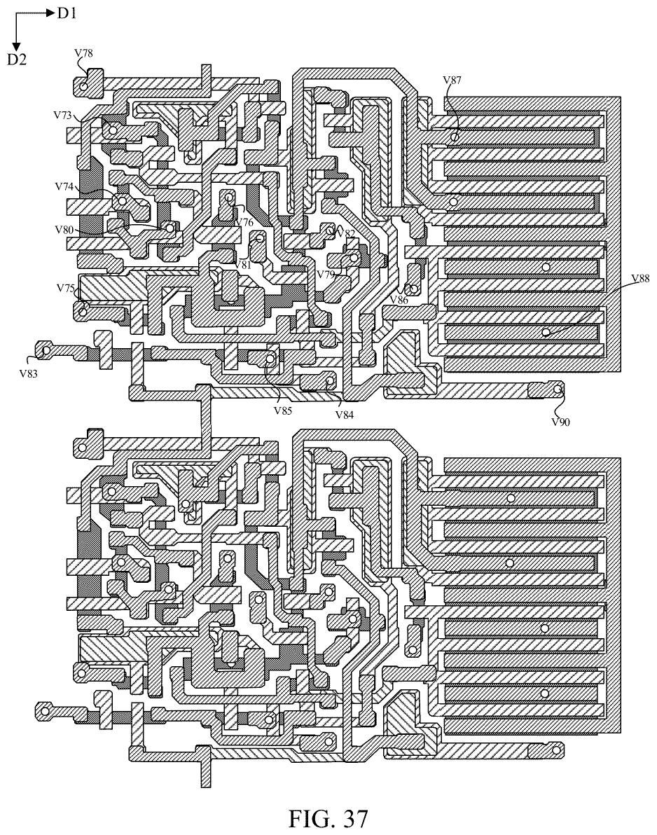

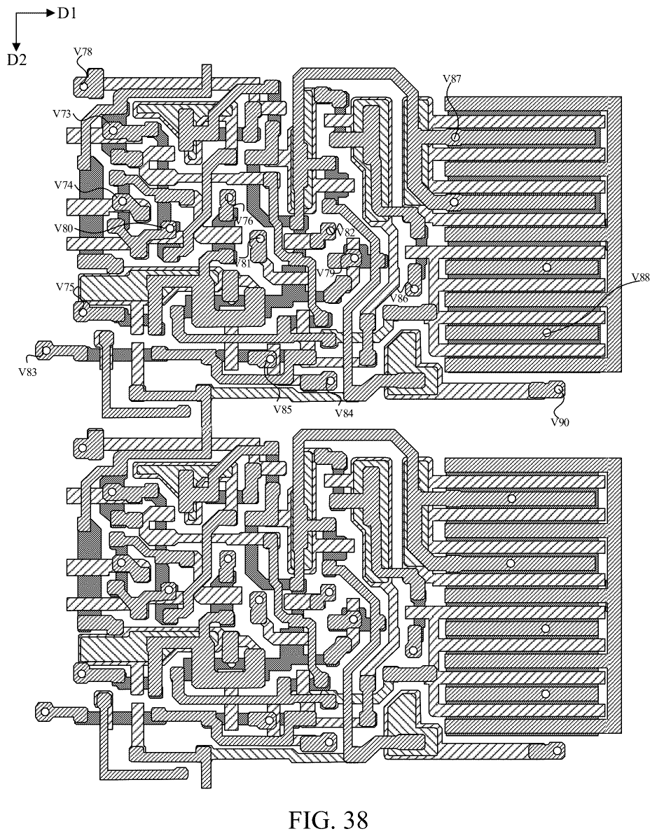

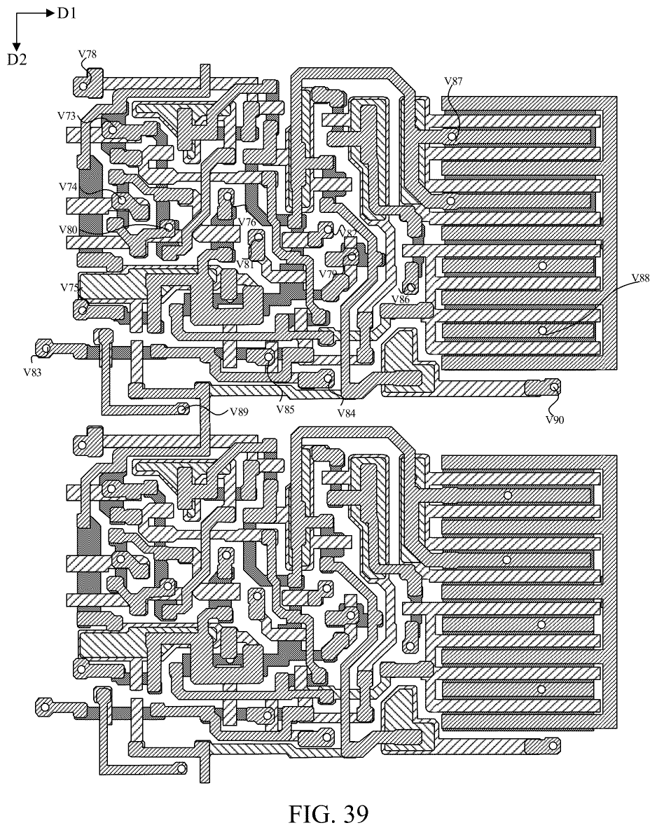

(6) A pattern of a fourth insulation layer is formed. In an exemplary implementation mode, forming the pattern of the fourth insulation layer may include: depositing a fourth insulation thin film on the base substrate on which the above-mentioned patterns are formed, and patterning the fourth insulation thin film through a patterning process to form the pattern of the fourth insulation layer covering the above-mentioned structure, wherein the fourth insulation layer is provided with patterns of a plurality of vias, as shown in FIGS. 35 to 39, FIG. 35 is a schematic diagram of the display substrate according to FIG. 7 after a pattern of a fourth insulation layer is formed, FIG. 36 is a schematic diagram of the display substrate according to FIG. 8 after a pattern of a fourth insulation layer is formed, FIG. 37 is a schematic diagram of the display substrate according to FIG. 9 after a pattern of a fourth insulation layer is formed, FIG. 38 is a schematic diagram of the display substrate according to FIG. 10 after a pattern of a fourth insulation layer is formed, and FIG. 39 is a schematic diagram of the display substrate according to FIG. 11 after a pattern of a fourth insulation layer is formed.

In an exemplary implementation mode, as shown in FIG. 35, the pattern of the fourth insulation layer in the display substrate according to FIG. 7 may include at least a seventy-third via V73 to a ninetieth via V90 in each stage shift register.

In an exemplary implementation mode, as shown in FIG. 36, the pattern of the fourth insulation layer in the display substrate according to FIG. 8 may include at least a seventy-third via V73 to an eighty-ninth via V89 in each stage shift register.

In an exemplary implementation mode, as shown in FIGS. 37 and 38, the pattern of the fourth insulation layer in the display substrate according to FIGS. 9 and 10 may include at least a seventy-third via V73 to a seventy-sixth via V76, a seventy-eighth via V78 to an eighty-eighth via V88, and a ninetieth via V90 in each stage shift register.

In an exemplary implementation mode, as shown in FIG. 39, the pattern of the fourth insulation layer in the display substrate according to FIG. 11 may include at least a seventy-third via V73 to a seventy-sixth via V76, and a seventy-eighth via V78 to a ninetieth via V90 in each stage shift register.

In an exemplary implementation mode, an orthographic projection of the seventy-third via V73 on the base substrate is within a range of an orthographic projection of the first electrode of the second transistor on the base substrate. The seventy-third via V73 exposes a surface of the first electrode of the second transistor. The seventy-third via V73 is configured such that one of the first clock signal line and the second clock signal line formed subsequently is connected with the first electrode of the second transistor through the via. FIGS. 35 to 39 are illustrated by taking a case in which the first electrode of the second transistor is connected with the second clock signal line as an example.

In an exemplary implementation mode, an orthographic projection of the seventy-fourth via V74 on the base substrate is within a range of an orthographic projection of the third connection line on the base substrate. The seventy-fourth via V74 exposes a surface of the third connection line. The seventy-fourth via V74 is configured such that one of the first clock signal line and the second clock signal line formed subsequently is connected with the third connection line through the via. FIGS. 35 to 39 are illustrated by taking a case in which the third connection line is connected with the second clock signal line as an example.

In an exemplary implementation mode, an orthographic projection of the seventy-fifth via V75 on the base substrate is within a range of an orthographic projection of the first electrode of the fourth transistor on the base substrate. The seventy-fifth via V75 exposes a surface of the first electrode of the fourth transistor. The seventy-fifth via V75 is configured such that the other of the first clock signal line and the second clock signal line formed subsequently is connected with the first electrode of the fifth transistor (also the first electrode of the eighth transistor, the first electrode of the ninth transistor, and the first electrode of the fourth transistor) through the via. FIGS. 35 to 39 are illustrated by taking a case in which the first electrode of the fourth transistor is connected with the second clock signal line as an example.

In an exemplary implementation mode, an orthographic projection of the seventy-sixth via V76 on the base substrate is within a range of an orthographic projection of the first electrode of the fifth transistor on the base substrate. The seventy-sixth via V76 exposes a surface of the first electrode of the fifth transistor. The seventy-sixth via V76 is configured such that a second power supply line formed subsequently is connected with the first electrode of the fifth transistor through the via.

In an exemplary implementation mode, an orthographic projection of the seventy-seventh via V77 on the base substrate is within a range of an orthographic projection of a second electrode of the sixth transistor (also a first electrode of the seventh transistor) on the base substrate, the seventy-seventh via V77 exposes the second electrode of the sixth transistor (also the first electrode of the seventh transistor), and the seventy-seventh via V77 is configured such that a first node connection line of a node connection line formed subsequently is connected with the second electrode of the sixth transistor (also the first electrode of the seventh transistor) through the via.

In an exemplary implementation mode, an orthographic projection of the seventy-eighth via V78 on the base substrate is within a range of an orthographic projection of a fourth connection line on the base substrate. The seventy-eighth via V78 exposes a surface of the fourth connection line. The seventy-eighth via V78 is configured such that the other of the first clock signal line and the second clock signal line formed subsequently is connected with the fourth connection line through the via.

In an exemplary implementation mode, an orthographic projection of the seventy-ninth via V79 on the base substrate is within a range of an orthographic projection of a first electrode of the tenth transistor on the base substrate. The seventy-ninth via V79 exposes a surface of the first electrode of the tenth transistor. The seventy-ninth via V79 is configured such that a fifth power supply line formed subsequently is connected with the first electrode of the tenth transistor through the via.

In an exemplary implementation mode, an orthographic projection of the eightieth via V80 on the base substrate is within a range of an orthographic projection of a first electrode of the third transistor on the base substrate, the eightieth via V80 exposes a surface of the first electrode of the third transistor, and the eightieth via V80 is configured such that a first power supply line formed subsequently is connected with the first electrode of the third transistor through the via.

In an exemplary implementation mode, an orthographic projection of the eighty-first via V81 on the base substrate is located within a range of an orthographic projection of a fifth connection line on the base substrate, the eighty-first via V81 exposes a surface of the fifth connection line, and the eighty-first via V81 is configured such that a third power supply line formed subsequently is connected with the fifth connection line through the via.

In an exemplary implementation mode, an orthographic projection of the eighty-second via V82 on the base substrate is located within a range of an orthographic projection of a sixth connection line on the base substrate, the eighty-second via V82 exposes a surface of the sixth connection line, and the eighty-second via V82 is configured such that a fourth power supply line formed subsequently is connected with the sixth connection line through the via.

In an exemplary implementation mode, an orthographic projection of the eighty-third via V83 on the base substrate is within a range of an orthographic projection of a first electrode of the nineteenth transistor on the base substrate, the eighty-third via V83 exposes a surface of the first electrode of the nineteenth transistor, and the eighty-third via V83 is configured such that a latch signal line formed subsequently is connected with the first electrode of the nineteenth transistor through the via.

In an exemplary implementation mode, an orthographic projection of the eighty-fourth via V84 on the base substrate is located within a range of an orthographic projection of an eighth connection line on the base substrate, the eighty-fourth via V84 exposes a surface of the eighth connection line, and the eighty-fourth via V84 is configured such that a fourth power supply line formed subsequently is connected with the eighth connection line through the via.

In an exemplary implementation mode, an orthographic projection of the eighty-fifth via V85 on the base substrate is within a range of an orthographic projection of a first electrode of the twenty-second transistor (also a first electrode of the twenty-third transistor) on the base substrate, the eighty-fifth via V85 exposes a surface of the first electrode of the twenty-second transistor (also the first electrode of the twenty-third transistor), and the eighty-fifth via V85 is configured such that a third power supply line formed subsequently is connected with the first electrode of the twenty-second transistor (also the first electrode of the twenty-third transistor) through the via.

In an exemplary implementation mode, an orthographic projection of the eighty-sixth via V86 on the base substrate is within a range of an orthographic projection of a first electrode of the twenty-fourth transistor on the base substrate, the eighty-sixth via V86 exposes a surface of the first electrode of the twenty-fourth transistor, and the eighty-sixth via V86 is configured such that a sixth power supply line formed subsequently is connected with the first electrode of the twenty-fourth transistor through the via.

In an exemplary implementation mode, an orthographic projection of the eighty-seventh via V87 on the base substrate is within a range of an orthographic projection of a first electrode of the eighth transistor (also a first electrode of the ninth transistor, a first electrode of the thirteenth transistor, and a first electrode of the twenty-fifth transistor) on the base substrate, the eighty-seventh via V87 exposes a surface of the first electrode of the eighth transistor (also the first electrode of the ninth transistor, the first electrode of the thirteenth transistor, and the first electrode of the twenty-fifth transistor), the eighty-seventh via V87 is configured such that a seventh or eighth power supply line formed subsequently is connected with the first electrode of the eighth transistor (also the first electrode of the ninth transistor, the first electrode of the thirteenth transistor, and the first electrode of the twenty-fifth transistor) through the via.

In an exemplary implementation mode, an orthographic projection of the eighty-eighth via V88 on the base substrate is within a range of an orthographic projection of a first electrode of the twenty-sixth transistor on the base substrate, the eighty-eighth via V88 exposes a surface of the first electrode of the twenty-sixth transistor, and the eighty-eighth via V88 is configured such that a ninth power supply line formed subsequently is connected with the first electrode of the twenty-sixth transistor through the via.

In an exemplary implementation mode, an orthographic projection of the eighty-ninth via V89 on the base substrate is within a range of an orthographic projection of a second node connection line on the base substrate. The eighty-ninth via V89 exposes a surface of the second node connection line. For the display substrate according to FIGS. 7, 8, and 10, the eighty-ninth via V89 is configured such that a first node connection line formed subsequently is connected with the second node connection line through the via. For the display substrate according to FIG. 11, the eighty-ninth via V89 is configured such that a third node connection line formed subsequently is connected with the second node connection line through the via.

In an exemplary implementation mode, an orthographic projection of the ninety via V90 on the base substrate is located within a range of an orthographic projection of a tenth connection line on the base substrate, the ninety via V90 exposes a surface of the tenth connection line, and the ninth via V90 is configured such that a ninth power supply line formed subsequently is connected with the tenth connection line through the via.

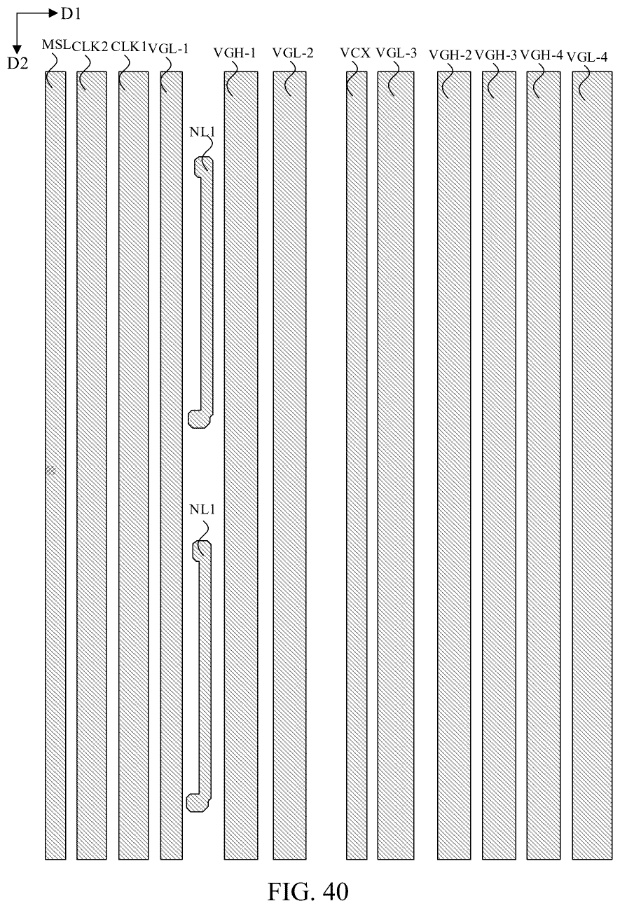

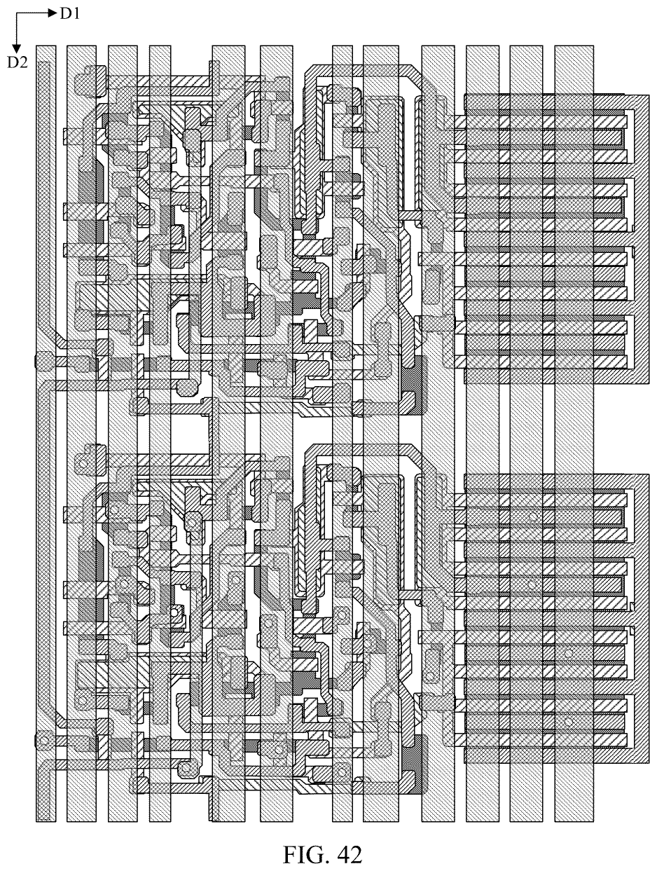

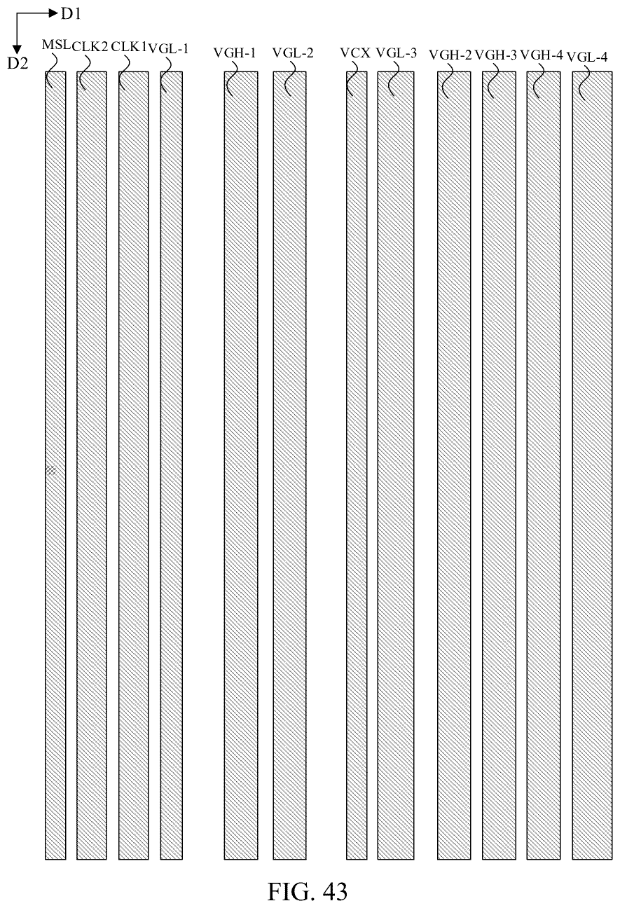

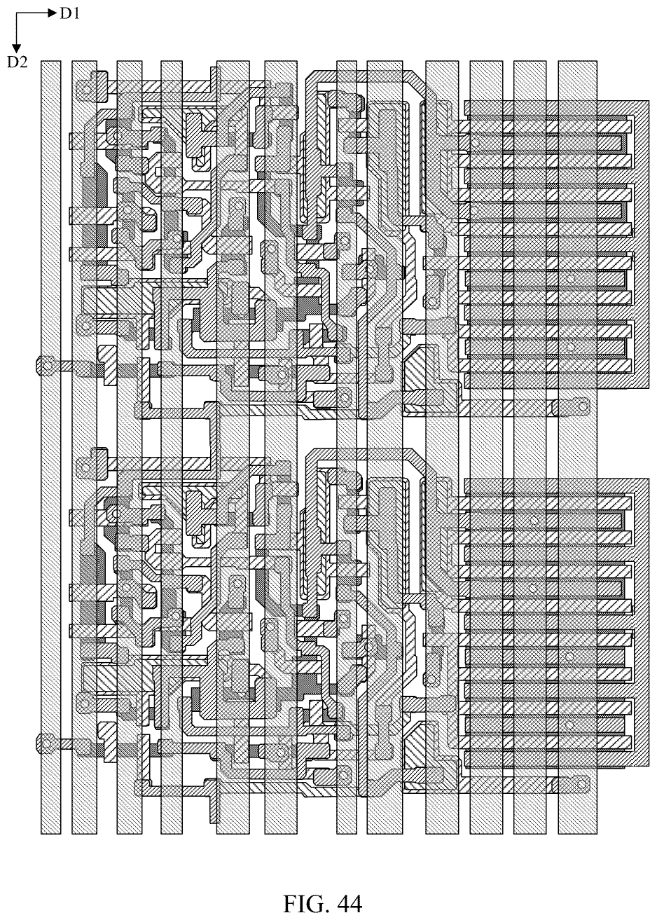

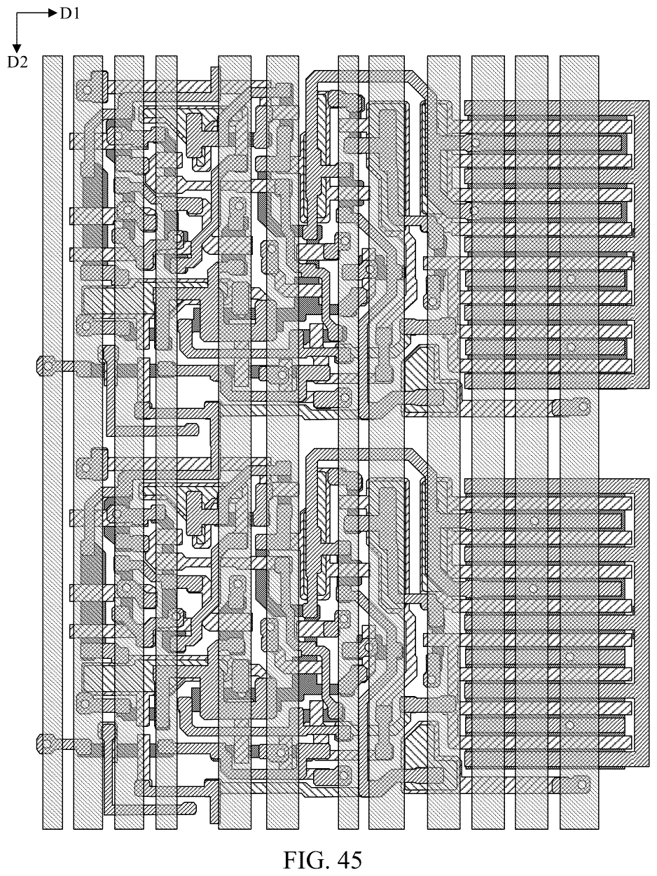

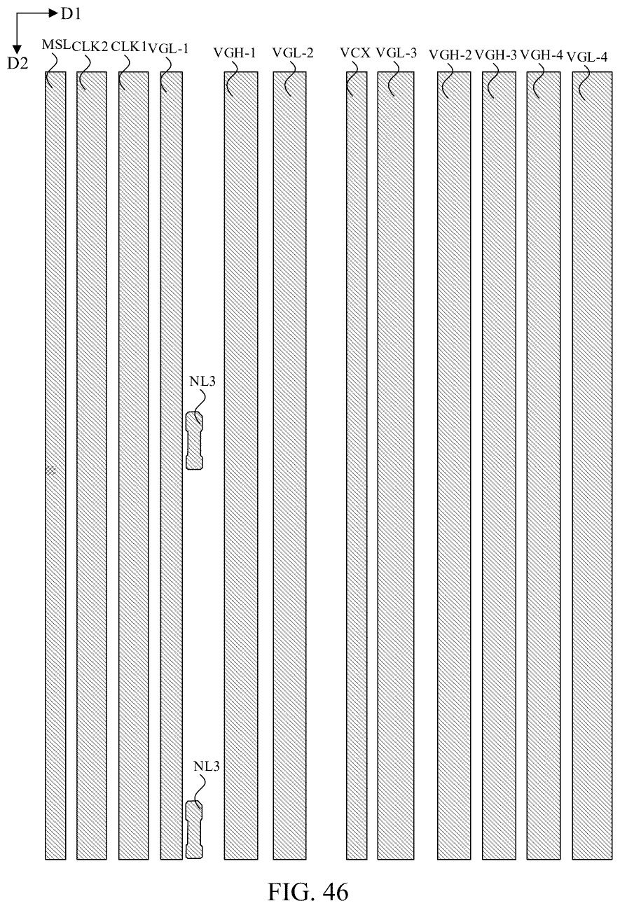

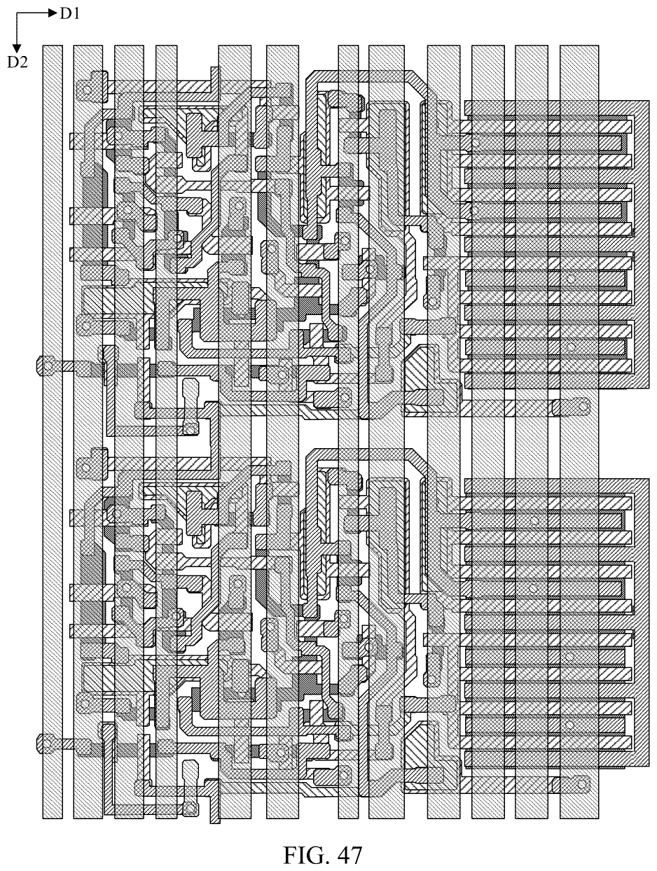

(7) A pattern of a fourth conductive layer is formed. In an exemplary implementation mode, forming the pattern of the fourth conductive layer may include: depositing a fourth conductive thin film on the base substrate on which the above-mentioned patterns are formed, and patterning the fourth conductive thin film through a patterning process, to form a fourth conductive layer disposed on the fourth insulation layer, as shown in FIGS. 40 to 47, FIG. 40 is a schematic diagram of a pattern of a fourth conductive layer in the display substrate according to FIGS. 7 and 8, FIG. 41 is a schematic diagram of the display substrate according to FIG. 7 after a pattern of a fourth conductive layer is formed, FIG. 42 is a schematic diagram of the display substrate according to FIG. 8 after a pattern of a fourth conductive layer is formed, FIG. 43 is a schematic diagram of a pattern of a fourth conductive layer in the display substrate according to FIGS. 9 and 10, FIG. 44 is a schematic diagram of the display substrate according to FIG. 9 after a pattern of a fourth conductive layer is formed, FIG. 45 is a schematic diagram of the display substrate according to FIG. 10 after a pattern of a fourth conductive layer is formed, FIG. 46 is a schematic diagram of a pattern of a fourth conductive layer in the display substrate according to FIG. 11, FIG. 47 is a schematic diagram of the display substrate according to FIG. 11 after a pattern of a fourth conductive layer is formed. In an exemplary implementation mode, the fourth conductive layer may be referred to as a second source drain metal (SD2) layer.

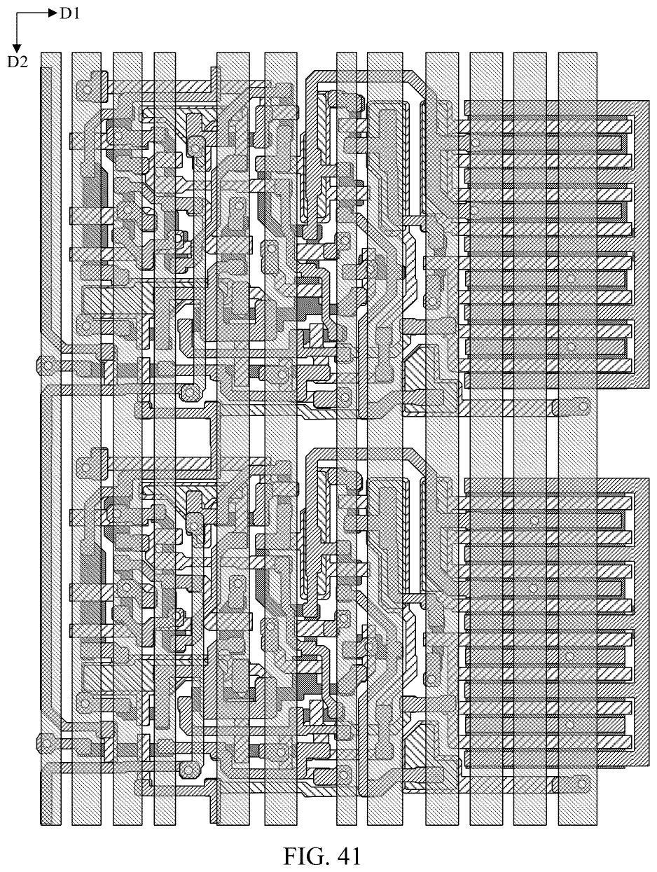

In an exemplary implementation mode, as shown in FIGS. 41 to 47, in the display substrate according to FIGS. 7 to 11, the pattern of the fourth conductive layer may at least include a latch signal line MSL, a second clock signal line CLK2, a first clock signal line CLK1, a first power supply line VGL-1, a second power supply line VGH-1, a third power supply line VGL-2, a fourth power supply line VCX, a fifth power supply line VGL-3, a sixth power supply line VGH-2, a seventh power supply line VGH-3, an eighth power supply line VGH-4, and a ninth power supply line VGL-4.

In an exemplary implementation mode, as shown in FIG. 41, in the display substrate according to FIGS. 7 and 8, the pattern of the fourth conductive layer may include at least a first node connection line NL1 of a node connection line. The first node connection line NL1 extends in the second direction D2.

In an exemplary implementation mode, as shown in FIG. 46, in the display substrate according to FIG. 11, the pattern of the fourth conductive layer may include at least a third node connection line NL3 of a node connection line. The third node connection line NL3 extends in the second direction D2.

In an exemplary implementation mode, the latch signal line MSL, the second clock signal line CLK2, the first clock signal line CLK1, the first power supply line VGL-1, the second power supply line VGH-1, the third power supply line VGL-2, the fourth power supply line VCX, the fifth power supply line VGL-3, the sixth power supply line VGH-2, the seventh power supply line VGH-3, the eighth power supply line VGH-4, and the ninth power supply line VGL-4 are arranged sequentially along the display region.

In an exemplary implementation mode, at least one signal line of the latch signal line MSL, the second clock signal line CLK2, the first clock signal line CLK1, the first power supply line VGL-1, the second power supply line VGH-1, the third power supply line VGL-2, the fourth power supply line VCX, the fifth power supply line VGL-3, the sixth power supply line VGH-2, the seventh power supply line VGH-3, the eighth power supply line VGH-4, and the ninth power supply line VGL-4 extends at least partially in the second direction D2.

In an exemplary implementation mode, an orthographic projection of the latch signal line MSL on the base substrate is located at a side of an orthographic projection of a plurality of transistors in a shift register on the base substrate away from the display region, and an orthographic projection of at least one signal line of the first clock signal line CLK1, the second clock signal line CLK2, the first power supply line VGL-1, the second power supply line VGH-1, the third power supply line VGL-2, the fourth power supply line, the fifth power supply line VGL-3, the sixth power supply line VGH-2, the seventh power supply line VGH-3, the eighth power supply line VGH-4, and the ninth power supply line VGL-4 on the base substrate is at least partially overlapped with orthographic projections of some transistors in the shift register on the base substrate. An arrangement mode of the above signal lines may reduce regions occupied by a gate drive circuit and signal lines connected thereto, and a narrow bezel of the display substrate may be achieved.

In an exemplary implementation mode, the latch signal line MSL is connected with a first electrode of a nineteenth transistor T19 of at least one stage shift register through the eighty-third via V83.

In an exemplary implementation mode, the second clock signal line CLK2 is connected with the first electrode of the second transistor through the seventy-third via, or is connected with the first electrode of the fifth transistor (also the first electrode of the eighth transistor, the first electrode of the ninth transistor, and the first electrode of the fourth transistor) through the seventy-fifth via, and is connected with the fourth connection line through the seventy-eighth via.

In an exemplary implementation mode, the first clock signal line CLK1 is connected with the first electrode of the fifth transistor (also the first electrode of the eighth transistor, the first electrode of the ninth transistor, and the first electrode of the fourth transistor) through the seventy-fifth via, and is connected with the fourth connection line through the seventy-eighth via, or is connected with the first electrode of the second transistor through the seventy-third via.

In an exemplary implementation mode, the first power supply line VGL-1 is connected with the first electrode of the third transistor through the eightieth via.

In an exemplary implementation mode, the second power supply line VGH-1 is connected with the first electrode of the fifth transistor through the seventy-sixth via.

In an exemplary implementation mode, the third power supply line VGL-2 is connected with the fifth connection line through the eighty-first via, and is connected with the first electrode of the twenty-second transistor (also the first electrode of the twenty-third transistor) through the eighty-fifth via.

In an exemplary implementation mode, the fourth power supply line VCX is connected with the sixth connection line through the eighty-second via, and is connected with the eighth connection line through the eighty-fourth via.

In an exemplary implementation mode, the fifth power supply line VGL-3 is connected with the first electrode of the tenth transistor through the seventy-ninth via.

In an exemplary implementation mode, the sixth power supply line VGH-2 is connected with the first electrode of the twenty-fourth transistor through the eighty-sixth via.

In an exemplary implementation mode, the seventh power supply line VGH-3, and a seventh power supply line or an eighth power supply line of one shift register of an i-th stage shift register and an (i+1)-th stage shift register through the eighty-seventh via, is connected with the first electrode of the eighth transistor (also the first electrode of the ninth transistor, the first electrode of the thirteenth transistor, and the first electrode of the twenty-fifth transistor) through the via.

In an exemplary implementation mode, the eighth power supply line VGH-4, and a seventh power supply line or an eighth power supply line of the other shift register of the i-th stage shift register and the (i+1)-th stage shift register through the eighty-seventh via, is connected with the first electrode of the eighth transistor (also the first electrode of the ninth transistor, the first electrode of the thirteenth transistor, and the first electrode of the twenty-fifth transistor) through the eighty-seventh via.

In an exemplary implementation mode, the ninth power supply line VGL-4 is connected with the first electrode of the twenty-sixth transistor through the eighty-eighth via.

In an exemplary implementation mode, the ninth power supply line VGL-4 is connected with the tenth connection line through the ninetieth via.

In an exemplary implementation mode, in the display substrate according to FIGS. 7 and 8, a first node connection line of an i-th node connection line is connected with a second electrode of a sixth transistor (also a first electrode of a seventh transistor) in the i-th stage shift register through the seventy-seventh via, and is connected with a second node connection line in the (i+1)-th stage shift register through the eighty-ninth via.

In an exemplary implementation mode, in the display substrate according to FIG. 11, a third node connection line NL3 of an i-th node connection line is connected with a second node connection line through the eighty-ninth via.

In an exemplary implementation mode, an arrangement of the first connection line to the eleventh connecting line plays a role of connection electrodes, so that depths of vias in the display substrate may be reduced, and reliability of the display substrate may be improved.

In an exemplary implementation mode, the latch signal line MSL, the second clock signal line CLK2, the first clock signal line CLK1, the first power supply line VGL-1, the second power supply line VGH-1, the third power supply line VGL-2, the fourth power supply line VCX, the fifth power supply line VGL-3, the sixth power supply line VGH-2, the seventh power supply line VGH-3, the eighth power supply line VGH-4, and the ninth power supply line VGL-4 may be designed with an equal width, or may be designed with unequal widths, may be straight lines, or may be polylines, which not only may facilitate a layout of shift registers, but also may reduce parasitic capacitance between signal lines, the present disclosure is not limited thereto.

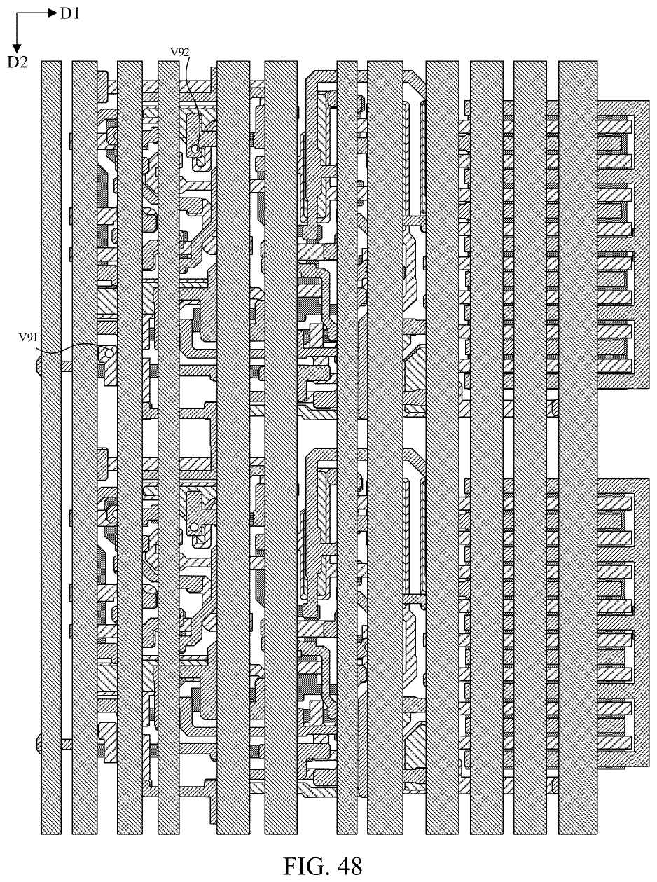

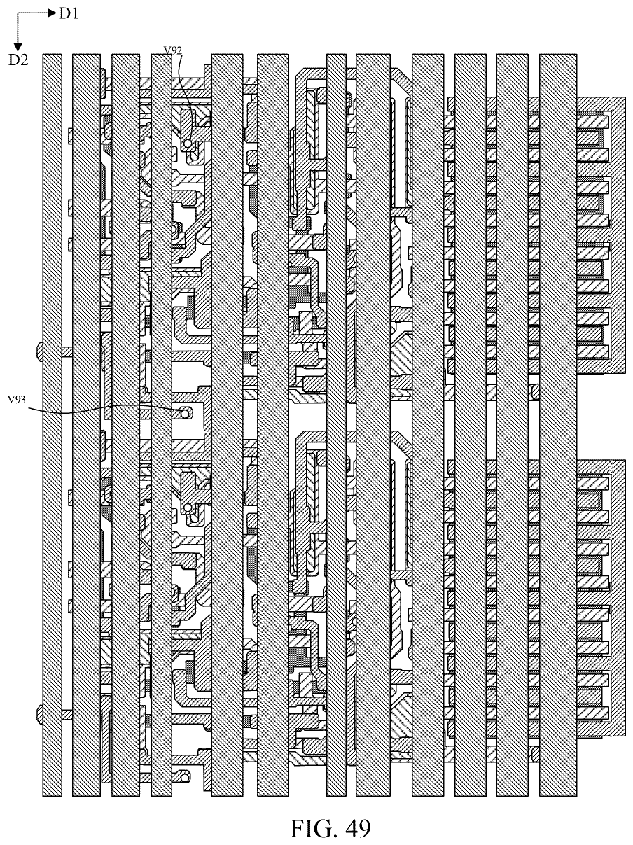

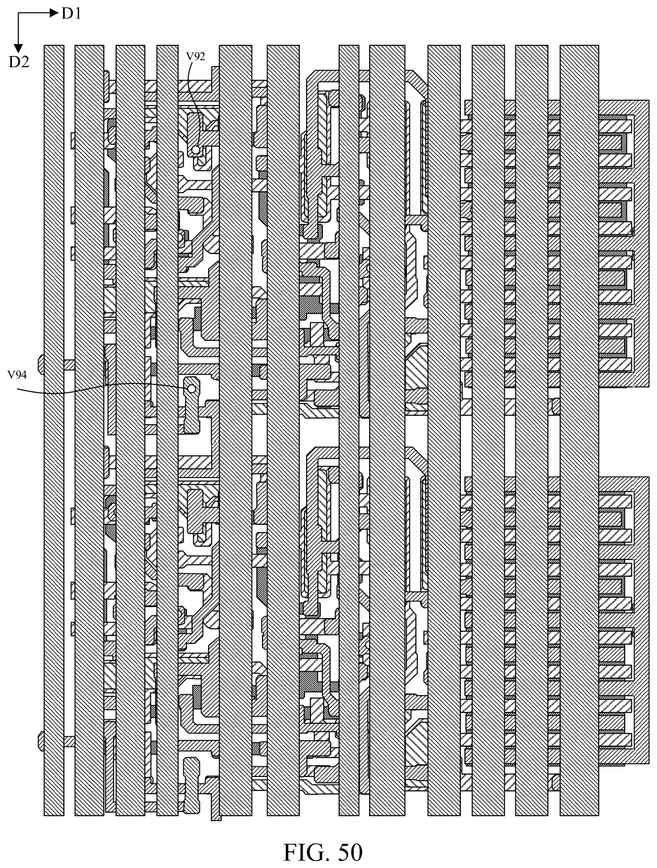

(8) A first planarization layer is formed. In an exemplary implementation mode, forming a pattern of a first planarization layer may include: depositing a fifth insulation thin film on the base substrate on which the aforementioned patterns are formed, coating a first planarization thin film, and patterning the fifth insulation thin film and the first planarization thin film through a patterning process, to form the pattern of the fifth insulation layer covering the aforementioned structures and the pattern of the first planarization layer covering the pattern of the fifth insulation layer, wherein the fifth insulation layer and the first planarization layer are provided with patterns of a plurality of via. As shown in FIGS. 48 to 50, FIG. 48 is a schematic diagram of the display substrate according to FIG. 9 after a pattern of a first planarization layer is formed, FIG. 49 is a schematic diagram of the display substrate according to FIG. 10 after a pattern of a first planarization layer is formed, and FIG. 50 is a schematic diagram of the display substrate according to FIG. 11 after a pattern of a first planarization layer is formed.

In an exemplary implementation mode, as shown in FIG. 48, the pattern of the first planarization layer in the display substrate according to FIG. 9 may include at least a ninety-first via V91 and a ninety-second via V92 in each stage shift register.

In an exemplary implementation mode, as shown in FIG. 49, the pattern of the fourth insulation layer in the display substrate according to FIG. 10 may include at least a ninety-second via V92 and a ninety-third via V93 in each stage shift register.

In an exemplary implementation mode, as shown in FIG. 50, the pattern of the fourth insulation layer in the display substrate according to FIG. 11 may include at least a ninety-second via V92 and a ninety-fourth via V94 in each stage shift register.

In an exemplary implementation mode, an orthographic projection of the ninety-first via V91 on the base substrate is located within a range of an orthographic projection of a gate electrode of the nineteenth transistor on the base substrate, the second insulation layer, the third insulation layer, the fourth insulation layer, and the fifth insulation layer within the ninety-first via V91 are etched to expose a surface of the gate electrode of the nineteenth transistor, and the ninety-first via V91 is configured such that a node connection line formed subsequently is connected with the gate electrode of the nineteenth transistor through the via.

In an exemplary implementation mode, an orthographic projection of the ninety-second via V92 on the base substrate is within a range of an orthographic projection of a second electrode of the sixth transistor (also a first electrode of the seventh transistor) on the base substrate. The fourth insulation layer and the fifth insulation layer within the ninety-second via V92 are etched away, and a surface of the second electrode of the sixth transistor (also the first electrode of the seventh transistor) is exposed. In the display substrate according to FIG. 9, the ninety-second via V92 is configured such that a node connection line formed subsequently is connected with the second electrode of the sixth transistor (also the first electrode of the seventh transistor) through the via. And in the display substrate according to FIG. 11, the ninety-second via V92 is configured such that a first connection line of a node connection line formed subsequently is connected with the second electrode of the sixth transistor (also the first electrode of the seventh transistor) through the via.

In an exemplary implementation mode, an orthographic projection of the ninety-third via V93 on the base substrate is within a range of an orthographic projection of a second node connection line of a node connection line on the base substrate, the fourth insulation layer and the fifth insulation layer within the ninety-third via V93 are etched to expose a surface of the second node connection line of the node connection line, and the ninety-third via V93 is configured such that a first node connection line of the node connection line formed subsequently is connected with the second node connection line of the node connection line through the via.

In an exemplary implementation mode, an orthographic projection of the ninety-fourth via V94 on the base substrate is within a range of an orthographic projection of a third node connection line of a node connection line on the base substrate, the fifth insulation layer within the ninety-fourth via V94 is etched, to expose a surface of the third node connection line of the node connection line, and the ninety-fourth via V94 is configured such that a first node connection line of the node connection line formed subsequently is connected with the third node connection line of the node connection line through the via.

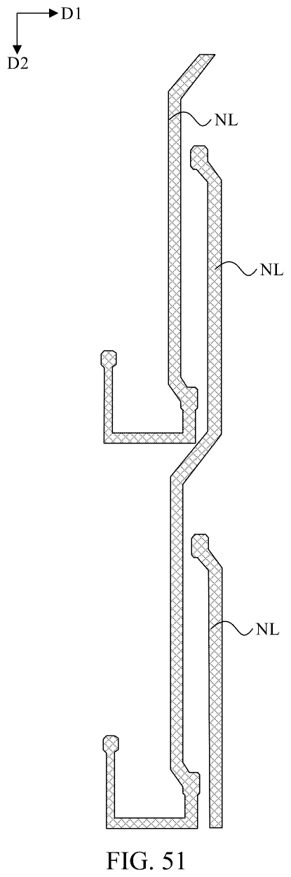

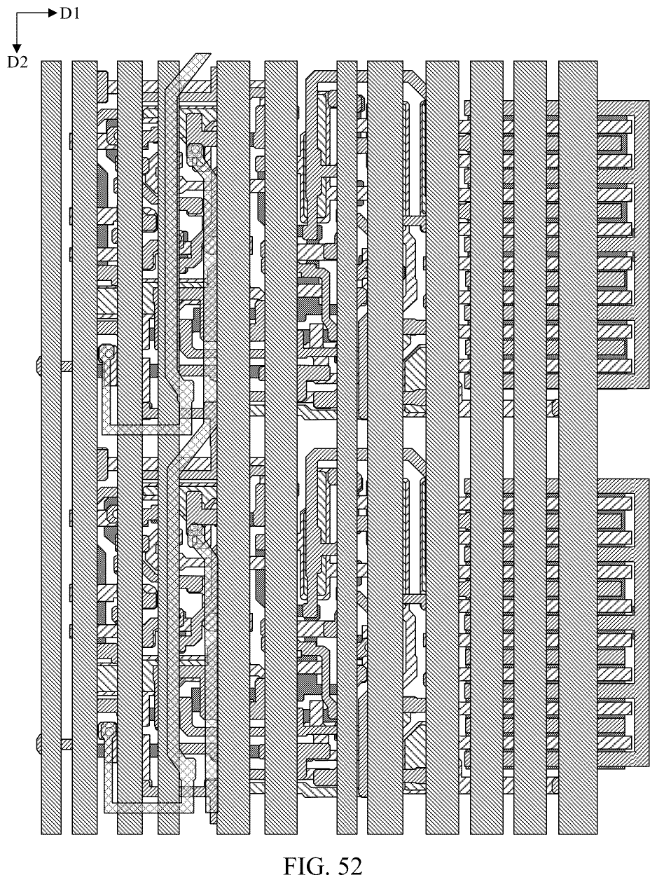

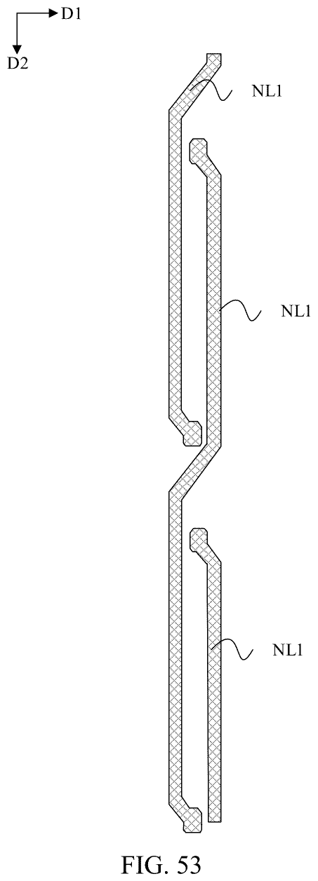

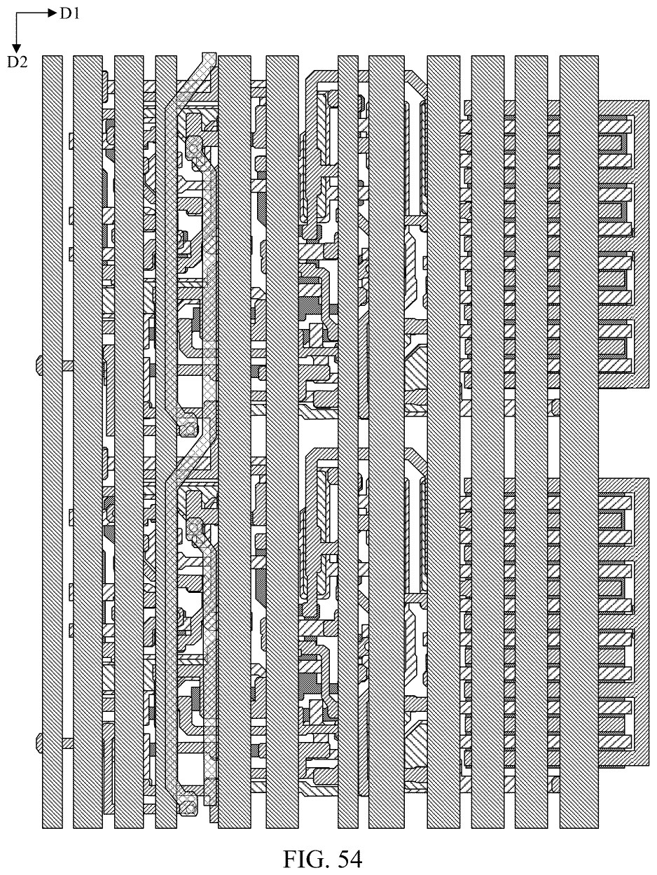

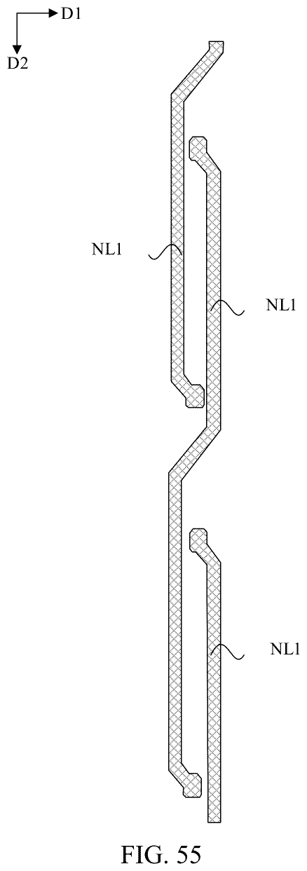

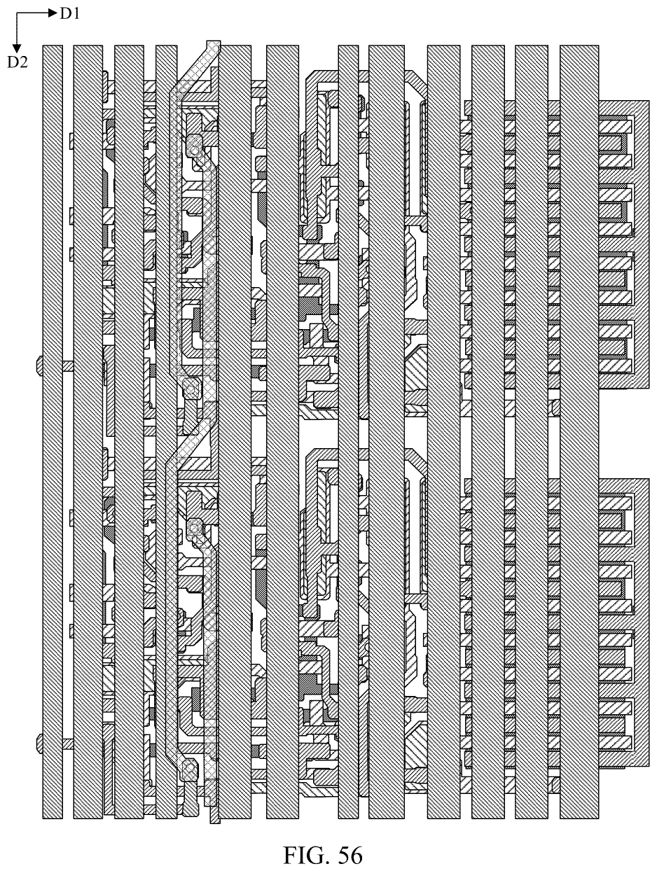

(9) A pattern of a fifth conductive layer is formed. In an exemplary implementation mode, forming the pattern of the fifth conductive layer may include: depositing a fifth conductive thin film on the base substrate on which the above-mentioned patterns are formed, and patterning the fifth conductive thin film through a patterning process, to form the pattern of the fifth conductive layer provided on the fifth insulation layer, as shown in FIGS. 51 to 56, FIG. 51 is a schematic diagram of a pattern of a fifth conductive layer in the display substrate according to FIG. 9, FIG. 52 is a schematic diagram of the display substrate according to FIG. 9 after a pattern of a fifth conductive layer is formed, FIG. 53 is a schematic diagram of a pattern of a fifth conductive layer in the display substrate according to FIG. 10, FIG. 54 is a schematic diagram of the display substrate according to FIG. 10 after a pattern of a fifth conductive layer is formed, FIG. 55 is a schematic diagram of a pattern of a fifth conductive layer in the display substrate according to FIG. 11, FIG. 56 is a schematic diagram of the display substrate according to FIG. 11 after a pattern of a fifth conductive layer is formed. In an exemplary implementation mode, the fifth conductive layer may be referred to as a third source drain metal (SD3) layer.

In an exemplary implementation mode, as shown in FIGS. 51 and 52, in the display substrate according to FIG. 9, the pattern of the fifth conductive layer may include at least a node connection line NL. The node connection line NL is connected with the gate electrode of the nineteenth transistor through the ninety-first via, and is connected with the second electrode of the sixth transistor (also the first electrode of the seventh transistor) through the ninety-second via.

In an exemplary implementation mode, as shown in FIGS. 53 and 54, in the display substrate according to FIG. 10, the pattern of the fifth conductive layer may at least include a first node connection line NL1. An i-th node connection line NL1 is connected with a second electrode of a sixth transistor of an i-th stage shift register (also a first electrode of a seventh transistor) through a ninety-second via, and is connected with a gate electrode of a nineteenth transistor of an (i+1)-th stage shift register through a ninety-third via.

In an exemplary implementation mode, as shown in FIGS. 55 and 56, in the display substrate according to FIG. 11, the pattern of the fifth conductive layer may at least include a first node connection line NL1. An i-th node connection line NL1 is connected with a second electrode of a sixth transistor of an i-th stage shift register (also a first electrode of a seventh transistor) through a ninety-second via, and is connected with a third node connection line through a ninety-fourth via.

So far, a drive circuit layer has been prepared on the base substrate. In a plane parallel to the display substrate, the drive circuit layer may include a plurality of shift registers electrically connected with the first clock signal line, the second clock signal line, the first power supply line to the ninth power supply line and the latch signal line. In a plane perpendicular to the display panel, the drive circuit layer may be disposed on the base substrate. In the display substrate according to FIGS. 7 and 8, the drive circuit layer may include the semiconductor layer, the first insulation layer, the first conductive layer, the second insulation layer, the second conductive layer, the third insulation layer, the third conductive layer, the fourth insulation layer, and the fourth conductive layer sequentially disposed on the base substrate. In the display substrate according to FIGS. 9 to 11, the drive circuit layer may include the semiconductor layer, the first insulation layer, the first conductive layer, the second insulation layer, the second conductive layer, the third insulation layer, the third conductive layer, the fourth insulation layer, the fourth conductive layer, the fifth insulation layer, and the fifth conductive layer sequentially disposed on the base substrate.

In an exemplary implementation mode, the base substrate may be a rigid base substrate or a flexible base substrate, wherein the rigid base substrate may be, but is not limited to, one or more of glass and metal foil; the flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber.

In an exemplary implementation mode, the flexible base substrate may include a first flexible material layer, a first inorganic material layer, a semiconductor layer, a second flexible material layer, and a second inorganic material layer which are stacked. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNx), Silicon Oxide (SiOx), or the like, for improving water and oxygen resistance of the base substrate. The first inorganic material layer and the second inorganic material layer may also be referred to as barrier layers, and a material of the semiconductor layer may be amorphous silicon (a-si). In an exemplary implementation mode, taking a stacked structure of PI1/Barrier1/a-si/PI2/Barrier2 as an example, its preparation process may include: first coating a layer of polyimide on a glass carrier board, after the layer of polyimide is cured to form a film, a first flexible (PI1) layer is formed; then depositing a layer of barrier thin film on the first flexible layer to form a first barrier (Barrier 1) layer overlaying the first flexible layer; then depositing a layer of amorphous silicon thin film on the first barrier layer to form an amorphous silicon (a-si) layer covering the first barrier layer; then coating another layer of polyimide on the amorphous silicon layer, after this layer of polyimide is cured to form a film, a second flexible (PI2) layer is formed; and then depositing a layer of barrier thin film on the second flexible layer to form a second barrier (Barrier 2) layer covering the second flexible layer, so as to complete preparation of the base substrate.

In an exemplary implementation mode, the semiconductor layer may be an amorphous silicon layer, a polysilicon layer, or may be a metal oxide layer. Herein, the metal oxide layer may be an oxide including indium and tin, an oxide including tungsten and indium, an oxide including tungsten, indium, and zinc, an oxide including titanium and indium, an oxide including titanium, indium, and tin, an oxide including indium and zinc, an oxide including silicon, indium, and tin, or an oxide including indium or gallium and zinc. The metal oxide layer may be a single layer, a double-layer, or a multi-layer.

In an exemplary implementation mode, the first conductive layer, the second conductive layer, the third conductive layer, the fourth conductive layer, and the fifth conductive layer may be made of a metal material, such as any one or more of Argentum (Ag), Copper (Cu), Aluminum (A1), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Mo/Cu/Mo.

In an exemplary implementation mode, the first insulation layer, the second insulation layer, the third insulation layer, the fourth insulation layer, and the fifth insulation layer may be made of any one or more of Silicon Oxide (SiOx), Silicon Nitride (SiNx), and Silicon Oxynitride (SiON), and may be a single layer, a multi-layer, or a composite layer.

In an exemplary implementation mode, after preparation of the drive circuit layer is completed, a light emitting structure layer is prepared on the drive circuit layer, and a preparation process of the light emitting structure layer may include following operations.

Depositing an anode conductive thin film on the base substrate on which the above-mentioned patterns are formed, patterning the anode conductive thin film through a patterning process to form a pattern of an anode conductive layer disposed on the second planarization layer, depositing a pixel definition thin film on the base substrate on which the above-mentioned patterns are formed, patterning the pixel definition thin film through a patterning process to form a pattern of a pixel definition layer exposing the pattern of the anode conductive layer, coating an organic light emitting material on the base substrate on which the pattern of the pixel definition layer is formed, patterning the organic light emitting material through a patterning process to form a pattern of an organic structure layer, depositing a cathode conductive thin film on the base substrate on which the pattern of the organic structure layer is formed, and patterning the cathode conductive thin film through a patterning process to form a cathode conductive layer.

So far, the light emitting structure layer has been manufactured on the base substrate.

In an exemplary implementation mode, the anode conductive layer includes at least patterns of a plurality of anodes. The patterns of the plurality of anodes may include an anode of a first light emitting device, an anode of a second light emitting device, an anode of a third light emitting device, and an anode of a fourth light emitting device, wherein the anode of the first light emitting device is located at a red sub-pixel emitting red light, the anode of the second light emitting device may be located at a blue sub-pixel emitting blue light, the anode of the third light emitting device may be located at a first green sub-pixel emitting green light, and the anode of the fourth light emitting device may be located at a second green sub-pixel emitting green light.

In an exemplary implementation mode, the anode of the first light emitting device and the anode of the second light emitting device may be alternately disposed in the first direction, and the anode of the third light emitting device and the anode of the fourth light emitting device may be alternately disposed in the first direction. Or, the anode of the first light emitting device and the anode of the second light emitting device may be alternately disposed in the second direction, and the anode of the third light emitting device and the anode of the fourth light emitting device may be alternately disposed in the second direction.

In an exemplary implementation mode, four sub-pixels in one pixel unit may have a same anode shape and a same area, or may have different anode shapes and different areas.

In an exemplary implementation mode, the anode conductive layer may be of a single-layer structure, such as Indium Tin Oxide (ITO) or Indium Zinc Oxide (IZO), or may be of a multi-layer composite structure, such as ITO/Ag/ITO.

In an exemplary implementation mode, the organic structure layer may at least include: an organic emitting layer of a light emitting device.

In an exemplary implementation mode, the cathode conductive layer may include, at least, cathodes of a plurality of light emitting devices.

In an exemplary implementation mode, the cathode layer may be made of a metal material, such as any one or more of Argentum (Ag), Copper (Cu), Aluminum (A1), and Molybdenum (Mo), or the above conductive alloy materials, such as an Aluminum Neodymium alloy (AlNd) or a Molybdenum Niobium alloy (MoNb), and may have a single-layer structure or a multi-layer composite structure, such as Mo/Cu/Mo. Exemplarily, the fourth conductive layer may be of a three-layer stacked structure formed of titanium, aluminum, and titanium.

The display substrate according to the embodiment of the present disclosure may be applied to a display product with any resolution.

In an exemplary implementation mode, a subsequent preparation process may include: forming an encapsulation structure layer on the cathode conductive layer, and the encapsulation structure layer may include a first encapsulation layer, a second encapsulation layer, and a third encapsulation layer which are stacked. The first encapsulation layer and the third encapsulation layer may be made of an inorganic material, the second encapsulation layer may be made of an organic material, and the second encapsulation layer is disposed between the first encapsulation layer and the third encapsulation layer, which may ensure that external water vapor cannot enter the light emitting structure layer.

An embodiment of the present disclosure also provides a gate drive circuit, including: a plurality of shift registers provided in any one of the foregoing embodiments; and a cascaded signal output terminal of one shift register in at least one stage shift register is electrically connected with a signal input terminal of a previous stage shift register.

An embodiment of the present disclosure also provides a display apparatus, which includes a gate drive circuit provided in any one of the aforementioned embodiments.

An embodiment of the present disclosure also provides a drive method of a shift register, which is configured to drive the shift register provided by any one of the embodiments. The drive method for the shift register may include: providing a signal to a cascaded signal output terminal by a shift sub-circuit under control of signals of a signal input terminal, a first clock signal terminal, a second clock signal terminal, a first power supply terminal, and a second power supply terminal; and providing a signal to a drive signal output terminal by an output sub-circuit under control of signals of the shift sub-circuit, a latch signal terminal, a first control signal terminal, a second control signal terminal, the cascaded signal output terminal, a third power supply terminal, a fourth power supply terminal, and a fifth power supply terminal.

An embodiment of the present disclosure also provides a display apparatus, which may include: a display substrate.

The display substrate is the display substrate according to any of the aforementioned embodiments, and has similar implementation principles and implementation effects, which will not be repeated here.

In an exemplary implementation mode, the display apparatus may be any product or component with a display function such as a wearable device, a mobile phone, a tablet computer, a television, a display, a laptop computer, a digital photo frame, and a navigator.

The drawings of the embodiments of the present disclosure only involve structures involved in the embodiments of the present disclosure, and other structures may be referred to general designs.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although the implementation modes of the present disclosure are disclosed above, the contents are only implementation modes used for ease of understanding of the present disclosure, but not intended to limit the present disclosure. Any of those skilled in the art of the present disclosure may make any modification and variation in the forms and details of implementation without departing from the spirit and scope of the present disclosure. However, the scope of patent protection of the present disclosure should be subject to the scope defined in the appended claims.

1. A shift register, comprising: a shift sub-circuit and an output sub-circuit; wherein
the shift sub-circuit is electrically connected with a signal input terminal, a first clock signal terminal, a second clock signal terminal, a first power supply terminal, a second power supply terminal, and a cascaded signal output terminal respectively, and is configured to provide a signal to the cascaded signal output terminal under control of signals of the signal input terminal, the first clock signal terminal, the second clock signal terminal, the first power supply terminal, and the second power supply terminal;
the output sub-circuit is electrically connected with the shift sub-circuit, a latch signal terminal, a first control signal terminal, a second control signal terminal, a third power supply terminal, a fourth power supply terminal, a fifth power supply terminal, the cascaded signal output terminal, and a drive signal output terminal respectively, and is configured to provide a signal to the drive signal output terminal under control of signals of the shift sub-circuit, the latch signal terminal, the first control signal terminal, the second control signal terminal, the cascaded signal output terminal, the third power supply terminal, the fourth power supply terminal, and the fifth power supply terminal;
the shift sub-circuit comprises: at least one shift output transistor, the shift output transistor is electrically connected with the cascaded signal output terminal, and the output sub-circuit comprises: at least one drive output transistor, and the drive output transistor is electrically connected with the drive signal output terminal; the shift sub-circuit further comprises: at least one transistor, and the output sub-circuit further comprises: at least one transistor;
the shift sub-circuit is provided with a third node, a control electrode of the at least one drive output transistor is electrically connected with the third node through the at least one transistor of the output sub-circuit, and a control electrode of the at least one shift output transistor is electrically connected with the third node through the at least one transistor of the shift sub-circuit.

2. The shift register according to claim 1, wherein the shift sub-circuit is further electrically connected with the fifth power supply terminal, and is configured to provide a signal to the cascaded signal output terminal under control of signals of the signal input terminal, the first clock signal terminal, the second clock signal terminal, the first power supply terminal, the second power supply terminal, and the fifth power supply terminal.

3. The shift register according to claim 2, wherein the shift sub-circuit comprises: a first transistor to a sixteenth transistor and a first capacitor to a third capacitor;
a control electrode of the first transistor is electrically connected with the first clock signal terminal, a first electrode of the first transistor is electrically connected with the signal input terminal, and a second electrode of the first transistor is electrically connected with the third node;
a control electrode of the second transistor is electrically connected with the third node, a first electrode of the second transistor is electrically connected with the first clock signal terminal, and a second electrode of the second transistor is electrically connected with a tenth node;
a control electrode of the third transistor is electrically connected with the first clock signal terminal, a first electrode of the third transistor is electrically connected with the second power supply terminal, and a second electrode of the third transistor is electrically connected with the tenth node;
a control electrode of the fourth transistor is electrically connected with a second node, a first electrode of the fourth transistor is electrically connected with the second clock signal terminal, and a second electrode of the fourth transistor is electrically connected with a fifth node;
a control electrode of the fifth transistor is electrically connected with the tenth node, a first electrode of the fifth transistor is electrically connected with the first power supply terminal, and a second electrode of the fifth transistor is electrically connected with the fifth node;
a control electrode of the sixth transistor is electrically connected with a sixth node, a first electrode of the sixth transistor is electrically connected with the second clock signal terminal, and a second electrode of the sixth transistor is electrically connected with a first node;
a control electrode of the seventh transistor is electrically connected with the second clock signal terminal, a first electrode of the seventh transistor is electrically connected with the first node, and a second electrode of the seventh transistor is electrically connected with a fourth node;
a control electrode of the eighth transistor is electrically connected with the third node, a first electrode of the eighth transistor is electrically connected with the first power supply terminal, and a second electrode of the eighth transistor is electrically connected with the fourth node;
a control electrode of the ninth transistor is electrically connected with the fourth node, a first electrode of the ninth transistor is electrically connected with the first power supply terminal, and a second electrode of the ninth transistor is electrically connected with the cascaded signal output terminal;
a gate electrode of the tenth transistor is electrically connected with a ninth node, a first electrode of the tenth transistor is electrically connected with the second power supply terminal, and a second electrode of the tenth transistor is electrically connected with the cascaded signal output terminal;
a control electrode of the eleventh transistor is electrically connected with the second power supply terminal, a first electrode of the eleventh transistor is electrically connected with the tenth node, and a second electrode of the eleventh transistor is electrically connected with the sixth node;
a control electrode of the twelfth transistor is electrically connected with the second power supply terminal, a first electrode of the twelfth transistor is electrically connected with the third node, and a second electrode of the twelfth transistor is electrically connected with the ninth node;
a control electrode of the thirteenth transistor is electrically connected with the fifth power supply terminal, a first electrode of the thirteenth transistor is electrically connected with the first power supply terminal, and a second electrode of the thirteenth transistor is electrically connected with the third node;
a control electrode of the fourteenth transistor is electrically connected with the first clock signal terminal, a first electrode of the fourteenth transistor is electrically connected with the signal input terminal, and a second electrode of the fourteenth transistor is electrically connected with a first electrode of the fifteenth transistor;
a control electrode of the fifteenth transistor is electrically connected with the second power supply terminal, and a second electrode of the fifteenth transistor is electrically connected with the second node;
a control electrode of the sixteenth transistor is electrically connected with the second node, a first electrode of the sixteenth transistor is electrically connected with the ninth node, and a second electrode of the sixteenth transistor is electrically connected with the second node;
a first electrode plate of the first capacitor is electrically connected with the sixth node, and a second electrode plate of the first capacitor is electrically connected with the first node;
a first electrode plate of the second capacitor is electrically connected with the fourth node, and a second electrode plate of the second capacitor is electrically connected with the first power supply terminal; and
a first electrode plate of the third capacitor is electrically connected with the second node, and a second electrode plate of the third capacitor is electrically connected with the fifth node.

4. The shift register according to claim 2, wherein the shift sub-circuit comprises: a first transistor to a fifteenth transistor and a first capacitor to a third capacitor;
a control electrode of the first transistor is electrically connected with the first clock signal terminal, a first electrode of the first transistor is electrically connected with the signal input terminal, and a second electrode of the first transistor is electrically connected with the third node;
a control electrode of the second transistor is electrically connected with the third node, a first electrode of the second transistor is electrically connected with the first clock signal terminal, and a second electrode of the second transistor is electrically connected with a tenth node;
a control electrode of the third transistor is electrically connected with the first clock signal terminal, a first electrode of the third transistor is electrically connected with the second power supply terminal, and a second electrode of the third transistor is electrically connected with the tenth node;
a control electrode of the fourth transistor is electrically connected with a second node, a first electrode of the fourth transistor is electrically connected with the second clock signal terminal, and a second electrode of the fourth transistor is electrically connected with a fifth node;
a control electrode of the fifth transistor is electrically connected with the tenth node, a first electrode of the fifth transistor is electrically connected with the first power supply terminal, and a second electrode of the fifth transistor is electrically connected with the fifth node;
a control electrode of the sixth transistor is electrically connected with a sixth node, a first electrode of the sixth transistor is electrically connected with the second clock signal terminal, and a second electrode of the sixth transistor is electrically connected with a first node;
a control electrode of the seventh transistor is electrically connected with the second clock signal terminal, a first electrode of the seventh transistor is electrically connected with the first node, and a second electrode of the seventh transistor is electrically connected with a fourth node;
a control electrode of the eighth transistor is electrically connected with the third node, a first electrode of the eighth transistor is electrically connected with the first power supply terminal, and a second electrode of the eighth transistor is electrically connected with the fourth node;
a control electrode of the ninth transistor is electrically connected with the fourth node, a first electrode of the ninth transistor is electrically connected with the first power supply terminal, and a second electrode of the ninth transistor is electrically connected with the cascaded signal output terminal;
a control electrode of a tenth transistor is electrically connected with the second node, a first electrode of the tenth transistor is electrically connected with the second power supply terminal, and a second electrode of the tenth transistor is electrically connected with the cascaded signal output terminal;
a control electrode of the eleventh transistor is electrically connected with the second power supply terminal, a first electrode of the eleventh transistor is electrically connected with the tenth node, and a second electrode of the eleventh transistor is electrically connected with the sixth node;
a control electrode of the twelfth transistor is electrically connected with the second power supply terminal, a first electrode of the twelfth transistor is electrically connected with the third node, and a second electrode of the twelfth transistor is electrically connected with the second node;
a control electrode of the thirteenth transistor is electrically connected with the fifth power supply terminal, a first electrode of the thirteenth transistor is electrically connected with the first power supply terminal, and a second electrode of the thirteenth transistor is electrically connected with the third node;
a control electrode of the fourteenth transistor is electrically connected with the first clock signal terminal, a first electrode of the fourteenth transistor is electrically connected with the signal input terminal, and a second electrode of the fourteenth transistor is electrically connected with a first electrode of the fifteenth transistor;
a control electrode of the fifteenth transistor is electrically connected with the second power supply terminal, and a second electrode of the fifteenth transistor is electrically connected with the second node;
a first electrode plate of the first capacitor is electrically connected with the sixth node, and a second electrode plate of the first capacitor is electrically connected with the first node;
a first electrode plate of the second capacitor is electrically connected with the fourth node, and a second electrode plate of the second capacitor is electrically connected with the first power supply terminal; and
a first electrode plate of the third capacitor is electrically connected with the second node, and a second electrode plate of the third capacitor is electrically connected with the fifth node.

5. The shift register according to claim 3, wherein the shift sub-circuit further comprises: a fourth capacitor;
a first electrode plate of the fourth capacitor is electrically connected with the second power supply terminal, and a second electrode plate of the fourth capacitor is electrically connected with the cascaded signal output terminal.

6. The shift register according to claim 3, wherein the first control signal terminal is electrically connected with the fifth node.

7. The shift register according to claim 6, wherein the second control signal terminal is electrically connected with a first node in a previous stage shift register of a current stage shift register.

8. The shift register according to claim 3, wherein the output sub-circuit is electrically connected with the second node, the third node, and the fourth node in the shift register, respectively.

9. The shift register according to claim 8, wherein the output sub-circuit comprises: a seventeenth transistor to a twenty-sixth transistor, and a fifth capacitor and a sixth capacitor;
a control electrode and a first electrode of the seventeenth transistor are respectively electrically connected with the second node, and a second electrode of the seventeenth transistor is electrically connected with the sixth node;
a control electrode of the eighteenth transistor is electrically connected with a seventh node, a first electrode of the eighteenth transistor is electrically connected with the third node, and a second electrode of the eighteenth transistor is electrically connected with the sixth node;
a control electrode of the nineteenth transistor is electrically connected with the second control signal terminal, a first electrode of the nineteenth transistor is electrically connected with the latch signal terminal, and a second electrode of the nineteenth transistor is electrically connected with a second electrode of the twentieth transistor;
a control electrode of the twentieth transistor is electrically connected with the cascaded signal output terminal, and a first electrode of the twentieth transistor is electrically connected with the seventh node;
a control electrode of the twenty-first transistor is electrically connected with the seventh node, a first electrode of the twenty-first transistor is electrically connected with the fourth node, and a second electrode of the twenty-first transistor is electrically connected with an eighth node;
a control electrode of the twenty-second transistor is electrically connected with the fifth power supply terminal, a first electrode of the twenty-second transistor is electrically connected with the fourth power supply terminal, and a second electrode of the twenty-second transistor is electrically connected with the seventh node;
a control electrode of the twenty-third transistor is electrically connected with the first control signal terminal, a first electrode of the twenty-third transistor is electrically connected with the fourth power supply terminal, and a second electrode of the twenty-third transistor is electrically connected with the seventh node;
a control electrode of the twenty-fourth transistor is electrically connected with the sixth node, a first electrode of the twenty-fourth transistor is electrically connected with the third power supply terminal, and a second electrode of the twenty-fourth transistor is electrically connected with the eighth node;
a control electrode of the twenty-fifth transistor is electrically connected with the eighth node, a first electrode of the twenty-fifth transistor is electrically connected with the third power supply terminal, and a second electrode of the twenty-fifth transistor is electrically connected with the drive signal output terminal;
a control electrode of the twenty-sixth transistor is electrically connected with the sixth node, a first electrode of the twenty-sixth transistor is electrically connected with the fourth power supply terminal, and a second electrode of the twenty-sixth transistor is electrically connected with the drive signal output terminal;
a first electrode plate of the fifth capacitor is electrically connected with the seventh node, and a second electrode plate of the fifth capacitor is electrically connected with the eighth node; and
a first electrode plate of the sixth capacitor is electrically connected with the eighth node, and a second electrode plate of the sixth capacitor is electrically connected with the third power supply terminal.

10. The shift register according to claim 1, wherein the shift sub-circuit comprises: a first transistor to an eighth transistor, and a first capacitor and a second capacitor;
a control electrode of the first transistor is electrically connected with the first clock signal terminal, a first electrode of the first transistor is electrically connected with the signal input terminal, and a second electrode of the first transistor is electrically connected with the third node;
a control electrode of the second transistor is electrically connected with the third node, a first electrode of the second transistor is electrically connected with the first clock signal terminal, and a second electrode of the second transistor is electrically connected with a fourth node;
a control electrode of the third transistor is electrically connected with the first clock signal terminal, a first electrode of the third transistor is electrically connected with the second power supply terminal, and a second electrode of the third transistor is electrically connected with the fourth node;
a control electrode of the fourth transistor is electrically connected with the fourth node, a first electrode of the fourth transistor is electrically connected with the first power supply terminal, and a second electrode of the fourth transistor is electrically connected with the cascaded signal output terminal;
a control electrode of the fifth transistor is electrically connected with a ninth node, a first electrode of the fifth transistor is electrically connected with the second clock signal terminal, and a second electrode of the fifth transistor is electrically connected with the cascaded signal output terminal;
a control electrode of the sixth transistor is electrically connected with the fourth node, a first electrode of the sixth transistor is electrically connected with the first power supply terminal, and a second electrode of the sixth transistor is electrically connected with a first electrode of the seventh transistor;
a control electrode of the seventh transistor is electrically connected with the second clock signal terminal, and a second electrode of the seventh transistor is electrically connected with the third node;
a control electrode of the eighth transistor is electrically connected with the second power supply terminal, a first electrode of the eighth transistor is electrically connected with the third node, and a second electrode of the eighth transistor is electrically connected with the ninth node;
a first electrode plate of the first capacitor is electrically connected with the ninth node, and a second electrode plate of the first capacitor is electrically connected with the cascaded signal output terminal; and
a first electrode plate of the second capacitor is electrically connected with the fourth node, and a second electrode plate of the second capacitor is electrically connected with the first power supply terminal.

11. The shift register according to claim 10, wherein the output sub-circuit is further electrically connected with the third node and the fourth node in the shift sub-circuit, respectively.

12. The shift register according to claim 11, wherein the output sub-circuit comprises: an eighteenth transistor to a twenty-sixth transistor, and a fifth capacitor and a sixth capacitor;
a control electrode of the eighteenth transistor is electrically connected with a seventh node, a first electrode of the eighteenth transistor is electrically connected with the third node, and a second electrode of the eighteenth transistor is electrically connected with a sixth node;
a control electrode of the nineteenth transistor is electrically connected with the second control signal terminal, a first electrode of the nineteenth transistor is electrically connected with the latch signal terminal, and a second electrode of the nineteenth transistor is electrically connected with a second electrode of the twentieth transistor;
a control electrode of the twentieth transistor is electrically connected with the cascaded signal output terminal, and a first electrode of the twentieth transistor is electrically connected with the seventh node;
a control electrode of the twenty-first transistor is electrically connected with the seventh node, a first electrode of the twenty-first transistor is electrically connected with the fourth node, and a second electrode of the twenty-first transistor is electrically connected with an eighth node;
a control electrode of the twenty-second transistor is electrically connected with the fifth power supply terminal, a first electrode of the twenty-second transistor is electrically connected with the fourth power supply terminal, and a second electrode of the twenty-second transistor is electrically connected with the seventh node;
a control electrode of the twenty-third transistor is electrically connected with the first control signal terminal, a first electrode of the twenty-third transistor is electrically connected with the fourth power supply terminal, and a second electrode of the twenty-third transistor is electrically connected with the seventh node;
a control electrode of the twenty-fourth transistor is electrically connected with the sixth node, a first electrode of the twenty-fourth transistor is electrically connected with the third power supply terminal, and a second electrode of the twenty-fourth transistor is electrically connected with the eighth node;
a control electrode of the twenty-fifth transistor is electrically connected with the eighth node, a first electrode of the twenty-fifth transistor is electrically connected with the third power supply terminal, and a second electrode of the twenty-fifth transistor is electrically connected with the drive signal output terminal;
a control electrode of the twenty-sixth transistor is electrically connected with the sixth node, a first electrode of the twenty-sixth transistor is electrically connected with the fourth power supply terminal, and a second electrode of the twenty-sixth transistor is electrically connected with the drive signal output terminal;
a first electrode plate of the fifth capacitor is electrically connected with the seventh node, and a second electrode plate of the fifth capacitor is electrically connected with the eighth node; and
a first electrode plate of the sixth capacitor is electrically connected with the eighth node, and a second electrode plate of the sixth capacitor is electrically connected with the third power supply terminal.

13. The shift register according to claim 1, wherein the first power supply terminal and the third power supply terminal are a same signal terminal, and the second power supply terminal and the fourth power supply terminal are a same signal terminal.

14. A gate drive circuit, comprising a plurality of shift registers according to claim 1; wherein
a cascaded signal output terminal of one shift register in at least one stage shift register is electrically connected with a signal input terminal of a previous stage shift register.

15. A display apparatus, comprising a gate drive circuit according to claim 14.

16. A drive method of a shift register, configured to drive the shift register according to claim 1, wherein the method comprises:
providing a signal to a cascaded signal output terminal by a shift sub-circuit under control of signals of a signal input terminal, a first clock signal terminal, a second clock signal terminal, a first power supply terminal, and a second power supply terminal; and
providing a signal to a drive signal output terminal by an output sub-circuit under control of signals of the shift sub-circuit, a latch signal terminal, a first control signal terminal, a second control signal terminal, the cascaded signal output terminal, a third power supply terminal, a fourth power supply terminal, and a fifth power supply terminal.

17. The shift register according to claim 4, wherein the shift sub-circuit further comprises: a fourth capacitor;
a first electrode plate of the fourth capacitor is electrically connected with the second power supply terminal, and a second electrode plate of the fourth capacitor is electrically connected with the cascaded signal output terminal.

18. The shift register according to claim 4, wherein the first control signal terminal is electrically connected with the fifth node.

19. The shift register according to claim 5, wherein the first control signal terminal is electrically connected with the fifth node.

20. The shift register according to claim 4, wherein the output sub-circuit is electrically connected with the second node, the third node, and the fourth node in the shift register, respectively.
